(19) United States
(12) Patent Application Publication
(10) Pub. No.: US 2024/0413141 A1
(43) Pub. Date: Dec. 12, 2024

(54) DISPLAY APPARATUS AND ELECTRONIC DEVICE

(71) Applicant: SEMICONDUCTOR ENERGY LABORATORY CO., LTD., Atsugi-shi, Kanagawa-ken (JP)

(72) Inventors: Tomoaki ATSUMI, Hadano, Kanagawa (JP); Koji KUSUNOKI, Isehara, Kanagawa (JP); Hideaki SHISHIDO, Atsugi, Kanagawa (JP); Susumu KAWASHIMA, Atsugi, Kanagawa (JP)

(21) Appl. No.: 18/700,899

(22) PCT Filed: Oct. 17, 2022
(86) PCT No.: PCT/IB2022/059905

§ 371 Date: Apr. 12, 2024

(30) Foreign Application Priority Data
Oct. 22, 2021 (JP) 2021-172871

(51) Int. Cl. H01L 25/16; H01L 23/15

(52) U.S. Cl. CPC H01L 25/167; H01L 23/15

(57) ABSTRACT

A high-definition display apparatus with a large diagonal size is provided. The display apparatus includes a first layer and a second layer positioned above the first layer. The first layer includes a substrate and a plurality of circuit regions, and the second layer includes a plurality of display regions. The substrate is a glass substrate. Each of the plurality of circuit regions includes a driver circuit, and the driver circuit includes a transistor including low-temperature polysilicon in a channel formation region. Each of the plurality of display regions includes a display pixel, and the display pixel includes a light-emitting device and a transistor including a metal oxide in a channel formation region. The driver circuit included in one of the plurality of circuit regions has a function of driving the display pixel included in one of the plurality of display region.

### TECHNICAL FIELD

One embodiment of the present invention relates to a display apparatus and an electronic device.

Note that one embodiment of the present invention is not limited to the above technical field. The technical field of the invention disclosed in this specification and the like relates to an object, a driving method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus, a liquid crystal display apparatus, a light-emitting device, a power storage device, an imaging device, a memory device, a signal processing device, a processor, an electronic device, a system, a driving method thereof, a manufacturing method thereof, and a testing method thereof.

### BACKGROUND ART

Display apparatuses included in electronic devices for XR (Extended Reality or Cross Reality) such as VR (Virtual Reality) or AR (Augmented Reality), mobile phones such as smartphones, tablet information terminals, laptop PCs (Personal Computers), and the like have undergone various improvements in recent years. For example, a display apparatus with a high pixel density, a display apparatus with high color reproducibility (NTSC ratio), a display apparatus with a small driver circuit, and a display apparatus with reduced power consumption have been developed.

In order to increase the area of the display portion of the display apparatus, for example, the bezel region around the display portion can be reduced. A driver circuit or the like is provided in the bezel region of the display portion of the display apparatus in some cases; thus, the driver circuit is provided in a region other than the bezel region, in which case the bezel region can be reduced or eliminated. For example, Patent Document 1 discloses a structure in which a display portion of a display apparatus is divided and one of a plurality of display portions and a driver circuit corresponding to the display portion overlap with each other, as a structure for making a smaller bezel region.

### REFERENCE

### Patent Document

### [Patent Document 1]

PCT International Publication No. 2021/191721

### SUMMARY OF THE INVENTION

### Problems to be Solved by the Invention

As described above, in a display apparatus with a display portion divided, a driver circuit corresponding to one display region is provided so as to overlap with the display region in a plan view in some cases. In that case, the display apparatus can be manufactured by providing the driver circuit over a semiconductor substrate and providing display pixels over the driver circuit, for example.

The diagonal size of such a display apparatus is limited by the size of a semiconductor substrate. In the case where a wafer including silicon as a material (hereinafter, referred to as a silicon wafer) is used for a semiconductor substrate, for example, a silicon wafer having a diameter exceeding 20 inches is needed to manufacture a display apparatus having a diagonal size exceeding 20 inches. Since the diameter of a silicon wafer used for the current semiconductor manufacturing line is approximately 300 mm (approximately 12 inches), a silicon wafer with a diameter exceeding 300 mm is difficult to prepare.

An object of one embodiment of the present invention is to provide a display apparatus with high definition and a large diagonal size. Another object of one embodiment of the present invention is to provide an electronic device including the above-described display apparatus. Another object of one embodiment of the present invention is to provide a novel display apparatus or a novel electronic device.

Note that the objects of one embodiment of the present invention are not limited to the objects listed above. The objects listed above do not preclude the existence of other objects. Note that the other objects are objects that are not described in this section and will be described below. The objects that are not described in this section can be derived from the description of the specification, the drawings, and the like and can be extracted as appropriate from the description by those skilled in the art. Note that one embodiment of the present invention is to achieve at least one of the objects listed above and the other objects. Note that one embodiment of the present invention does not necessarily achieve all of the objects listed above and the other objects.

### Means for Solving the Problems

(1)

One embodiment of the present invention is a display apparatus including a first layer and a second layer positioned above the first layer. The first layer includes a substrate and a plurality of circuit regions, and the second layer includes a plurality of display regions. In addition, each of the plurality of circuit regions includes a driver circuit, and the driver circuit includes a transistor including low-temperature polysilicon in a channel formation region. Each of the plurality of display regions includes a display pixel, and the display pixel includes a transistor including a metal oxide in a channel formation region and a light-emitting device. The driver circuit included in one of the plurality of circuit regions has a function of driving the display pixel included in one of the plurality of display regions. In this manner, the display apparatus can display images on at least two of the plurality of display regions at different frame frequencies.

(2)

In the above (1), another embodiment of the present invention may have a structure in which the one of the plurality of circuit regions and the one of the plurality of display regions are positioned in a region where they overlap with each other in a plan view.

(3)

In the above (1) or (2), a wiring may be extended between the first layer and the second layer in a direction perpendicular to the substrate according to another embodiment of the present invention. In particular, it is preferable that the wiring be electrically connected to the display pixel and the driver circuit.

(4)

In any one of the above (1) to (3), the substrate may be a glass substrate according to another embodiment of the present invention.

(5)

Another embodiment of the present invention is an electronic device including the display apparatus according to any one of the above (1) to (4) and a housing.

### Effect of the Invention

One embodiment of the present invention can provide a display apparatus with high definition and a large diagonal size. Another embodiment of the present invention can provide an electronic device including the above-described display apparatus. Another embodiment of the present invention can provide a novel display apparatus or a novel electronic device.

Note that the effects of one embodiment of the present invention are not limited to the effects listed above. The effects listed above do not preclude the presence of other effects. Note that the other effects are effects that are not described in this section and will be described below. The effects that are not described in this section can be derived from the description of the specification, the drawings, and the like and can be extracted as appropriate from the description by those skilled in the art. Note that one embodiment of the present invention has at least one of the effects listed above and the other effects. Accordingly, depending on the case, one embodiment of the present invention does not have the effects listed above.

### BRIEF DESCRIPTION OF THE DRAWINGS

FIG. 1A and FIG. 1B are schematic cross-sectional views illustrating structure examples of a display apparatus.

FIG. 2A is a schematic plan view illustrating an example of a display portion of a display apparatus, and FIG. 2B is a schematic plan view illustrating an example of a driver circuit region of the display apparatus.

FIG. 3 is a block diagram illustrating a structure example of a display apparatus.

FIG. 4A and FIG. 4B are schematic top views illustrating structure examples of a display apparatus.

FIG. 5 is a block diagram illustrating a structure example of a display apparatus.

FIG. 6 is a schematic cross-sectional view illustrating a structure example of a display apparatus.

FIG. 7A and FIG. 7B is cross-sectional views each illustrating an example of a transistor. FIG. 7C to FIG. 7E are cross-sectional views illustrating examples of a display apparatus.

FIG. 8 is a schematic cross-sectional view illustrating a structure example of a display apparatus.

FIG. 9 is a schematic cross-sectional view illustrating a structure example of a display apparatus.

FIG. 10 is a schematic cross-sectional view illustrating a structure example of a display apparatus.

FIG. 11A to FIG. 11F are diagrams each illustrating a structure example of a light-emitting device.

FIG. 12A to FIG. 12C are diagrams each illustrating a structure example of a light-emitting device.

FIG. 13A is a circuit diagram illustrating a structure example of a pixel circuit included in a display apparatus and FIG. 13B a schematic perspective view illustrating the structure example of the pixel circuit included in the display apparatus.

FIG. 14A to FIG. 14D are circuit diagrams each illustrating a configuration example of a pixel circuit included in a display apparatus.

FIGS. 15A to 15D are circuit diagrams each illustrating a configuration example of a pixel circuit included in a display apparatus.

FIG. 16A to FIG. 16G are plan views each illustrating an example of a pixel.

FIG. 17A to FIG. 17F are plan views each illustrating an example of a pixel.

FIG. 18A to FIG. 18H are plan views each illustrating an example of a pixel.

FIG. 19A to FIG. 19D are plan views each illustrating an example of a pixel.

FIG. 20A and FIG. 20B are diagrams illustrating a structure example of a display apparatus.

FIG. 21A to FIG. 21F are diagrams illustrating structure examples of electronic devices.

FIG. 22A to FIG. 22D are diagrams illustrating structure examples of electronic devices.

FIG. 23A to FIG. 23C are diagrams illustrating structure examples of electronic devices.

FIG. 24A to FIG. 24H are diagrams illustrating structure examples of electronic devices.

### MODE FOR CARRYING OUT THE INVENTION

In this specification and the like, a semiconductor device refers to a device that utilizes semiconductor characteristics, and means a circuit including a semiconductor element (e.g., a transistor, a diode, and a photodiode), or a device including the circuit. The semiconductor device also means all devices that can function by utilizing semiconductor characteristics. For example, an integrated circuit, a chip including an integrated circuit, and an electronic component including a chip in a package are each an example of the semiconductor device. Moreover, for example, a memory device, a display apparatus, a light-emitting apparatus, a lighting device, an electronic device, and the like themselves are semiconductor devices and include semiconductor devices in some cases.

In the case where there is description “X and Y are connected” in this specification and the like, a case where X and Y are electrically connected, a case where X and Y are functionally connected, and a case where X and Y are directly connected are regarded as being disclosed in this specification and the like. Accordingly, without being limited to a predetermined connection relation, for example, a connection relation shown in drawings or described with texts, a connection relation other than one shown in drawings or described with texts is regarded as being disclosed in the drawings or description with the texts. Each of X and Y denotes an object (e.g., a device, an element, a circuit, a wiring, an electrode, a terminal, a conductive film, a layer, or the like).

For example, in the case where X and Y are electrically connected, one or more elements that allow electrical connection between X and Y (e.g., a switch, a transistor, a capacitor, an inductor, a resistor, a diode, a display device, a light-emitting device, and a load) can be connected between X and Y. Note that a switch has a function of being controlled to be turned on or off. That is, the switch has a function of being in a conducting state (on state) or a non-conducting state (off state) to control whether current flows or not.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit such as a step-up circuit or a step-down circuit, or a level shifter circuit for changing the potential level of a signal); a voltage source; a current source; a switching circuit; an amplifier circuit (e.g., a circuit that can increase signal amplitude, the amount of current, or the like, an operational amplifier, a differential amplifier circuit, a source follower circuit, or a buffer circuit); a signal generation circuit; a memory circuit; or a control circuit) can be connected between X and Y. For instance, even if another circuit is provided between X and Y, X and Y are regarded as being functionally connected when a signal output from X is transmitted to Y.

Note that an explicit description “X and Y are electrically connected” includes the case where X and Y are electrically connected (i.e., the case where X and Y are connected with another element or another circuit provided therebetween) and the case where X and Y are directly connected (i.e., the case where X and Y are connected without another element or another circuit provided therebetween).

This specification describes a circuit structure in which a plurality of elements are electrically connected to a wiring (a wiring for supplying a constant potential or a wiring for transmitting a signal). For example, in the case where X is directly connected to a wiring and Y is directly connected to the wiring, this specification may describe that X and Y are directly electrically connected to each other.

It can be expressed as, for example, “X, Y, a source (sometimes called one of a first terminal and a second terminal) of a transistor, and a drain (sometimes called the other of the first terminal and the second terminal) of the transistor are electrically connected to each other, and X, the source of the transistor, the drain of the transistor, and Y are electrically connected to each other in this order”. Alternatively, it can be expressed as “a source of a transistor is electrically connected to X; a drain of the transistor is electrically connected to Y; and X, the source of the transistor, the drain of the transistor, and Y are electrically connected to each other in this order”. Alternatively, it can be expressed as “X is electrically connected to Y through a source and a drain of a transistor, and X, the source of the transistor, the drain of the transistor, and Y are provided in this connection order”. When the connection order in a circuit structure is defined by an expression similar to the above examples, a source and a drain of a transistor can be distinguished from each other to specify the technical scope. Note that these expressions are examples and the expression is not limited to these expressions. Here, each of X and Y denotes an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has both functions of a wiring and an electrode. Thus, electrical connection in this specification includes, in its category, such a case where one conductive film has functions of a plurality of components.

In this specification and the like, a “resistor” can be, for example, a circuit element having a resistance value higher than 0Ω or a wiring having a resistance value higher than 0Ω. Therefore, in this specification and the like, a “resistor” includes a wiring having a resistance value, a transistor in which current flows between a source and a drain, a diode, and a coil. Thus, the term “resistor” can be sometimes replaced with the terms “resistance”, “load”, “region having a resistance value”, or the like. Conversely, the term “resistor”, “load”, or “region having a resistance value” can be sometimes replaced with the term “resistor”. The resistance value can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. As another example, the resistance value may be higher than or equal to 1Ω and lower than or equal to 1×10⁹Ω.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. The term “capacitor”, “parasitic capacitance”, or “gate capacitance” can be replaced with the term “capacitance” in some cases. Conversely, the term “capacitance” can be replaced with the term “capacitor”, “parasitic capacitance”, or “gate capacitance” in some cases. In addition, a “capacitor” (including a “capacitor” with three or more terminals) includes an insulator and a pair of conductors between which the insulator is interposed. Thus, the term “pair of conductors” of “capacitor” can be replaced with “pair of electrodes”, “pair of conductive regions”, “pair of regions”, or “pair of terminals”. In addition, the terms “one of a pair of terminals” or “the other of the pair of terminals” is referred to as a first terminal or a second terminal in some cases. Note that the electrostatic capacitance value can be higher than or equal to 0.05 fF and lower than or equal to 10 pF, for example. For another example, the electrostatic capacitance value may be higher than or equal to 1 pF and lower than or equal to 10 μF.

In this specification and the like, a transistor includes three terminals called a gate, a source, and a drain. The gate is a control terminal for controlling the conducting state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source” and “drain” can sometimes be replaced with each other in this specification and the like. In this specification and the like, expressions “one of a source and a drain” (or a first electrode or a first terminal) and “the other of the source and the drain” (or a second electrode or a second terminal) are used in description of the connection relation of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, and a third gate in this specification and the like.

In this specification and the like, for example, a transistor with a multi-gate structure having two or more gate electrodes can be used as the transistor. With the multi-gate structure, channel formation regions are connected in series; accordingly, a plurality of transistors are connected in series. Thus, with the multi-gate structure, the amount of off-state current can be reduced, and the withstand voltage of the transistor can be increased (the reliability can be improved). Alternatively, with the multi-gate structure, drain-source current does not change very much even if drain-source voltage changes at the time of an operation in a saturation region, so that a flat slope of voltage-current characteristics can be obtained. By utilizing the flat slope of the voltage-current characteristics, an ideal current source circuit or an active load having an extremely high resistance value can be obtained. Accordingly, a differential circuit, a current mirror circuit, and the like having excellent properties can be obtained.

In this specification and the like, circuit elements such as a “light-emitting device” and a “light-receiving device” sometimes have polarities called an “anode” and a “cathode”. In the case of a “light-emitting device”, the “light-emitting device” can sometimes emit light when a forward bias is applied (a positive potential with respect to a “cathode” is applied to an “anode”). In the case of a “light-receiving device”, current is sometimes generated between an “anode” and a “cathode” when a zero bias or a reverse bias is applied (a negative potential with respect to a “cathode” is applied to an “anode”) and the “light-receiving device” is irradiated with light. As described above, an “anode” and a “cathode” are sometimes regarded as input/output terminals of the circuit elements such as a “light-emitting device” and a “light-receiving device”. In this specification and the like, an “anode” and a “cathode” of the circuit element such as a “light-emitting device” or a “light-receiving device” are sometimes called terminals (a first terminal, a second terminal, and the like). For example, one of an “anode” and a “cathode” is called a first terminal and the other of the “anode” and the “cathode” is called a second terminal in some cases.

The case where a single circuit element is illustrated in a circuit diagram may include a case where the circuit element includes a plurality of circuit elements. For example, the case where a single resistor is illustrated in a circuit diagram may include a case where two or more resistors are electrically connected to each other in series. For another example, the case where a single capacitor is illustrated in a circuit diagram may include a case where two or more capacitors are electrically connected to each other in parallel. For another example, the case where a single transistor is illustrated in a circuit diagram may include a case where two or more transistors are electrically connected to each other in series and their gates are electrically connected to each other. Similarly, for another example, the case where a single switch is illustrated in a circuit diagram may include a case where the switch includes two or more transistors which are electrically connected to each other in series or in parallel and whose gates are electrically connected to each other.

In this specification and the like, a node can be referred to as a terminal, a wiring, an electrode, a conductive layer, a conductor, or an impurity region depending on the circuit structure and the device structure. Furthermore, a terminal or a wiring can be referred to as a node.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and, for example, a potential supplied to a wiring, a potential applied to a circuit or the like, and a potential output from a circuit or the like change with a change of the reference potential.

In this specification and the like, the terms “high-level potential” and “low-level potential” do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

“Current” means a charge transfer phenomenon (electrical conduction); for example, the description “electrical conduction of positively charged particles occurs” can be rephrased as “electrical conduction of negatively charged particles occurs in the opposite direction”. Therefore, unless otherwise specified, “current” in this specification and the like refers to a charge transfer phenomenon (electrical conduction) accompanied by carrier movement. Examples of a carrier here include an electron, a hole, an anion, a cation, and a complex ion, and the type of carrier differs between current flow systems (e.g., a semiconductor, a metal, an electrolyte solution, or a vacuum). The “direction of current” in a wiring or the like refers to the direction in which a carrier with a positive charge moves, and the amount of current is expressed as a positive value. In other words, the direction in which a carrier with a negative charge moves is opposite to the direction of current, and the amount of current is expressed as a negative value. Thus, in the case where the polarity of current (or the direction of current) is not specified in this specification and the like, the description “current flows from element A to element B” can be rephrased as a description “current flows from element B to element A”. The description “current is input to element A” can be rephrased as a description “current is output from element A”.

Ordinal numbers such as “first”, “second”, and “third” in this specification and the like are used to avoid confusion among components. Thus, the ordinal numbers do not limit the number of components. In addition, the ordinal numbers do not limit the order of components. In this specification and the like, for example, a “first” component in one embodiment can be referred to as a “second” component in other embodiments or the scope of claims. For another example, a “first” component in one embodiment in this specification and the like can be omitted in other embodiments or the scope of claims.

In this specification and the like, the terms for describing positioning, such as “over” and “under”, are sometimes used for convenience to describe the positional relation between components with reference to drawings. The positional relation between components is changed as appropriate in accordance with the direction in which the components are described. Thus, the positional relation is not limited to the terms described in the specification and the like, and can be described with another term as appropriate depending on the situation. For example, the expression “an insulator positioned over (on) the top surface of a conductor” can be replaced with the expression “an insulator positioned under (on) a bottom surface of a conductor” when the direction of a drawing showing these components is rotated by 180°.

Furthermore, the terms “over” and “under” do not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B. Similarly, for example, the expression “electrode B above insulating layer A” does not necessarily mean that the electrode B is formed above and in direct contact with the insulating layer A, and does not exclude the case where another component is provided between the insulating layer A and the electrode B. Similarly, for example, the expression “electrode B under insulating layer A” does not necessarily mean that the electrode B is formed under and in direct contact with the insulating layer A, and does not exclude the case where another component is provided between the insulating layer A and the electrode B.

In this specification and the like, components arranged in a matrix and their positional relation are sometimes described using terms such as “row” and “column”. The positional relation between components is changed as appropriate in accordance with the direction in which the components are described. Thus, the positional relation is not limited to the terms described in the specification and the like, and can be described with another term as appropriate depending on the situation. For example, the term “row direction” can be replaced with the term “column direction” when the direction of the diagram is rotated by 90°.

In this specification and the like, the terms “film” and “layer” can be interchanged with each other depending on the situation. For example, the term “conductive layer” can be changed into the term “conductive film” in some cases. For another example, the term “insulating film” can be changed into the term “insulating layer” in some cases. Alternatively, the terms “film” and “layer” are not used and can be interchanged with another term depending on the case or the situation. For example, the term “conductive layer” or “conductive film” can be changed into the term “conductor” in some cases. For another example, the term “insulating layer” or “insulating film” can be changed into the term “insulator” in some cases.

In this specification and the like, the terms “electrode”, “wiring”, “terminal”, and the like do not limit the functions of such components. For example, an “electrode” is used as part of a “wiring” in some cases, and vice versa. Furthermore, the term “electrode” or “wiring” also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also includes the case where a plurality of “electrodes”, “wirings” or “terminals” are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, or “terminal” is sometimes replaced with the term “region” depending on the case.

In this specification and the like, the terms “wiring”, “signal line”, and “power supply line” can be interchanged with each other depending on the case or the situation. For example, the term “wiring” can be changed into the term “signal line” in some cases. As another example, the term “wiring” can be changed into the term “power supply line” or the like in some cases. Conversely, the term “signal line” or “power supply line” can be changed into the term “wiring” in some cases. The term “power supply line” can be changed into the term “signal line” in some cases. Conversely, the term “signal line” can be changed into the term “power supply line” in some cases. The term “potential” that is applied to a wiring can be changed into the term “signal” depending on the case or the situation. Conversely, the term “signal” can be changed into the term “potential” in some cases.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is included in a channel formation region of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS transistor is mentioned, the OS transistor can also be referred to as a transistor including a metal oxide or an oxide semiconductor.

In this specification and the like, a metal oxide containing nitrogen is also collectively referred to as a metal oxide in some cases. A metal oxide containing nitrogen may be called a metal oxynitride.

In this specification and the like, an impurity in a semiconductor refers to, for example, an element other than a main component of a semiconductor layer. For example, an element with a concentration of lower than 0.1 atomic % is an impurity. When an impurity is contained, for example, at least one of an increase in the density of defect states in a semiconductor, a decrease in carrier mobility, and a decrease in crystallinity occurs in some cases. In the case where the semiconductor is an oxide semiconductor, examples of an impurity that changes characteristics of the semiconductor include Group 1 elements, Group 2 elements, Group 13 elements, Group 14 elements, Group 15 elements, and transition metals other than the main components; specific examples are hydrogen (contained also in water), lithium, sodium, silicon, boron, phosphorus, carbon, and nitrogen. In addition, in the case where the semiconductor is a silicon layer, examples of an impurity that changes characteristics of the semiconductor include Group 1 elements, Group 2 elements, Group 13 elements, and Group 15 elements (except oxygen and hydrogen).

In this specification and the like, a switch has a function of being in a conducting state (on state) or a non-conducting state (off state) to control whether current flows or not. Alternatively, a switch has a function of selecting and changing a current path. Thus, a switch may have two terminals or three or more terminals through which current flows, in addition to a control terminal. For example, an electrical switch or a mechanical switch can be used. That is, a switch can be any element capable of controlling a current, and is not limited to a particular element.

Examples of an electrical switch include a transistor (e.g., a bipolar transistor and a MOS transistor), a diode (e.g., a PN diode, a PIN diode, a Schottky diode, a MIM (Metal Insulator Metal) diode, a MIS (Metal Insulator Semiconductor) diode, and a diode-connected transistor), and a logic circuit in which such elements are combined. Note that in the case of using a transistor as a switch, a “conducting state” of the transistor refers to a state where a source electrode and a drain electrode of the transistor can be regarded as being electrically short-circuited or a state where current can flow between the source electrode and the drain electrode. Furthermore, a “non-conducting state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

An example of a mechanical switch is a switch using a MEMS (micro electro mechanical systems) technology. Such a switch includes an electrode that can be moved mechanically and controls conduction and non-conduction with movement of the electrode.

In this specification and the like, a device formed using a metal mask or an FMM (fine metal mask, high-resolution metal mask) may be referred to as a device having an MM (metal mask) structure. In this specification and the like, a device formed without using a metal mask or an FMM may be referred to as a device having an MML (metal maskless) structure.

In this specification and the like, a structure in which light-emitting layers in light-emitting devices of different colors (here, blue (B), green (G), and red (R)) are separately formed or separately patterned may be referred to as an SBS (Side By Side) structure. In this specification and the like, a light-emitting device capable of emitting white light may be referred to as a white-light-emitting device. Note that a combination of white-light-emitting devices with coloring layers (e.g., color filters) enables a full-color display apparatus.

Light-emitting devices can be classified roughly into a single structure and a tandem structure. A device with a single structure includes one light-emitting unit between a pair of electrodes, and the light-emitting unit preferably includes one or more light-emitting layers. When white light emission is obtained using two light-emitting layers, the two light-emitting layers are selected such that emission colors of the light-emitting layers are complementary colors. For example, when an emission color of a first light-emitting layer and an emission color of a second light-emitting layer are complementary colors, a light-emitting device can be configured to emit white light as a whole. When white light emission is obtained using three or more light-emitting layers, a light-emitting device is configured to emit white light as a whole by combining emission colors of the three or more light-emitting layers.

A device with a tandem structure includes two or more light-emitting units between a pair of electrodes, and each light-emitting unit preferably includes one or more light-emitting layers. To obtain white light emission, the structure can be made such that light from light-emitting layers of the plurality of light-emitting units can be combined to be white light. Note that a structure for obtaining white light emission is similar to that in the case of a single structure. In the device with a tandem structure, an intermediate layer such as a charge-generation layer is preferably provided between the plurality of light-emitting units.

When the above white-light-emitting device (having a single structure or a tandem structure) and the above light-emitting device having an SBS structure are compared to each other, the light-emitting device having an SBS structure can have lower power consumption than the white-light-emitting device. The light-emitting device having an SBS structure is suitably used in the case where the power consumption is required to be low. Meanwhile, the white-light-emitting device is suitable in terms of lower manufacturing cost or higher manufacturing yield because the manufacturing process of the white-light-emitting device is simpler than that of the light-emitting device having an SBS structure.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In this specification and the like, one embodiment of the present invention can be constituted by appropriately combining a structure described in an embodiment with any of the structures described in the other embodiments. In addition, in the case where a plurality of structure examples are described in one embodiment, the structure examples can be combined as appropriate.

Note that a content (or part of the content) described in one embodiment can be applied to, combined with, or replaced with at least one of another content (or part of the content) in the embodiment and a content (or part of the content) described in one or a plurality of different embodiments.

Note that in each embodiment, a content described in the embodiment is a content described using a variety of diagrams or a content described with text disclosed in the specification.

Note that by combining a diagram (or part thereof) described in one embodiment with at least one of another part of the diagram, a different diagram (or part thereof) described in the embodiment, and a diagram (or part thereof) described in one or a plurality of different embodiments, much more diagrams can be provided.

Embodiments described in this specification are described with reference to the drawings. Note that the embodiments can be implemented in many different modes, and it will be readily appreciated by those skilled in the art that modes and details can be changed in various ways without departing from the spirit and scope thereof. Therefore, the present invention should not be interpreted as being limited to the description in the embodiments. Note that in the structures of the invention in the embodiments, the same portions or portions having similar functions are denoted by the same reference numerals in different drawings, and repeated description thereof is omitted in some cases. In perspective views and the like, illustration of some components may be omitted for clarity of the drawings.

In this specification, a plan view is sometimes used to explain a structure in each embodiment. A plan view is, for example, a diagram showing a plane of a structure seen in a direction perpendicular to a horizontal plane or a diagram showing a plane (section) of a structure cut in a horizontal direction (any of the planes is sometimes referred to as a plan view). Hidden lines (e.g., dashed lines) shown in a plan view can indicate the positional relation between a plurality of components included in a structure or the overlapping relation between the plurality of components. In this specification and the like, the term “plan view” can be replaced with the term “projection view”, “top view”, or “bottom view”. A plane (section) of a structure cut in a direction other than the horizontal direction may be referred to as a plan view depending on circumstances.

In this specification, a cross-sectional view is sometimes used to explain a structure in each embodiment. A cross-sectional view is, for example, a diagram showing a plane of a structure seen in a direction perpendicular to a horizontal plane or a diagram showing a plane (section) of a structure cut in a direction perpendicular to a horizontal plane (any of the planes is sometimes referred to as a cross-sectional view). In this specification and the like, the term “cross-sectional view” can be replaced with the term “front view” or “side view”. A plane (section) of a structure cut in a direction other than the perpendicular direction may be referred to as a cross-sectional view depending on circumstances.

In this specification and the like, when a plurality of components are denoted with the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes described without such identification signs in this specification and the like when the components do not need to be distinguished from each other.

In the drawings in this specification, the size, the layer thickness, or the region is exaggerated for clarity in some cases. Therefore, they are not limited to the illustrated scale. The drawings are schematic views showing ideal examples, and embodiments of the present invention are not limited to shapes, values, or the like shown in the drawings. For example, variations in signal, voltage, or current due to noise, variations in signal, voltage, or current due to difference in timing, or the like can be included.

### Embodiment 1

In this embodiment, a display apparatus of one embodiment of the present invention will be described.

### Structure Example of Display Apparatus

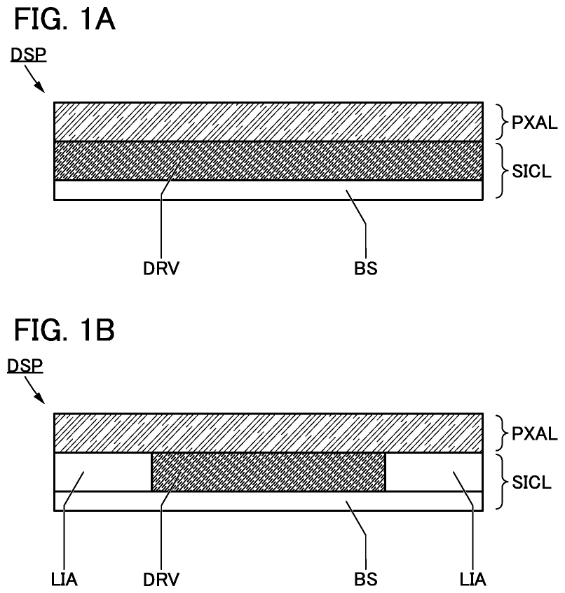

FIG. 1A is a schematic cross-sectional view of the display apparatus of one embodiment of the present invention. The display apparatus DSP illustrated in FIG. 1A includes a pixel layer PXAL and a circuit layer SICL as an example.

The pixel layer PXAL is provided over the circuit layer SICL. Note that the pixel layer PXAL overlaps with a region including a driver circuit region DRV described later.

The circuit layer SICL includes a substrate BS and the driver circuit region DRV.

As the substrate BS, for example, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, paper or a base material film including a fibrous material can be used. Examples of the glass substrate include barium borosilicate glass, aluminoborosilicate glass, and soda lime glass. Examples of the flexible substrate, the attachment film, the base material film, and the like, include plastics typified by polyethylene terephthalate (PET), polyethylene naphthalate (PEN), polyether sulfone (PES), and polytetrafluoroethylene (PTFE). Another example is a synthetic resin such as an acrylic resin. Other examples include polypropylene, polyester, polyvinyl fluoride, and polyvinyl chloride. Other examples include polyamide, polyimide, aramid, an epoxy resin, an inorganic vapor deposition film, and paper. Note that in the case where the manufacturing process of the display apparatus DSP includes heat treatment, a highly heat-resistant material is preferably selected for the substrate BS.

Note that in this embodiment, the substrate BS is described as a substrate including a material with high resistance to heat, such as a glass substrate.

The driver circuit region DRV is provided over the substrate BS.

The driver circuit region DRV includes, for example, a driver circuit for driving a pixel included in the pixel layer PXAL to be described later. Note that a specific structure example of the driver circuit region DRV will be described later.

The pixel layer PXAL includes, for example, a plurality of pixels. The plurality of pixels may be arranged in a matrix in the pixel layer PXAL.

Each of the plurality of pixels can express one color or a plurality of colors. In particular, the plurality of colors can be, for example, three colors of red (R), green (G), and blue (B). Alternatively, the plurality of colors may be one or more of, for example, red (R), green (G), blue (B), cyan (C), magenta (M), yellow (Y), and white (W). Note that in the case where each of pixels expressing different colors is called a subpixel and white is expressed by a plurality of subpixels expressing different colors, the plurality of subpixels are collectively called a pixel in some cases. In this specification and the like, a subpixel is referred to as a pixel for convenience in some cases.

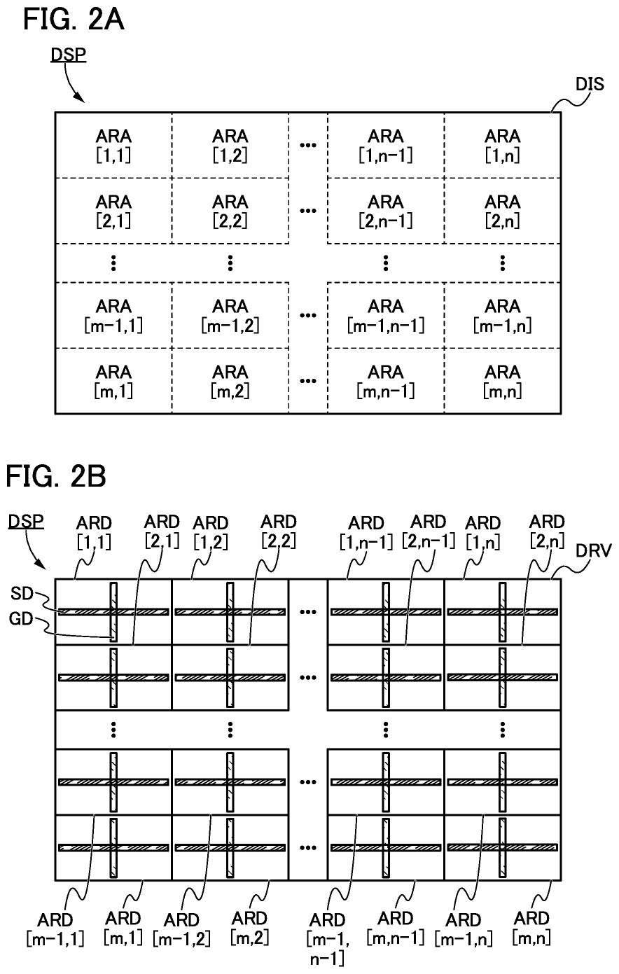

FIG. 2A is an example of a top view of the display apparatus DSP and illustrates only a display portion DIS. Note that the display portion DIS can be a top view of the pixel layer PXAL.

In the display apparatus DSP in FIG. 2A, the display portion DIS is divided into regions in m rows and n columns (m is an integer greater than or equal to 1, and n is an integer greater than or equal to 1) as an example. Thus, the display portion DIS includes a display region ARA[1,1] to a display region ARA[m,n]. Note that FIG. 2A selectively illustrates the display region ARA[1,1], the display region ARA[2,1], the display region ARA[m-1,1], the display region ARA[m,1], the display region ARA[1,2], the display region ARA[2,2], the display region ARA[m-1,2], the display region ARA[m,2], the display region ARA[1,n-1], the display region ARA[2,n-1], the display region ARA[m-1,n-1], ARA[m,n-1], the display region ARA[1,n], the display region ARA[2,n], the display region ARA[m-1,n], and the display region ARA[m,n], as an example.

For example, in the case where the display portion DIS is divided into 32 regions, m=4 and n=8 may be substituted into FIG. 2A. In the case where the display apparatus DSP has a screen resolution of 8K4K, the number of pixels is 7680×4320. In the case where the colors of subpixels of the display portion DIS are three colors, red (R), green (G), and blue (B), the total number of subpixels is 7680×4320×3. Here, in the case where a pixel array of the display portion DIS with a screen resolution of 8K4K is divided into 32 regions, the number of pixels per region is 960×1080, and when the colors of the subpixels of the display apparatus DSP are three colors, red (R), green (G), and blue (B), the number of subpixels per region is 960×1080×3.

Here, in the case where the display portion DIS of the display apparatus DSP in FIG. 2A is divided into regions in m rows and n columns, the driver circuit region DRV included in the circuit layer SICL is considered.

FIG. 2B is an example of a plan view of the display apparatus DSP, and illustrates only the driver circuit region DRV included in the circuit layer SICL.

Since the display portion DIS in the display apparatus DSP in FIG. 2A is divided into regions in m rows and n columns, each of the divided display regions ARA[1,1] to ARA[m,n] needs a corresponding driver circuit. Specifically, the driver circuit region DRV may also be divided into regions in m rows and n columns and a driver circuit may be provided in each of the divided regions.

The driver circuit region DRV in the display apparatus DSP in FIG. 2B includes regions divided into m rows and n columns. Thus, the driver circuit region DRV includes a circuit region ARD[1,1] to a circuit region ARD[m,n]. Note that FIG. 2B selectively illustrates the circuit region ARD[1,1], the circuit region ARD[2,1], the circuit region ARD[m-1,1], the circuit region ARD[m,1], the circuit region ARD[1,2], the circuit region ARD[2,2], the circuit region ARD[m-1,2], the circuit region ARD[m,2], the circuit region ARD[1,n-1], the circuit region ARD[2,n-1], the circuit region ARD[m-1,n-1], the circuit region ARD[m,n-1], the circuit region ARD[1,n], the circuit region ARD[2,n], the circuit region ARD[m-1,n], and the circuit region ARD[m,n], as an example.

Each of the circuit region ARD[1,1] to the circuit region ARD[m,n] includes a driver circuit SD and a driver circuit GD. For example, the driver circuit SD and the driver circuit GD included in a circuit region ARD[i,j] (not illustrated in FIG. 2B) positioned in the i-th row and the j-th column (i is an integer greater than or equal to 1 and less than or equal to m, and j is an integer greater than or equal to 1 and less than or equal to n) can drive a plurality of pixels included in the display region ARA[i,j] positioned in the i-th row and the j-th column (not illustrated in FIG. 2A) in the display portion DIS.

The driver circuit SD serves as, for example, a source driver circuit that transmits image signals to a plurality of pixels included in the corresponding circuit region ARD. The driver circuit SD may include a digital-analog conversion circuit that converts digital data of an image signal to analog data.

The driver circuit GD serves as, for example, a gate driver circuit that selects a plurality of pixels, which are destinations to which image signals are transmitted, in the corresponding circuit region ARD.

In FIG. 2A and FIG. 2B, the display region ARA[i,j] and the circuit region ARD[i,j] are positioned in a region where the display region ARA[i,j] and the circuit region ARD[i,j] overlap with each other in the plan view. When the display region ARA[i,j] and the circuit region ARD[i,j] overlap with each other, a wiring electrically connecting the display region ARA[i,j] and the circuit region ARD[i,j] can be shortened, so that the parasitic resistance of the wiring can be reduced. Furthermore, shortening the wiring can reduce parasitic capacitance of the wiring, and thus the time constant of the wiring can be decreased. When the time constant of the wiring is decreased, the time for writing an image to be displayed on the display region ARA[i,j] can be shortened, and the frame frequency can be consequently increased.

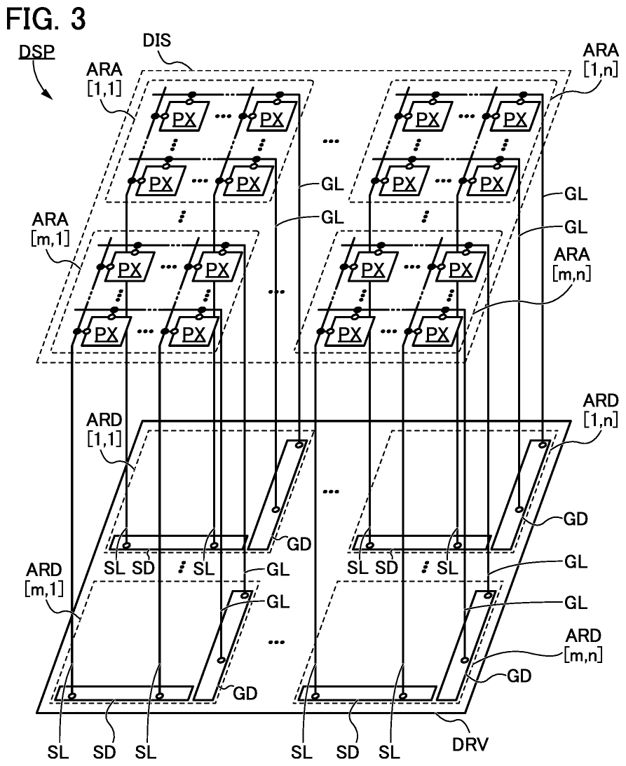

FIG. 3 is a perspective view of the display apparatus DSP illustrated in FIG. 2A and FIG. 2B. FIG. 3 selectively illustrates the display region ARA[1,1], the display region ARA[m, 1], the display region ARA[1,n], and the display region ARA[m,n] as the display region ARA, and selectively illustrates the circuit region ARD[1,1], the circuit region ARD[m,1], the circuit region ARD[1,n], and the circuit region ARD[m,n] as the circuit region ARD.

In the display apparatus DSP in FIG. 3, each of the plurality of display regions ARA includes a plurality of pixels PX, for example. In the display region ARA, the plurality of pixels PX are arranged in a matrix.

In each of the plurality of display regions ARA, a plurality of wirings GL are extended in the row direction and a plurality of wirings SL are extended in the column direction.

Each of the plurality of pixels PX arranged in a matrix in the display region ARA is electrically connected to the wiring GL in the corresponding row. Similarly, each of the plurality of pixels PX is electrically connected to the wiring SL in the corresponding column. In the display apparatus DSP in FIG. 3, each of the plurality of circuit regions ARD includes the driver circuit SD and the driver circuit GD as in the display apparatus DSP illustrated in FIG. 2B.

As described with reference to FIG. 2A and FIG. 2B, the driver circuit SD and the driver circuit GD included in the circuit region ARD[i,j] have a function of driving a plurality of pixels included in the display region ARA[i,j]. Thus, the driver circuit SD included in the circuit region ARD[i,j] is electrically connected to a plurality of wirings SL extending in the display region ARA[i,j]. The driver circuit GD included in the circuit region ARD[i,j] is electrically connected to a plurality of wirings GL extended to the display region ARA[i,j].

In order to electrically connect the display region ARA[i,j] and the circuit region ARD[i,j], the plurality of wirings SL and the plurality of wirings GL are provided between the display portion DIS and the driver circuit region DRV.

When the display region ARA[i,j] and the circuit region ARD[i,j] are arranged so as to overlap with each other, the wiring electrically connecting the display region ARA[i,j] and the circuit region ARD[i,j] to each other can be extended in the direction perpendicular or substantially perpendicular to the substrate BS, for example. When the wiring is extended in the perpendicular direction or substantially perpendicular direction, the length of the wiring can be shortened; thus, the parasitic resistance of the wiring can be reduced as described above. In addition, the parasitic capacitance of the wiring can be reduced. Accordingly, a voltage for supplying current to the wiring can be reduced, leading to reduced power consumption.

Note that the display apparatus DSP illustrated in FIG. 1A, FIG. 2A, FIG. 2B, and FIG. 3 has a structure in which the display region ARA[i,j] and the circuit region ARD[i,j] overlap with each other in the display portion DIS; however, the display apparatus of one embodiment of the present invention is not limited to the structure. In a structure of the display apparatus of one embodiment of the present invention, the display region ARA[i,j] and the circuit region ARD[i,j] do not necessarily overlap with each other.

For example, as illustrated in FIG. 1B, the display apparatus DSP may have a structure in which not only the driver circuit region DRV but also a region LIA is provided over the substrate BS.

A wiring is provided in the region LIA, as an example. At this time, the display apparatus DSP may have a structure in which a circuit included in the driver circuit region DRV and a circuit included in the pixel layer PXAL are electrically connected to each other through the wiring included in the region LIA.

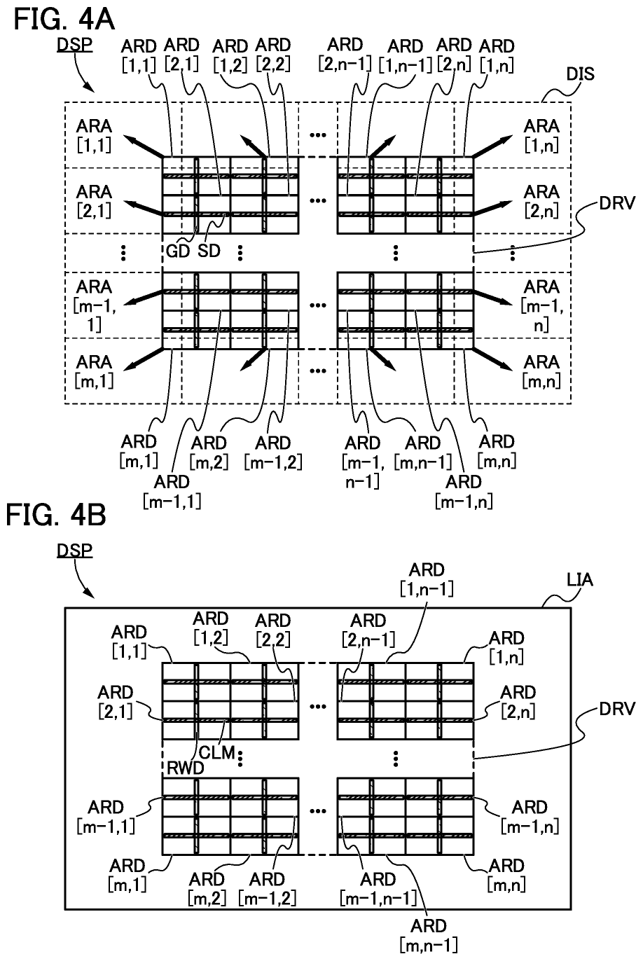

FIG. 4A is an example of a plan view of the display apparatus DSP illustrated in FIG. 1B, and illustrates the driver circuit region DRV denoted by a solid line and the display portion DIS denoted by a dotted line. In the display apparatus DSP in FIG. 4A, a structure where the driver circuit region DRV is surrounded by the region LIA is illustrated as an example, (FIG. 4B is an example of a plan view of the display apparatus DSP and illustrates only the circuit layer SICL). Thus, as illustrated in FIG. 4A, the driver circuit region DRV is provided to overlap with the inside of the display portion DIS in the plan view.

In the display apparatus DSP illustrated in FIG. 4A, the display portion DIS is divided into the display region ARA[1,1] to the display region ARA[m,n] and the driver circuit region DRV is also divided into the circuit region ARD[1,1] to the circuit region ARD[m,n] as in FIG. 2A.

As illustrated in FIG. 4A, a correspondence between the display region ARA and the circuit region ARD including a driver circuit that drives a pixel included in the display region ARA is shown by a thick arrow. Specifically, a driver circuit included in the circuit region ARD[1,1] drives a pixel included in the display region ARA[1,1], and a driver circuit included in the circuit region ARD[2,1] drives a pixel included in the display region ARA[2,1]. A driver circuit included in the circuit region ARD[m-1,1] drives a pixel included in the display region ARA[m-1,1], and a driver circuit included in the circuit region ARD[m, 1] drives a pixel included in the display region ARA[m,1]. A driver circuit included in the circuit region ARD[1,n] drives a pixel included in the display region ARA[1,n], and a driver circuit included in the circuit region ARD[2,n] drives a pixel included in the display region ARA[2,n]. A driver circuit included in the circuit region ARD[m-1,n] drives a pixel included in the display region ARA[m-1,n], and a driver circuit included in the circuit region ARD[m,n] drives a pixel included in the display region ARA[m,n]. That is, although not illustrated in FIG. 4A, a driver circuit included in the circuit region ARD[i,j] positioned in the i-th row and the j-th column drives a pixel included in the display region ARA[i,j].

In FIG. 1B, when the driver circuit included in the circuit region ARD in the circuit layer SICL and the pixel included in the display region ARA in the pixel layer PXAL are electrically connected through a wiring, the display apparatus DSP can have a structure in which the display region ARA[i,j] and the circuit region ARD[i,j] do not necessarily overlap with each other. Accordingly, the positional relation between the driver circuit region DRV and the display portion DIS is not limited to the plan view of the display apparatus DSP in FIG. 4A, and the position of the driver circuit region DRV can be freely determined.

Note that in FIG. 2B and FIG. 4A, the driver circuit SD and the driver circuit GD are arranged so as to form a cross in each of the circuit region ARD[1,1] to the circuit region ARD[m,n]; however, the arrangement of the driver circuit SD and the driver circuit GD is not limited to the structure of the display apparatus of one embodiment of the present invention. For example, the arrangement of the driver circuit SD and the driver circuit GD may form an L shape in one circuit region ARD in the driver circuit region DRV as illustrated in FIG. 3. Alternatively, one of the driver circuit SD and the driver circuit GD may be placed in upper and lower parts in a plan view and the other of the driver circuit SD and the driver circuit GD may be placed in right and left parts in the plan view.

As illustrated in FIG. 2A to FIG. 4B, the display portion DIS of the display apparatus DSP is divided into the display region ARA[1,1] to the display region ARA[m,n], and the driver circuit SD and the driver circuit GD are provided in the circuit region ARD corresponding to each display region ARA, whereby each of the display region ARA[1, 1] to the display region ARA[m,n] can be independently driven. For example, for the display region ARA in which image data is often rewritten, the driver circuit SD and the driver circuit GD provided in the corresponding circuit region ARD can be driven with a high frame frequency; and for the display region ARA in which image data is not often rewritten, the driver circuit SD and the driver circuit GD provided in the corresponding circuit region ARD can be driven with a low frame frequency. Specifically, the driver circuit SD and the driver circuit GD corresponding to the display region ARA in which image data is often rewritten to display moving images or the like may be driven with a high frame frequency of higher than or equal to 60 Hz, higher than or equal to 120 Hz, higher than or equal to 165 Hz, or higher than or equal to 240 Hz. For example, the driver circuit SD and the driver circuit GD corresponding to the display region ARA in which image data is not often rewritten to display a still image or the like may be driven with a low frame frequency of lower than or equal to 5 Hz, lower than or equal to 1 Hz, lower than or equal to 0.5 Hz, or lower than or equal to 0.1 Hz. In this manner, the display portion DIS of the display apparatus DSP is divided into the display region ARA[1,1] to the display region ARA[m,n], whereby the rewrite frequency (frame frequency) can be changed depending on an image displayed on the display region ARA. That is, in the display portion DIS of the display apparatus DSP, two selected from the display region ARA[1, 1] to the display region ARA[m,n] can display images with different frame frequencies.

When any of a glass substrate, a metal substrate, and a base material film is used as the substrate BS, the diagonal size of the display apparatus DSP can be easily increased as compared with the case of using a semiconductor substrate including silicon or the like as a material. In particular, a substrate having a substrate size such as the second generation (approximately 370 mm×470 mm), the third generation (approximately 550 mm×650 mm), the fourth generation (approximately 680 mm×880 mm), or a substrate size exceeding the fourth generation is selected as the glass substrate, in which case the display apparatus DSP having a diagonal size larger than the diameter (approximately 12 inches) of a silicon wafer mainly used in the current semiconductor process can be manufactured.

### Structure Example of Control Circuit

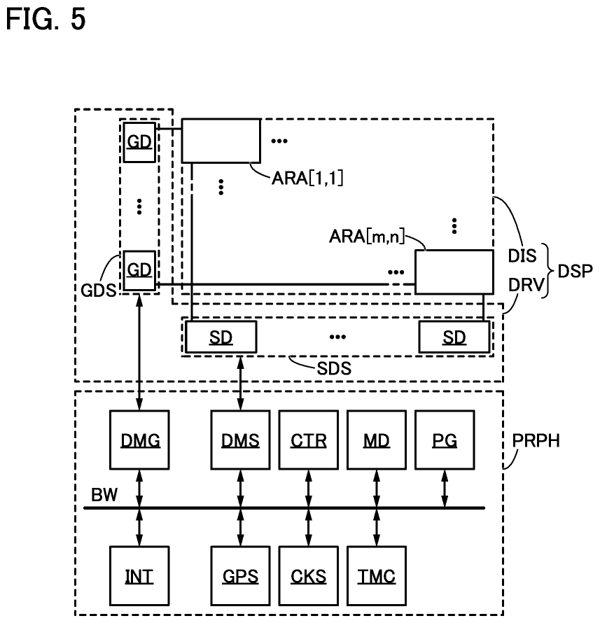

Next, an example of the display apparatus DSP and a control circuit provided outside the display apparatus DSP will be described. FIG. 5 is a block diagram illustrating an example of the display apparatus DSP and a control circuit PRPH.

The display apparatus DSP illustrated in FIG. 5 includes the display portion DIS and the driver circuit region DRV. The driver circuit region DRV includes a circuit GDS including a plurality of driver circuits GD and a circuit SDS including a plurality of driver circuits SD. The control circuit PRPH includes a distribution circuit DMG, a distribution circuit DMS, a control unit CTR, a memory device MD, a voltage generation circuit PG, a timing controller TMC, a clock signal generation circuit CKS, an image processing unit GPS, and an interface INT.

Note that in the display apparatus DSP, the driver circuit region DRV including the plurality of driver circuits GD overlaps with the pixel layer PXAL including the plurality of display regions ARA as illustrated in FIG. 2A to FIG. 4B; however, FIG. 5 illustrates the plurality of driver circuits GD arranged in a column, for convenience. Similarly, the driver circuit region DRV including the plurality of driver circuits SD overlaps with the pixel layer PXAL including the plurality of display regions ARA as illustrated in FIG. 2A to FIG. 4B; however, FIG. 5 illustrates the plurality of driver circuits SD arranged in a row, for convenience.

The control circuit PRPH is electrically connected to the outside of the display apparatus DSP illustrated in FIG. 1A to FIG. 4B, for example.

The distribution circuit DMG, the distribution circuit DMS, the control unit CTR, the memory device MD, the voltage generation circuit PG, the timing controller TMC, the clock signal generation circuit CKS, the image processing unit GPS, and the interface INT transmit and receive signals mutually through a bus wiring BW.

The interface INT has, for example, a function of a circuit for taking image information output from an external device for displaying an image on the display apparatus DSP into the circuit in the control circuit PRPH. Examples of the external device include a recording media player and a nonvolatile memory device such as a hard disk drive (HDD) and a solid state drive (SSD). The interface INT may be a circuit that outputs a signal from a circuit inside the control circuit PRPH to a device outside the display apparatus DSP.

In the case where image information is input from the external device to the interface INT by wireless communication, the interface INT can include, for example, an antenna receiving the image information, a mixer, an amplifier circuit, and an analog-digital conversion circuit. The control unit CTR has functions of processing control signals transmitted from the external device through the interface INT and controlling circuits included in the control circuit PRPH.

The memory device MD has a function of temporarily holding data and an image signal. In that case, the memory device MD serves as a frame memory (sometimes referred to as a frame buffer), for example. The memory device MD may have a function of temporarily holding at least one piece of information transmitted from the external device through the interface INT and information processed in the control unit CTR. In that case, at least one of an SRAM (Static Random Access Memory) and a DRAM (Dynamic Random Access Memory) can be used as the memory device MD, for example.

The voltage generation circuit PG has a function of generating power supply voltages supplied to a pixel circuit included in the display portion DIS and a circuit included in the control circuit PRPH. Note that the power generation circuit PG may have a function of selecting a circuit to which a voltage is to be supplied. For example, the voltage generation circuit PG stops supply of voltage to the circuit GDS, the circuit SDS, the image processing unit GPS, the timing controller TMC, and the clock signal generation circuit CKS in a period in which a still image is displayed on the display portion DIS, enabling a reduction in the total power consumption of the display apparatus DSP.

The timing controller TMC has a function of generating timing signals used in the plurality of driver circuits GD included in the circuit GDS and the plurality of driver circuits SD included in the circuit SDS. For the generation of the timing signal, a clock signal generated by the clock signal generation circuit CKS can be used.

The image processing unit GPS has a function of performing processing for drawing an image on the display portion DIS. For example, the image processing unit GPS may include a GPU (Graphics Processing Unit). Specifically, the image processing unit GPS is configured to perform pipeline processing in parallel and can thus perform high-speed processing of image data to be displayed on the display portion DIS. The image processing unit GPS can also have a function of a decoder for decoding an encoded image.

In FIG. 5, the image processing portion GPS has a function of receiving image data to be displayed on each of the display region ARA[1,1] to the display region ARA[m,n] and generating an image signal from the image data, for example.

The image processing portion GPS may have a function of correcting the color tone of an image displayed on the display region ARA[1, 1] to the display region ARA[m,n]. In that case, the image processing portion GPS is preferably provided with one or both of a dimming circuit and a toning circuit. In the case where the display pixel circuit included in the display portion DIS includes an organic EL element, the image processing portion GPS may be provided with an EL correction circuit.

The above-described image correction may be performed using artificial intelligence. For example, a current flowing in a display device included in a pixel (or a voltage applied to the display device) may be monitored and acquired, an image displayed on the display portion DIS may be acquired with an image sensor or the like, the current (or voltage) and the image may be used as input data in an arithmetic operation of the artificial intelligence (e.g., an artificial neural network), and the output result may be used to determine whether the image is needed to be corrected.

Such an arithmetic operation of artificial intelligence can be applied not only to image correction but also to upconversion processing of image data. Accordingly, upconversion of low screen resolution image data can be performed in accordance with the screen resolution of the display portion DIS, which enables a high-display-quality image to be displayed on the display portion DIS. Such an arithmetic operation of artificial intelligence can be applied to downconversion processing of image data.

Note that for the above-described arithmetic operation of artificial intelligence, the GPU included in the image processing unit GPS can be used, for example. That is, the GPU can be used to perform arithmetic operations for various kinds of correction (e.g., color irregularity correction or upconversion).

Note that in this specification and the like, such a GPU performing an arithmetic operation of artificial intelligence is referred to as an AI accelerator. That is, the GPU may be replaced with an AI accelerator in the description in this specification and the like. The clock signal generation circuit CKS has a function of generating a clock signal for displaying a desired image on each of the display region ARA[1,1] to the display region ARA[m,n], for example.

In the case where the image rewriting frequency (frame frequency) is different among the display region ARA[1,1] to the display region ARA[m,n], the clock signal generation circuit CKS preferably has a function of generating a clock signal with the frame frequency corresponding to each of the display region ARA[1, 1] to the display region ARA[m,n]. That is, the clock signal generation circuit CKS preferably has a function of generating clock signals with different frequencies at the same time.

The distribution circuit DMG has a function of transmitting a signal received from the bus wiring BW to the driver circuit GD for driving pixels included in any one of the display region ARA[1,1] to the display region ARA[m,n], in accordance with the content of the signal.

The distribution circuit DMS has a function of transmitting a signal received from the bus wiring BW to the driver circuit SD for driving pixels included in any one of the display region ARA[1,1] to the display region ARA[m,n], in accordance with the content of the signal.

FIG. 5 illustrates a state where the distribution circuit DMG transmits a signal directly to the circuit GDS; however, the signal transmitted from the distribution circuit DMG may be input to the circuit GDS through the interface INT. Similarly, the distribution circuit DMS transmits a signal directly to the circuit SDS in FIG. 5; however, the signal transmitted from the distribution circuit DMS may be input to the circuit SDS through the interface INT.

Although not illustrated in FIG. 5, a level shifter may be included in the control circuit PRPH. The level shifter has a function of converting signals input to circuits into appropriate levels, for example.

Note that the structure of the control circuit PRPH illustrated in FIG. 5 is an example, and the circuit structure included in the control circuit PRPH may be changed depending on circumstances. For example, in the case where the control circuit PRPH receives driving voltages of circuits from the outside, the control circuit PRPH does not need to generate the driving voltages. In that case, the control circuit PRPH may have a structure without including the voltage generation circuit PG.

For another example, some or all of the circuits included in the control circuit PRPH may be included in the circuit layer SICL of the display apparatus DSP. Specifically, in the case of the display apparatus DSP in FIG. 1A, some or all of the circuits included in the control circuit PRPH may be included in the driver circuit region DRV. In the case of the display apparatus DSP in FIG. 1B, some or all of the circuits included in the control circuit PRPH may be included in the driver circuit region DRV or the region LIA.

Note that this embodiment can be combined with any of the other embodiments in this specification as appropriate.

### Embodiment 2

In this embodiment, a display apparatus that can be provided in an electronic device of one embodiment of the present invention will be described. Note that the display apparatus described in this embodiment can be used in the display apparatus DSP described in the above embodiment.

### Structure Example of Display Apparatus

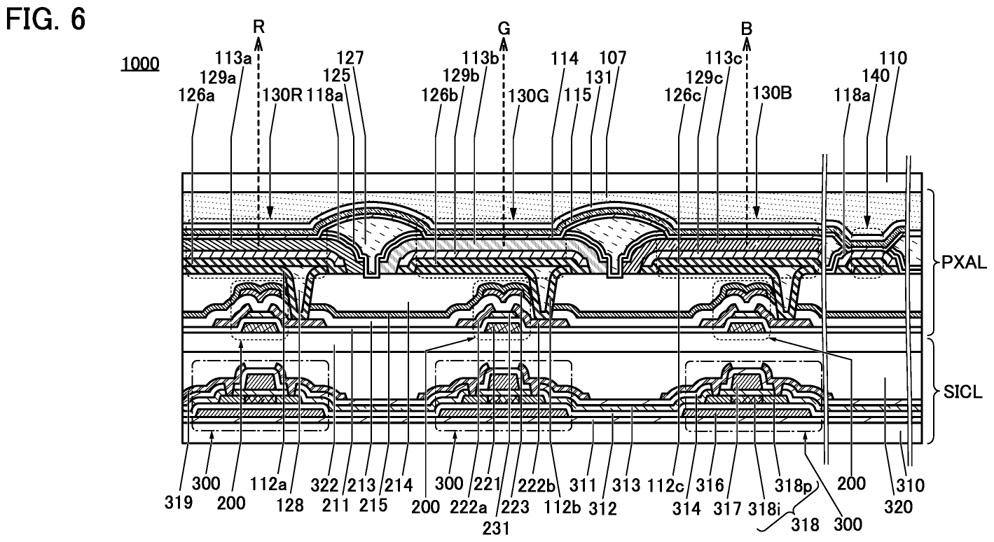

FIG. 6 is a cross-sectional view illustrating an example of a display apparatus of one embodiment of the present invention. A display apparatus 1000 illustrated in FIG. 6 has a structure in which a pixel circuit, a driver circuit, and the like are provided over a substrate 310, for example. Note that the display apparatus DSP described in the above embodiment can have a structure of the display apparatus 1000 in FIG. 6.

Specifically, for example, the circuit layer SICL and the pixel layer PXAL illustrated in the display apparatus DSP in FIG. 1 can be structured as in the display apparatus 1000 in FIG. 6. In the structure of the display apparatus 1000 in FIG. 6, a circuit element and a light-emitting device are formed between the substrate 310 and a substrate 110. The circuit layer SICL includes a transistor 300. Specifically, the transistor 300 is formed over the substrate 310. The pixel layer PXAL is provided above the transistor 300. Note that a wiring electrically connecting the transistor 300 and the transistor 200 to each other is provided between the transistor 300 and the transistor 200 (the wiring is not illustrated). The pixel layer PXAL includes, for example, the transistor 200 and a light-emitting device 130 (a light-emitting device 130R, a light-emitting device 130G, and a light-emitting device 130B in FIG. 6). The substrate 110 is provided over the light-emitting device 130.

The substrate 310 corresponds to the substrate BS described in Embodiment 1, for example. Thus, as described in Embodiment 1, a substrate that can be used as the substrate BS is preferably used as the substrate 310.

As described in Embodiment 1, the diagonal size of the display apparatus DSP can be determined by the size of the substrate used as the substrate BS (the substrate 310). In particular, when a substrate used as the substrate BS (the substrate 310) is a glass substrate, a metal substrate, or a base film that easily has a large area, the display apparatus DSP with a large diagonal size can be manufactured. In this specification and the like, a large-area substrate refers to a substrate of the second generation substrate size or larger, for example.

Note that in this embodiment, the substrate 310 is described as a substrate including a material with high resistance to heat, such as a glass substrate.

In the case where the area of the substrate BS (the substrate 310) is increased, the transistor 300 and the transistor 200 are preferably formed by a process that enables the transistors to be formed over the substrate BS (the substrate 310) having a large area. Examples of the transistor that can be formed over a large-area substrate include a transistor containing low-temperature polysilicon in a channel formation region (hereinafter, referred to as an LTPS transistor) and an OS transistor.

The transistor 300 is provided over the substrate 310. The transistor 300 includes an insulator 311, an insulator 312, an insulator 313, an insulator 314, a conductor 316, a conductor 317, a low-resistance region 318p, a semiconductor region 318i, and a conductor 319. Here, a plurality of layers obtained by processing the same conductive film are shown with the same hatching pattern. In this specification and the like, the low-resistance region 318p and the semiconductor region 318i are collectively referred to as a semiconductor layer 318. In particular, when, for example, low-temperature polysilicon is used as a semiconductor material contained in the semiconductor layer 318, the transistor 300 can be an LTPS transistor. The LTPS transistor has high field-effect mobility and excellent frequency characteristics.

With the use of an LTPS transistor as the transistor 300, a circuit provided in the circuit layer SICL (e.g., the driver circuit GD and the driver circuit SD illustrated in FIG. 2B to FIG. 5) can be formed over the same substrate as the display portion. This allows simplification of an external circuit mounted on the display apparatus and a reduction in component cost and mounting cost.

In FIG. 6, the conductor 317 serves as a first gate (sometimes referred to as one of a gate and a back gate) of the transistor 300. The conductor 316 serves as a second gate (sometimes referred to as the other of the gate and the back gate) of the transistor 300. One of the pair of low-resistance regions 318p in the semiconductor layer 318 serves as one of a source and a drain of the transistor 300, and the other of the pair of low-resistance regions 318p in the semiconductor layer 318 serves as the other of the source and the drain of the transistor 300. The insulator 313 functions as a first gate insulating film of the transistor 300, and the insulator 312 functions as a second gate insulating film of the transistor 300.

In FIG. 6, the insulator 311 is formed over the substrate 310. The conductor 316 is formed in a region over the insulator 311. The insulator 312 is formed to cover the insulator 311 and the conductor 316. The semiconductor layer 318 is formed in a region overlapping with the conductor 316 and the insulator 312 and being over part pf the insulator 312. The insulator 313 is formed to cover the insulator 312 and the semiconductor layer 318. The conductor 317 is formed in a region overlapping with the conductor 316, the insulator 312, the semiconductor layer 318, and the insulator 313 and being over part of the insulator 313. The insulator 314 covers so as to cover the insulator 313 and the conductor 317 in this order. An opening is formed in the insulator 313 and the insulator 314 in regions overlapping with the low-resistance region 318p, and the conductor 319 is formed over the insulator 314 to fill the opening.

For the insulator 311, the insulator 312, the insulator 313, and the insulator 314, silicon oxide, silicon oxynitride, silicon nitride oxide, silicon nitride, aluminum oxide, aluminum oxynitride, aluminum nitride oxide, aluminum nitride, or the like can be used, for example.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition; in the case where silicon nitride oxide is described, it refers to a material that contains more nitrogen than oxygen in its composition.

In particular, a barrier insulating film that can prevent diffusion of impurities (e.g., a metal ion, a metal atom, an oxygen atom, an oxygen molecule, a hydrogen atom, a hydrogen molecule, and a water molecule) from a region below the insulator 311 (e.g., the substrate 310) is preferably used as the insulator 311.

Similarly, for the insulator 314, it is preferable to use a barrier insulating film that can prevent diffusion of impurities (e.g., a certain metal ion, a certain metal atom, an oxygen atom, an oxygen molecule, a hydrogen atom, a hydrogen molecule, and a water molecule) from a region above the insulator 314 (e.g., a region where the transistor 200, the light-emitting device 130R, the light-emitting device 130G, and the light-emitting device 130B are provided).

Accordingly, for the insulator 311 and the insulator 314, it is preferable to use an insulating material that has a function of suppressing diffusion of impurities such as a certain metal ion, a certain metal atom, an oxygen atom, an oxygen molecule, a hydrogen atom, a hydrogen molecule, and a water molecule (an insulating material through which the above impurities are less likely to pass). Furthermore, depending on the situation, for the insulator 311 and the insulator 314, it is preferable to use an insulating material that has a function of reducing diffusion of impurities such as a nitrogen atom, a nitrogen molecule, a nitrogen oxide molecule (e.g., N₂O, NO, or NO₂), and a copper atom (through which oxygen less likely to pass).

For the film having a barrier property against hydrogen, silicon nitride deposited by a CVD (Chemical Vapor Deposition) method can be used, for example.

The amount of released hydrogen can be analyzed by thermal desorption spectroscopy (TDS), for example. The amount of hydrogen released from the insulator 311 or the insulator 314 that is converted into hydrogen atoms per unit area of an insulator 324 can be less than or equal to 10×10¹⁵ atoms/cm², preferably less than or equal to 5×10¹⁵ atoms/cm² in TDS analysis in a film-surface temperature range of 50° C. to 500° C., for example.

The semiconductor layer 318 contains silicon, as described above. In particular, the silicon is preferably low-temperature polysilicon. That is, the transistor 300 is preferably an LTPS transistor.

Since a p-type semiconductor is difficult to form with use of a metal oxide in terms of mobility and reliability, a circuit formed with OS transistors becomes a single-polarity circuit with only n-channel transistors in many cases. Meanwhile, since the LTPS transistor can be easily fabricated to be either n-channel type or p-channel type, a CMOS circuit can be formed using the LTPS transistor. As described in Embodiment 1, the circuit layer SICL includes a driver circuit; thus, the driver circuit is preferably configured with a CMOS circuit rather than the single-polarity circuit in terms of driving speed and power consumption.

The low-resistance regions 318p is a region containing an impurity element. For example, in the case where the transistor 300 is an n-channel transistor, an impurity element such as phosphorus or arsenic is added to the low-resistance regions 318p. In contrast, in the case where the transistor 300 is a p-channel transistor, an impurity element such as boron or aluminum is added to the low-resistance region 318p. In addition, in order to control the threshold voltage of the transistor 300, the above-described impurity element may be added to the channel formation region 318i.

Note that the transistor 300 may be either a p-channel transistor or an n-channel transistor. Alternatively, a plurality of the transistors 300 may be provided in the circuit layer SICL and both the p-channel transistor and the n-channel transistor may be used.

For the conductor 316 and the conductor 317, a metal such as aluminum, titanium, chromium, nickel, copper, yttrium, zirconium, molybdenum, silver, tantalum, or tungsten can be used, for example. Alternatively, an alloy containing one or more of the above metals as its main component can be used for the conductor 316 and the conductor 317 as a single-layer structure or a stacked-layer structure. Alternatively, a light-transmitting conductive material such as indium oxide, indium tin oxide (ITO), indium oxide containing tungsten, indium zinc oxide containing tungsten, indium oxide containing titanium, ITO containing titanium, indium zinc oxide, zinc oxide (ZnO), ZnO containing gallium, or indium tin oxide containing silicon may be used for the conductor 316 and the conductor 317. Alternatively, a semiconductor such as an oxide semiconductor or polycrystalline silicon whose resistance is lowered by adding an impurity element, for example, or silicide such as nickel silicide may be used for the conductor 316 and the conductor 317. Alternatively, a film containing graphene can be used for the conductor 316 and the conductor 317. The film containing graphene can be formed, for example, by reducing a film containing graphene oxide. Alternatively, the conductors may be formed using a conductive paste of silver, carbon, copper, or the like or a conductive polymer such as polythiophene. A conductive paste is preferable because it is inexpensive. A conductive polymer is preferable because it is easily applied.

The conductor 319 serves as a wiring electrically connected to the low-resistance region 318p of the transistor 300. That is, the conductor 319 serves as a source or a drain of the transistor 300. Note that the conductor 319 can be formed using any of the materials usable for the conductor 316 and the conductor 317.

Note that the transistor 300 illustrated in FIG. 6 is only an example and the structure is not limited thereto; an appropriate transistor can be used in accordance with a circuit structure, a driving method, or the like.

An insulator 320 and an insulator 322 are formed in this order over the insulator 314.

For the insulator 320 and the insulator 322, a material usable for any one of the insulator 311 to the insulator 314 can be used, for example.

A plurality of transistors 200 are formed over the insulator 322. The plurality of transistors 200 can be manufactured using the same materials through the same process, for example.

The insulator 211, an insulator 213, an insulator 215, and the insulator 214 are provided in this order over the insulator 322. Part of the insulator 211 functions as a gate insulator of each transistor. Part of the insulator 213 functions as a gate insulator of each transistor. The insulator 215 is provided to cover the transistors. The insulator 214 is provided to cover the transistors and has a function of a planarization layer. Note that there is no limitation on the number of gate insulating layers and the number of insulating layers covering the transistors, and each insulating layer may be a single layer or a stacked layer of two or more layers.

A material through which impurities such as water and hydrogen do not easily diffuse is preferably used for at least one of the insulating layers covering the transistors. In that case, the insulating layer can function as a barrier layer. Such a structure can effectively suppress diffusion of impurities into the transistors from the outside and increase the reliability of the display apparatus.

An inorganic insulating film is preferably used as each of the insulator 211, the insulator 213, and the insulator 215. As the inorganic insulating film, for example, a silicon nitride film, a silicon oxynitride film, a silicon oxide film, a silicon nitride oxide film, an aluminum oxide film, or an aluminum nitride film can be given. Alternatively, a hafnium oxide film, an yttrium oxide film, a zirconium oxide film, a gallium oxide film, a tantalum oxide film, a magnesium oxide film, a lanthanum oxide film, a cerium oxide film, or a neodymium oxide film may be used as the inorganic insulating film. A stack including two or more of the above insulating films may also be used.

An organic insulating layer is suitable as the insulator 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulator 214 may have a stacked-layer structure of an organic insulating layer and an inorganic insulating layer. The outermost layer of the insulator 214 preferably has a function of an etching protective layer. In that case, a depressed portion can be inhibited from being formed in the insulator 214 at the time of processing the conductor 112a, the conductor 126a, the conductor 129a, or the like described later. Alternatively, a depressed portion may be formed in the insulator 214 at the time of processing the conductor 112a, the conductor 126a, the conductor 129a, or the like.

The plurality of transistors 200 each include a conductor 221 functioning as a gate, the insulator 211 functioning as a gate insulating layer, a conductor 222a and a conductor 222b functioning as a source and a drain, a semiconductor layer 231, the insulator 213 functioning as a gate insulating layer, and a conductor 223 functioning as a gate. Here, a plurality of layers obtained by processing the same conductive film are shown with the same hatching pattern, as in the transistor 300. The insulator 211 is positioned between the conductor 221 and the semiconductor layer 231. The insulator 213 is positioned between the conductor 223 and the semiconductor layer 231.

There is no particular limitation on the structure of the transistors included in the display apparatus of this embodiment. For example, a planar transistor, a staggered transistor, an inverted staggered transistor, or the like can be used. A top-gate transistor structure or a bottom-gate transistor structure may be employed. Alternatively, gates may be provided above and below the semiconductor layer where a channel is formed.

The structure in which the semiconductor layer where a channel is formed is sandwiched between the two gates is used for each of the plurality of transistors 200. The two gates may be connected to each other and supplied with the same signal to drive the transistor. Alternatively, the threshold voltage of the transistor may be controlled by supplying a potential for controlling the threshold voltage to one of the two gates and supplying a potential for driving to the other of the two gates.

There is no particular limitation on the crystallinity of a semiconductor material used for the transistors, and any of an amorphous semiconductor, and a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case degradation of the transistor characteristics can be inhibited.

The semiconductor layer of the transistor preferably includes a metal oxide (also referred to as an oxide semiconductor). That is, a transistor including a metal oxide in its channel formation region (hereinafter, an OS transistor) is preferably used for the display apparatus of this embodiment.

As examples of the oxide semiconductor having crystallinity, a CAAC (c-axis aligned crystalline)-OS, an nc (nanocrystalline)-OS, and the like can be given.

An OS transistor has much higher field-effect mobility than a transistor containing amorphous silicon. In addition, the OS transistor has an extremely low leakage current between a source and a drain in an off state (hereinafter also referred to as off-state current), and electric charge accumulated in a capacitor that is connected in series to the transistor can be retained for a long period. Furthermore, power consumption of the display apparatus can be reduced with the use of an OS transistor.

The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of a channel width of a Si transistor at room temperature is higher than or equal to 1 fA (1×10⁻¹⁵ A) and lower than or equal to 1 pA (1×10⁻¹² A). Thus, the off-state current of the OS transistor is lower than the off-state current of the Si transistor by approximately ten orders of magnitude.

To increase the emission luminance of the light-emitting device included in the pixel circuit, the amount of current fed through the light-emitting device needs to be increased. For this, it is necessary to increase the source-drain voltage of a driving transistor included in the pixel circuit. Since an OS transistor has a higher breakdown voltage between the source and the drain than a Si transistor, a high voltage can be applied between the source and the drain of the OS transistor. Accordingly, when an OS transistor is used as the driving transistor included in the pixel circuit, the amount of current flowing through the light-emitting device can be increased, so that the emission luminance of the light-emitting device can be increased.

When transistors operate in a saturation region, a change in source-drain current with respect to a change in gate-source voltage can be smaller in an OS transistor than in a Si transistor. Accordingly, when an OS transistor is used as the driving transistor in the pixel circuit, the amount of current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the light-emitting devices vary, for example. In other words, when the OS transistor operates in the saturation region, the source-drain current hardly changes with an increase in the source-drain voltage; hence, the emission luminance of the light-emitting device can be stable.

As described above, by using an OS transistor as the driving transistor included in the pixel circuit, it is possible to “reduce black-level degradation”, “increase the emission luminance”, “increase the number of gray levels”, and “suppress variations in light-emitting devices”, for example.

The semiconductor layer used in the OS transistor preferably contains at least indium or zinc, and further preferably contains indium and zinc, for example. The semiconductor layer preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, the element M is preferably one or more kinds selected from gallium, aluminum, yttrium, and tin.

It is preferable to use especially an oxide containing indium (In), gallium (Ga), and zinc (Zn) (also referred to as IGZO) as the semiconductor layer. Alternatively, it is preferable to use an oxide containing indium, tin, and zinc. Further alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO).

When the semiconductor layer is an In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

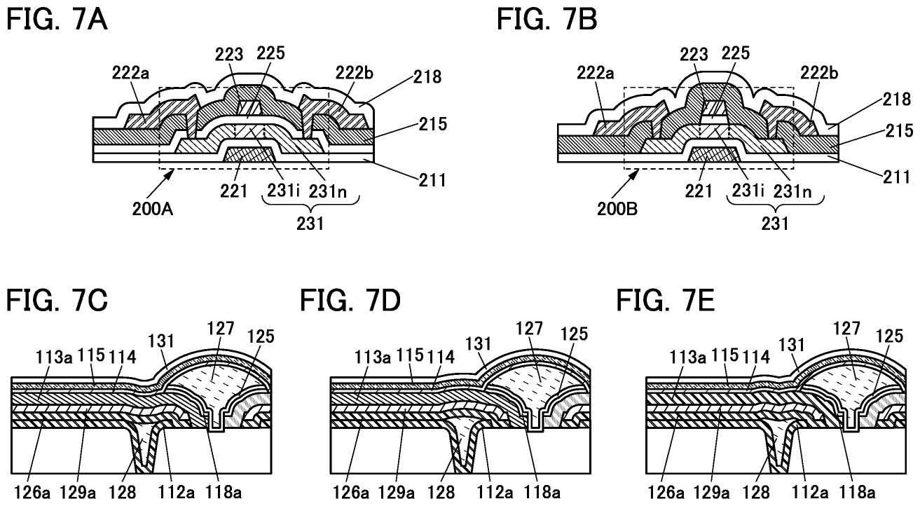

The structure of the OS transistor is not limited to the structure illustrated in FIG. 6. For example, the structures illustrated in FIG. 7A and FIG. 7B may be employed.

Each of the transistor 200A and the transistor 200B includes the conductor 221 functioning as a gate, the insulator 211 functioning as a gate insulating layer, the semiconductor layer 231 including a channel formation region 231i and a pair of low-resistance regions 231n, the conductor 222a connected to one of the pair of low-resistance regions 231n, the conductor 222b connected to the other of the pair of low-resistance regions 231n, an insulator 225 functioning as a gate insulating layer, the conductor 223 functioning as a gate, and the insulator 215 covering the conductor 223. The insulator 211 is positioned between the conductor 221 and the channel formation region 231i. The insulator 225 is positioned at least between the conductor 223 and the channel formation region 231i. Furthermore, an insulator 218 covering the transistor may be provided.

FIG. 7A illustrates an example of the transistor 200A in which the insulator 225 covers the top and side surfaces of the semiconductor layer 231. The conductor 222a and the conductor 222b are connected to the low-resistance regions 231n through openings provided in the insulator 225 and the insulator 215. One of the conductor 222a and the conductor 222b functions as a source, and the other functions as a drain.

Meanwhile, in the transistor 200B illustrated in FIG. 7B, the insulator 225 overlaps with the channel formation region 231i of the semiconductor layer 231 and does not overlap with the low-resistance regions 231n. The structure illustrated in FIG. 7B can be formed by processing the insulator 225 using the conductor 223 as a mask, for example. In FIG. 7B, the insulator 215 is provided to cover the insulator 225 and the conductor 223, and the conductor 222a and the conductor 222b are connected to the low-resistance regions 231n through the openings in the insulator 215.

The light-emitting device 130R, the light-emitting device 130G, the light-emitting device 130B, and a connection portion 140 are formed over the insulator 214.

The connection portion 140 is referred to as a cathode contact portion in some cases, and is electrically connected to cathodes of the light-emitting device 130R, the light-emitting device 130G, and the light-emitting device 130B. The connection portion 140 in FIG. 6 includes one or more conductors selected from the conductor 112a to a conductor 112c, one or more conductors selected from the conductor 126a to a conductor 126c, one or more conductors selected from the conductor 129a to a conductor 129c, a common layer 114 to be described later, and a common electrode 115 to be described later.

Note that the connection portion 140 may be provided to surround four sides of the display portion or may be provided in the display portion (e.g., between adjacent light-emitting devices 130).

The light-emitting device 130R includes the conductor 112a, the conductor 126a over the conductor 112a, and the conductor 129a over the conductor 126a. All of the conductor 112a, the conductor 126a, and the conductor 129a can be referred to as pixel electrodes, or part of them can be referred to as pixel electrodes.

The light-emitting device 130G includes the conductor 112b, the conductor 126b over the conductor 112b, and the conductor 129b over the conductor 126b. As in the light-emitting device 130R, all of the conductor 112b, the conductor 126b, and the conductor 129b can be referred to as a pixel electrode, or part of them can be referred to as a pixel electrode.

The light-emitting device 130B includes the conductor 112c, the conductor 126c over the conductor 112c, and the conductor 129c over the conductor 126c. As in the light-emitting device 130R and the light-emitting device 130G, all of the conductor 112c, the conductor 126c, and the conductor 129c can be referred to as a pixel electrode, or part of them can be referred to as a pixel electrode.

For the conductor 112a to the conductor 112c and the conductor 126a to the conductor 126c, a conductive layer functioning as a reflective electrode can be used, for example. For the conductive layer functioning as a reflective electrode, a conductor with high visible-light reflectance such as silver, aluminum, or an alloy film of silver (Ag), palladium (Pd), and copper (Cu) (an Ag—Pd—Cu (APC) film) can be used. The conductor 112a to the conductor 112c and the conductor 126a to the conductor 126c may each be, for example, a stacked-layer film in which a pair of titanium films sandwich aluminum (a film in which Ti, Al, and Ti are stacked in this order), a stacked-layer film in which a pair of indium tin oxide films sandwich silver (a film in which ITO, Ag, and ITO are stacked in this order), or the like.

For example, a conductive layer functioning as a reflective electrode may be used for the conductor 112a to the conductor 112c, and a conductor with a high light-transmitting property may be used for the conductor 126a to the conductor 126c. Examples of the conductor with a high light-transmitting property include indium tin oxide (sometimes referred to as ITO) and an alloy of silver and magnesium.

A conductive layer functioning as a transparent electrode can be used for the conductor 129a to the conductor 129c. For the conductive layer functioning as a transparent electrode, for example, the above-described conductor with a high light-transmitting property can be used.

A microcavity structure may be provided in the light-emitting device 130 to be described in detail later. The microcavity structure refers to a structure in which the distance between a bottom surface of the light-emitting layer and a top surface of a lower electrode is set to a thickness depending on a wavelength of light emitted from the light-emitting layer. In that case, a light-transmitting and light-reflective conductive material is preferably used for the conductor 129a to the conductor 129c serving as an upper electrode (a common electrode), and a light-reflective conductive material is preferably used for the conductor 112a to the conductor 112c and the conductor 126a to the conductor 126c which serve as lower electrodes (pixel electrodes).

The microcavity structure refers to a structure in which the optical distance between the lower electrode and the light-emitting layer is adjusted to be (2n-1)λ/4 (n is a natural number greater than or equal to 1, and λ is a wavelength of emitted light to be amplified). Thus, light that is reflected back by the lower electrode (reflected light) considerably interferes with light that directly enters the upper electrode from the light-emitting layer (incident light). Therefore, the phases of the reflected light and the incident light each having the wavelength λ can be aligned with each other, and the light emitted from the light-emitting layer can be further amplified. In the case where the reflected light and the incident light have a wavelength other than the wavelength λ, their phases are not aligned with each other, resulting in attenuation without resonation.

The conductor 112a is connected to the conductor 222b included in the transistor 200 through an opening provided in the insulator 214. An end portion of the conductor 126a is positioned outward from an end portion of the conductor 112a. The end portion of the conductor 126a and an end portion of the conductor 129a are aligned or substantially aligned with each other.

Detailed description of the conductor 112b, the conductor 126b, and the conductor 129b of the light-emitting device 130G and the conductor 112c, the conductor 126c, and the conductor 129c of the light-emitting device 130B is omitted because these conductive layers are similar to the conductor 112a, the conductor 126a, and the conductor 129a of the light-emitting device 130R.

Depressed portions are formed in the conductor 112a, the conductor 112b, and the conductor 112c to cover the openings provided in the insulator 214. A layer 128 is embedded in each of the depressed portions.

The layer 128 has a planarization function for the depressed portions of the conductor 112a, the conductor 112b, and the conductor 112c. In the light-emitting device 130R, the conductor 126a electrically connected to the conductor 112a is provided over the conductor 112a and the layer 128. Similarly, in the light-emitting device 130G, the conductor 126b electrically connected to the conductor 112b is provided over the conductor 112b and the layer 128. Similarly, in the light-emitting device 130B, the conductor 126c electrically connected to the conductor 112c is provided over the conductor 112c and the layer 128. Thus, regions overlapping with the depressed portions of the conductor 112a, the conductor 112b, and the conductor 112c can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used for the layer 128. As the layer 128, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used, for example. A photosensitive resin can also be used for the layer 128. As the photosensitive resin, a positive photosensitive material or a negative photosensitive material can be used.

When a photosensitive resin is used, the layer 128 can be formed through only light-exposure and development processes, reducing the influence of dry etching, wet etching, or the like on the surfaces of the conductor 112a, the conductor 112b, and the conductor 112c. When the layer 128 is formed using a negative photosensitive resin, the layer 128 can sometimes be formed using the photomask (light-exposure mask) used for forming the opening in the insulator 214.

Note that although FIG. 6 illustrates an example where the top surface of the layer 128 includes a planar portion, the shape of the layer 128 is not particularly limited. FIG. 7C to FIG. 7E each illustrate a variation example of the layer 128.

As illustrated in FIG. 7C and FIG. 7E, the top surface of the layer 128 can have a shape such that its center and the vicinity thereof are recessed, i.e., a shape including a concave surface, in a cross-sectional view.

As illustrated in FIG. 7D, the top surface of the layer 128 can have a shape such that its center and the vicinity thereof bulge, i.e., a shape including a convex surface, in a cross-sectional view.

The top surface of the layer 128 may include one or both of a convex surface and a concave surface. The number of convex surfaces and the number of concave surfaces included in the top surface of the layer 128 are not limited and can each be one or more than one.

The height of the top surface of the layer 128 and the level of the top surface of the conductor 112a may be equal to or substantially equal to each other, or may be different from each other. For example, the level of the top surface of the layer 128 may be either lower or higher than the level of the top surface of the conductor 112a.

FIG. 7C can be regarded as illustrating an example where the layer 128 fits in the depressed portion formed in the conductor 112a. By contrast, as illustrated in FIG. 7E, the layer 128 may exist also outside the depressed portion formed in the conductor 112a, that is, the layer 128 may be formed to have a top surface wider than the depressed portion.

The light-emitting device 130R includes a first layer 113a, the common layer 114 over the first layer 113a, and the common electrode 115 over the common layer 114. The light-emitting device 130G includes a second layer 113b, the common layer 114 over the second layer 113b, and the common electrode 115 over the common layer 114. The light-emitting device 130B includes a third layer 113c, the common layer 114 over the third layer 113c, and the common electrode 115 over the common layer 114.

The first layer 113a is formed to cover a top surface and a side surface of the conductor 126a and a top surface and a side surface of the conductor 129a. Similarly, the second layer 113b is formed to cover a top surface and a side surface of the conductor 126b and a top surface and a side surface of the conductor 129b. Similarly, the third layer 113c is formed to cover a top surface and a side surface of the conductor 126c and a top surface and a side surface of the conductor 129c. Accordingly, regions provided with the conductor 126a, the conductor 126b, and the conductor 126c can be entirely used as the light-emitting regions of the light-emitting device 130R, the light-emitting device 130G, and the light-emitting device 130B, increasing the aperture ratio of the pixels.

In the light-emitting device 130R, the first layer 113a and the common layer 114 can be collectively referred to as an EL layer. Similarly, in the light-emitting device 130G, the second layer 113b and the common layer 114 can be collectively referred to as an EL layer. Similarly, in the light-emitting device 130B, the third layer 113c and the common layer 114 can be collectively referred to as an EL layer.

There is no particular limitation on the structure of the light-emitting device in this embodiment, and the light-emitting device can have a single structure or a tandem structure.

Each of the first layer 113a, the second layer 113b, and the third layer 113c is processed into an island shape by a photolithography method. Thus, each end portion of the first layer 113a, the second layer 113b, and the third layer 113c has a shape such that an angle formed by the top surface and the side surface is close to 90°. By contrast, an organic film formed using an FMM (Fine Metal Mask) or the like has a thickness that tends to gradually decrease with decreasing distance to the end portion, and the top surface has a slope shape in the range of greater than or equal to 1 μm and less than or equal to 10 μm, for example; thus, such an organic film has a shape whose top surface and side surface cannot be easily distinguished from each other.

The top surface and the side surface of each of the first layer 113a, the second layer 113b, and the third layer 113c are clearly distinguished from each other. Accordingly, regarding the first layer 113a and the second layer 113b which are adjacent to each other, one of the side surfaces of the first layer 113a and one of the side surfaces of the second layer 113b are placed to face each other. This applies to a combination of any two of the first layer 113a, the second layer 113b, and the third layer 113c.

The first layer 113a, the second layer 113b, and the third layer 113c each include at least a light-emitting layer. Preferably, the first layer 113a, the second layer 113b, and the third layer 113c include a red-light-emitting layer, a green-light-emitting layer, and a blue-light-emitting layer, respectively, for example. Other than the above colors, cyan, magenta, yellow, or white can be employed as colors of light emitted from the light-emitting layers.

Each of the first layer 113a, the second layer 113b, and the third layer 113c may include one or more of a hole-injection layer, a hole-transport layer, a hole-blocking layer, a charge-generation layer, an electron-blocking layer, an electron-transport layer, and an electron-injection layer.

For example, the first layer 113a, the second layer 113b, and the third layer 113c may each include a hole-injection layer, a hole-transport layer, a light-emitting layer, and an electron-transport layer. In addition, an electron-blocking layer may be provided between the hole-transport layer and the light-emitting layer. Furthermore, an electron-injection layer may be provided over the electron-transport layer.

The first layer 113a, the second layer 113b, and the third layer 113c may each include an electron-injection layer, an electron-transport layer, a light-emitting layer, and a hole-transport layer in this order, for example. In addition, a hole-blocking layer may be provided between the electron-transport layer and the light-emitting layer. Furthermore, a hole-injection layer may be provided over the hole-transport layer.

The first layer 113a, the second layer 113b, and the third layer 113c each preferably include a light-emitting layer and a carrier-transport layer (an electron-transport layer or a hole-transport layer) over the light-emitting layer. Since the surfaces of the first layer 113a, the second layer 113b, and the third layer 113c are sometimes exposed in the manufacturing process of the display apparatus, providing the carrier-transport layer over the light-emitting layer inhibits the light-emitting layer from being exposed on the outermost surface, so that damage to the light-emitting layer can be reduced. Thus, the reliability of the light-emitting device can be increased.

The first layer 113a, the second layer 113b, and the third layer 113c may each include a first light-emitting unit, a charge-generation layer, and a second light-emitting unit, for example. The first layer 113a, the second layer 113b, and the third layer 113c preferably include two or more light-emitting units that emit red light, two or more light-emitting units that emit green light, and two or more light-emitting units that emit blue light, respectively, for example.

The second light-emitting unit preferably includes a light-emitting layer and a carrier-transport layer (an electron-transport layer or a hole-transport layer) over the light-emitting layer. Since the surface of the second light-emitting unit is exposed in the manufacturing process of the display apparatus, providing the carrier-transport layer over the light-emitting layer inhibits the light-emitting layer from being exposed on the outermost surface, so that damage to the light-emitting layer can be reduced. Thus, the reliability of the light-emitting device can be increased.

The common layer 114 includes an electron-injection layer or a hole-injection layer, for example. Alternatively, the common layer 114 may include a stack of an electron-transport layer and an electron-injection layer, and may include a stack of a hole-transport layer and a hole-injection layer. The common layer 114 is shared by the light-emitting device 130R, the light-emitting device 130G, and the light-emitting device 130B.

The common electrode 115 is shared by the light-emitting device 130R, the light-emitting device 130G, and the light-emitting device 130B. As illustrated in FIG. 6, the common electrode 115 shared by the plurality of light-emitting devices is electrically connected to the conductor provided in the connection portion 140.

The side surfaces of the first layer 113a, the second layer 113b, and the third layer 113c are covered with the insulator 125 and the insulator 127. The mask layer 118a is located between the first layer 113a and the insulator 125. The mask layer 118a is located between the second layer 113b and the insulator 125, and the mask layer 118a is located between the third layer 113c and the insulator 125. The common layer 114 is provided over the first layer 113a, the second layer 113b, the third layer 113c, the insulator 125, and the insulator 127. The common electrode 115 is provided over the common layer 114. The common layer 114 and the common electrode 115 are each a continuous film shared by a plurality of light-emitting devices.

The protective layer 131 is provided over each of the light-emitting device 130R, the light-emitting device 130G, and the light-emitting device 130B. The protective layer 131 serves as a passivation film for protecting the light-emitting devices 130. The protective layer 131 covering the light-emitting devices can inhibit an impurity such as water from entering the light-emitting device, and increase the reliability of the light-emitting device 130.

For example, aluminum oxide, silicon nitride, or silicon nitride oxide can be used for the protective layer 131.

The protective layer 131 and the substrate 110 are bonded to each other with an adhesive layer 107. A solid sealing structure, a hollow sealing structure, or the like can be employed to seal the light-emitting device. In FIG. 6, a solid sealing structure is employed in which a space between the substrate 310 and the substrate 110 is filled with the adhesive layer 107. Alternatively, a hollow sealing structure in which the space is filled with an inert gas (e.g., nitrogen or argon) may be employed. Here, the adhesive layer 107 may be provided not to overlap with the light-emitting device. The space may be filled with a resin different from that of the frame-shaped adhesive layer 107.

As the adhesive layer 107, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-liquid-mixture-type resin may be used. An adhesive sheet or the like may be used.

The display apparatus 1000 has a top-emission structure. Light from the light-emitting device is emitted toward the substrate 110 side. For the substrate 110, a material having a high visible-light-transmitting property is preferably used. For example, as the substrate 110, a substrate having a high visible-light-transmitting property may be selected from the substrates usable as the substrate BS. The pixel electrode contains a material that reflects visible light, and a counter electrode (the common electrode 115) contains a material that transmits visible light.

Note that the structure of the display apparatus of one embodiment of the present invention is not limited to that of the display apparatus 1000 illustrated in FIG. 6. The structure of the display apparatus of one embodiment of the present invention may be the structure of the display apparatus 1000 in FIG. 6 on which some modification is performed.

A light-blocking layer may be provided on the surface of the substrate 110 on the substrate 310 side, for example. The light-blocking layer can be provided between adjacent light-emitting devices and in the connection portion 140, for example. A variety of optical members can be arranged on the outer surface of the substrate 110. Examples of the optical members include a polarizing plate, a retardation plate, a light diffusion layer (a diffusion film or the like), an anti-reflective layer, and a light-condensing film. Furthermore, an antistatic film inhibiting the attachment of dust, a water repellent film reducing the attachment of stain, a hard coat film reducing generation of a scratch caused by the use, an impact-absorbing layer, or the like may be placed as a surface protective layer on the outer surface of the substrate 110. For example, a glass layer or a silica layer (a SiOₓ layer) is preferably provided as the surface protective layer to reduce the surface contamination and generation of a scratch. The surface protective layer may be formed using DLC (diamond like carbon), aluminum oxide (AlOₓ), a polyester-based material, a polycarbonate-based material, or the like. Note that for the surface protective layer, a material having high visible light transmittance is preferably used. The surface protective layer is preferably formed using a material with high hardness.

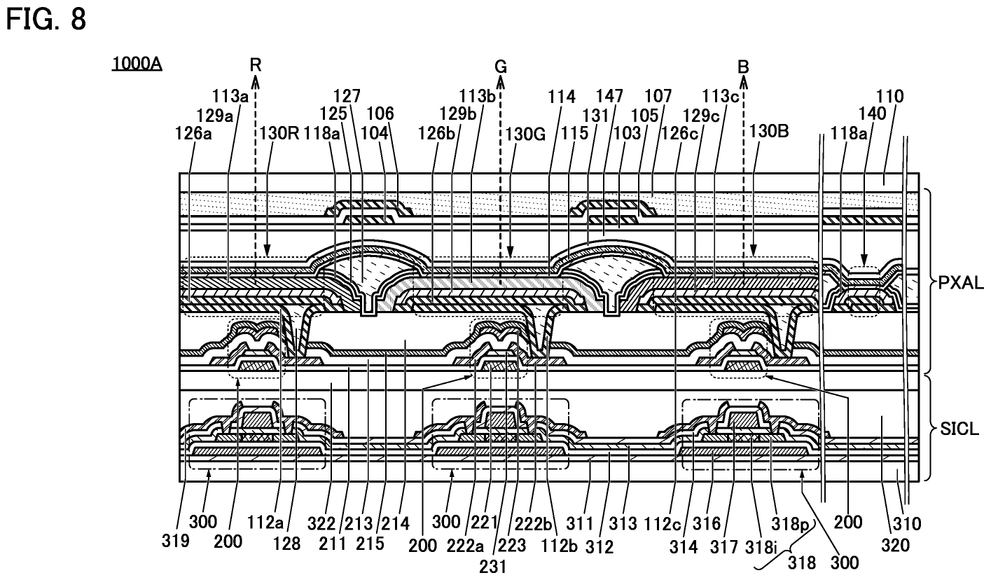

The display apparatus 1000 in FIG. 6 may be provided with a panel having a touch sensor function (sometimes referred to as a touch panel), for example, as in a display apparatus 1000A illustrated in FIG. 8. In the display apparatus 1000A illustrated in FIG. 8, a resin layer 147, an insulator 103, a conductor 104, an insulator 105, and a conductor 106 are formed in this order over the protective layer 131, for example.

The resin layer 147 preferably contains an organic insulating material. Examples of the organic insulating material include an acrylic resin, a polyimide resin, an epoxy resin, a polyamide resin, a polyimide-amide resin, a siloxane resin, a benzocyclobutene-based resin, a phenol resin, and precursors of these resins.

The insulator 103 preferably contains an inorganic insulating material. Examples of the inorganic insulating material include an oxide or a nitride such as silicon oxide, silicon oxynitride, silicon nitride oxide, silicon nitride, aluminum oxide, aluminum oxynitride, and hafnium oxide.

The conductor 104 and the conductor 106 function as the electrodes of the touch sensor. In the case of using a mutual capacitive type as a type of the touch sensor, a pulse potential may be supplied to one of the conductor 104 and the conductor 106, and an analog-digital (A/D) conversion circuit, a detection circuit such as a sense amplifier, or the like may be electrically connected to the other of the conductor 104 and the conductor 106, for example. In that case, capacitance is generated between the conductor 104 and the conductor 106. When the finger or the like approaches, the capacitance changes (specifically, the capacitance is reduced). This change in the capacitance appears, when a pulse potential is supplied to one of the conductor 104 and the conductor 106, as a change in the amplitude of a signal that occurs in the other of the conductor 104 and the conductor 106. Accordingly, the touch and proximity of the finger or the like can be detected.

As the insulator 105, an inorganic insulating film or an organic insulating film can be used. Examples of insulating materials include a resin such as an acrylic resin and an epoxy resin, and an inorganic insulating material such as silicon oxide, silicon oxynitride, silicon nitride oxide, silicon nitride, and aluminum oxide. The insulator 105 may have a single-layer structure or a stacked-layer structure.

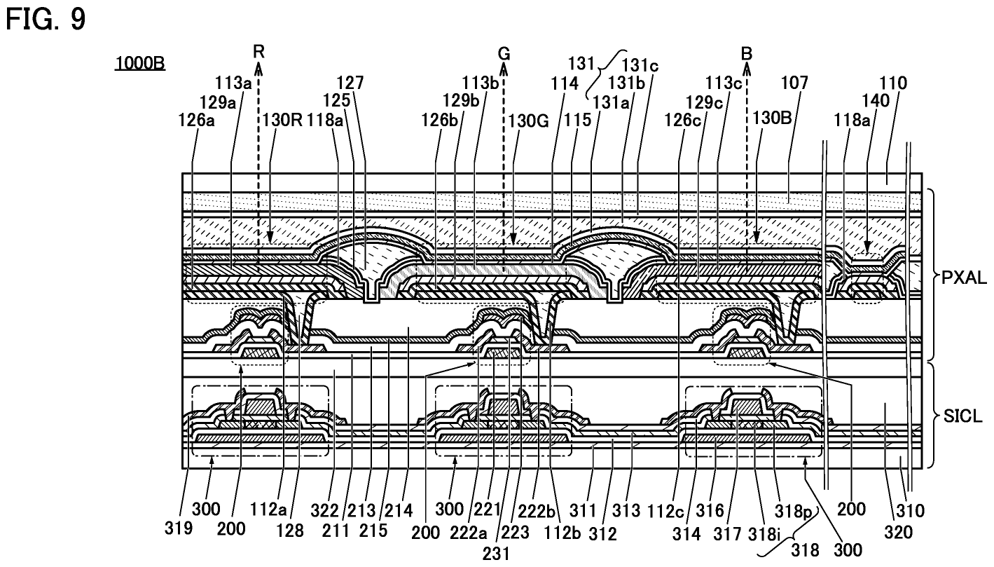

In the structure of the display apparatus 1000 illustrated in FIG. 6, for example, the protective layer 131 may have a stacked-layer structure of two or more layers, instead of a single layer. The protective layer 131 may have a three-layer structure that includes an insulator of an inorganic material as the first layer, an insulator of an organic material as the second layer, and an insulator of an inorganic material as the third layer. FIG. 9 is a cross-sectional view illustrating part of a display apparatus 1000B in which the protective layer 131 has a multilayer structure including a protective layer 131a, a protective layer 131b, and a protective layer 131c, which are an insulator of an inorganic material, an insulator of an organic material, and an insulator of an inorganic material, respectively. Note that when an insulator of an organic material is used for the protective layer 131b as illustrated in FIG. 9, the protective layer 131b can be provided as a planarization film.

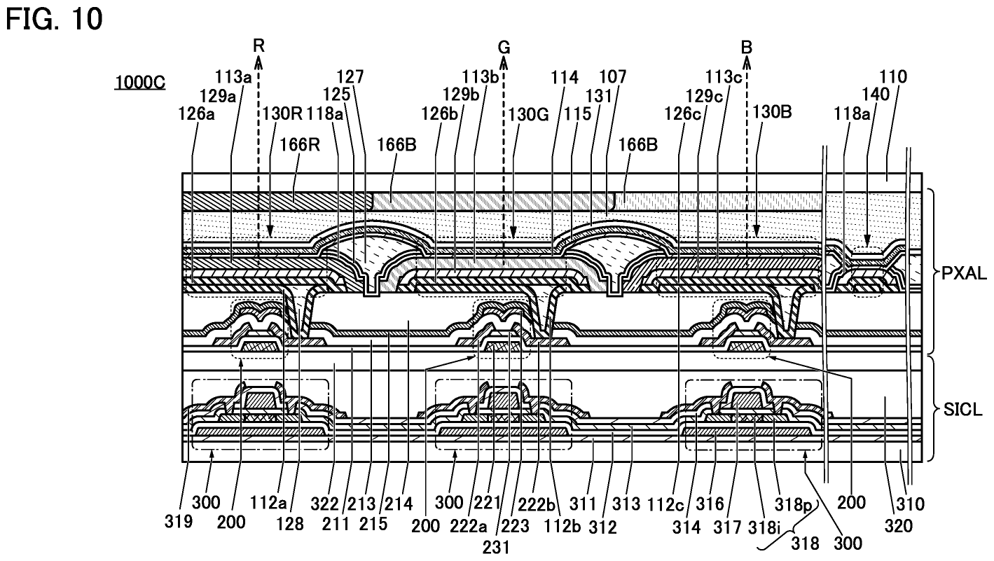

The display apparatus 1000 illustrated in FIG. 6 may include a coloring layer (color filter) or the like, for example. A display apparatus 1000C illustrated in FIG. 10 a structure in which a coloring layer 166a, a coloring layer 166b, and a coloring layer 166c are included between the adhesive layer 107 and the substrate 110, for example. Note that the coloring layer 166a to the coloring layer 166c can be formed on the substrate 110, for example. In the case where the light-emitting device 130R includes a light-emitting layer emitting red (R) light, the light-emitting device 130G includes a light-emitting layer emitting green (G) light, and the light-emitting device 130B includes a light-emitting layer emitting blue (B) light, the coloring layer 166a is a red coloring layer, the coloring layer 166b is a green coloring layer, and the coloring layer 166c is a blue coloring layer.

Note that the structure of the display apparatus of one embodiment of the present invention is not limited to that of the display apparatus 1000 illustrated in FIG. 6. The structure of the display apparatus of one embodiment of the present invention may be changed as appropriate. For example, a display apparatus may have a layer structure in which three or more layers of transistors are stacked (not illustrated) instead of the layer structure in which two layers of transistors are stacked.

### Structure Example of Light-Emitting Device

Next, a structure example of a light-emitting device that can be used for the above-described display apparatus is described.

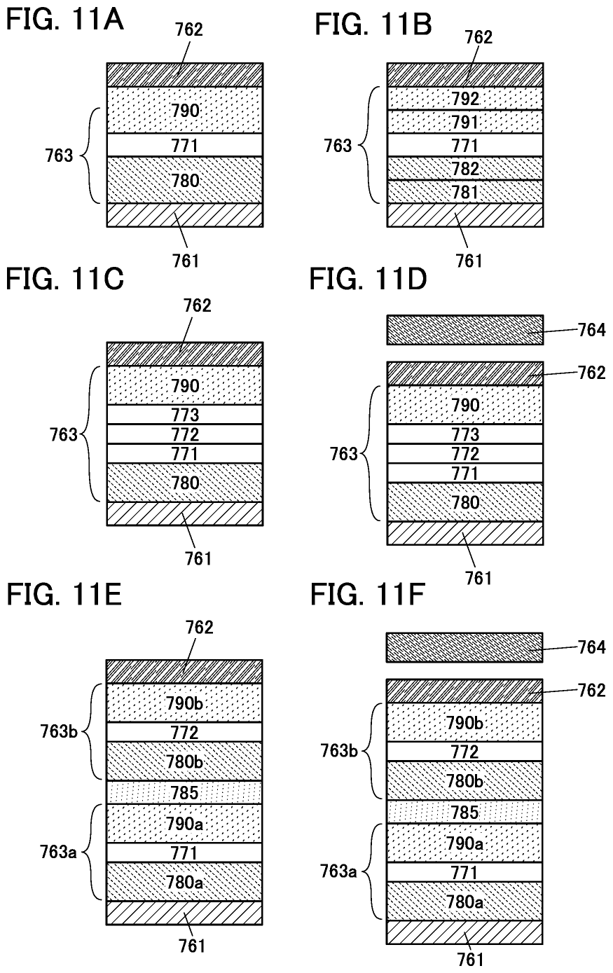

As illustrated in FIG. 11A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (a hole-injection layer), a layer containing a substance having a high hole-transport property (a hole-transport layer), and a layer containing a substance having a high electron-blocking property (an electron-blocking layer). Furthermore, the layer 790 includes one or more of a layer containing a substance having a high electron-injection property (an electron-injection layer), a layer containing a substance having a high electron-transport property (an electron-transport layer), and a layer containing a substance having a high hole-blocking property (a hole-blocking layer). In the case where the lower electrode 761 is a cathode and the upper electrode 762 is an anode, the structures of the layer 780 and the layer 790 are interchanged.

The structure including the layer 780, the light-emitting layer 771, and the layer 790, which are provided between a pair of electrodes, can function as a single light-emitting unit, and the structure in FIG. 11A is referred to as a single structure in this specification.

FIG. 11B is a modification example of the EL layer 763 included in the light-emitting device illustrated in FIG. 11A. Specifically, the light-emitting device illustrated in FIG. 11B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected to the light-emitting layer 771, and the efficiency of the recombination of carriers in the light-emitting layer 771 can be enhanced.

Note that structures in which a plurality of light-emitting layers (the light-emitting layer 771, a light-emitting layer 772, and a light-emitting layer 773) are provided between the layer 780 and the layer 790 as illustrated in FIG. 11C and FIG. 11D are variations of the single structure. Although FIG. 11C and FIG. 11D illustrate the examples where three light-emitting layers are included, the light-emitting device having a single structure may include two or four or more light-emitting layers. In addition, the light-emitting device having a single structure may include a buffer layer between two light-emitting layers.

A structure where a plurality of light-emitting units (a light-emitting unit 763a and a light-emitting unit 763b) are connected in series with a charge-generation layer 785 (also referred to as an intermediate layer) therebetween as illustrated in FIG. 11E and FIG. 11F is referred to as a tandem structure in this specification. Note that a tandem structure may be referred to as a stack structure. The tandem structure enables a light-emitting device capable of high-luminance light emission. Furthermore, the tandem structure reduces the amount of current needed for obtaining the same luminance as compared with a single structure, and thus can improve the reliability.

Note that FIG. 11D and FIG. 11F illustrate examples where the display apparatus includes a layer 764 overlapping with the light-emitting device. FIG. 11D illustrates an example where the layer 764 overlaps with the light-emitting device illustrated in FIG. 11C, and FIG. 11F illustrates an example where the layer 764 overlaps with the light-emitting device illustrated in FIG. 11E.

One or both of a color conversion layer and a color filter (a coloring layer) can be used as the layer 764.

In FIG. 11C and FIG. 11D, light-emitting substances that emit light of the same color or the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In a subpixel that emits red light and a subpixel that emits green light, by providing a color conversion layer as the layer 764 illustrated in FIG. 11D, blue light emitted from the light-emitting device can be converted into light with a longer wavelength, and red light or green light can be extracted.

Alternatively, light-emitting substances that emit light of different colors may be used for the light-emitting layer 771, the light-emitting layer 772, and the light-emitting layer 773. White light can be obtained when the light-emitting layer 771, the light-emitting layer 772, and the light-emitting layer 773 emit light of complementary colors. The light-emitting device having a single structure preferably includes a light-emitting layer containing a light-emitting substance emitting blue light and a light-emitting layer containing a light-emitting substance emitting visible light with a longer wavelength than blue light, for example.

In the case where the light-emitting device having a single structure includes three light-emitting layers, for example, a light-emitting layer containing a light-emitting substance emitting red (R) light, a light-emitting layer containing a light-emitting substance emitting green (G) light, and a light-emitting layer containing a light-emitting substance emitting blue (B) light are preferably included. The stacking order of the light-emitting layers can be R, G, and B or R, B, and G from an anode side, for example. In that case, a buffer layer may be provided between R and G or between R and B.

For example, in the case where the light-emitting device having a single structure includes two light-emitting layers, the light-emitting element preferably includes a light-emitting layer containing a light-emitting substance that emits blue (B) light and a light-emitting layer containing a light-emitting substance that emits yellow (Y) light. Such a structure may be referred to as a BY single structure.

A color filter may be provided as the layer 764 illustrated in FIG. 11D. When white light passes through a color filter, light of a desired color can be obtained.

The light-emitting device emitting white light preferably contains two or more kinds of light-emitting substances. To obtain white light emission, two light-emitting substances may be selected such that their emission colors are complementary colors. For example, when an emission color of a first light-emitting layer and an emission color of a second light-emitting layer are complementary colors, the light-emitting device can be configured to emit white light as a whole. When white light emission is obtained using three or more light-emitting layers, a light-emitting device is preferably configured to emit white light as a whole by combining emission colors of the three or more light-emitting layers.

In FIG. 11E and FIG. 11F, light-emitting substances that emit light of the same color or the same light-emitting substance may be used for the light-emitting layer 771 and the light-emitting layer 772.

For example, in light-emitting devices included in subpixels emitting light of different colors, a light-emitting substance that emits blue light may be used for each of the light-emitting layer 771 and the light-emitting layer 772. In a subpixel that emits blue light, blue light emitted from the light-emitting device can be extracted. In I the subpixel that emits red light and the subpixel that emits green light, by providing a color conversion layer as the layer 764 illustrated in FIG. 11F, blue light emitted from the light-emitting device can be converted into light with a longer wavelength, and red light or green light can be extracted.

In the case where the light-emitting device having the structure illustrated in FIG. 11E or FIG. 11F is used for the subpixels emitting different colors, the subpixels may use different light-emitting substances. Specifically, in the light-emitting device included in the subpixel emitting red light, a light-emitting substance that emits red light may be used for each of the light-emitting layer 771 and the light-emitting layer 772. Similarly, in the light-emitting device included in the subpixel emitting green light, a light-emitting substance that emits green light can be used for each of the light-emitting layer 771 and the light-emitting layer 772. In the light-emitting device included in the subpixel emitting blue light, a light-emitting substance that emits blue light can be used for each of the light-emitting layer 771 and the light-emitting layer 772. A display apparatus having such a structure can be regarded as employing a light-emitting device with the tandem structure and having the SBS structure. Thus, the display apparatus can take advantages of both the tandem structure and the SBS structure. Accordingly, a display apparatus being capable of high-luminance light emission and having high reliability can be obtained.

In FIG. 11E and FIG. 11F, light-emitting substances emitting light of different colors may be used for the light-emitting layer 771 and the light-emitting layer 772. White light can be obtained when the light-emitting layer 771 and the light-emitting layer 772 emit light of complementary colors. A color filter may be provided as the layer 764 illustrated in FIG. 11F. When white light passes through a color filter, light of a desired color can be obtained.

Although FIG. 11E and FIG. 11F illustrate examples where the light-emitting unit 763a includes one light-emitting layer 771 and the light-emitting unit 763b includes one the light-emitting layer 772, one embodiment of the present invention is not limited thereto. Each of the light-emitting unit 763a and the light-emitting unit 763b may include two or more light-emitting layers.

In addition, although FIG. 11E and FIG. 11F illustrate the light-emitting device including two light-emitting units as an example, one embodiment of the present invention is not limited thereto. The light-emitting device may include three or more light-emitting units.

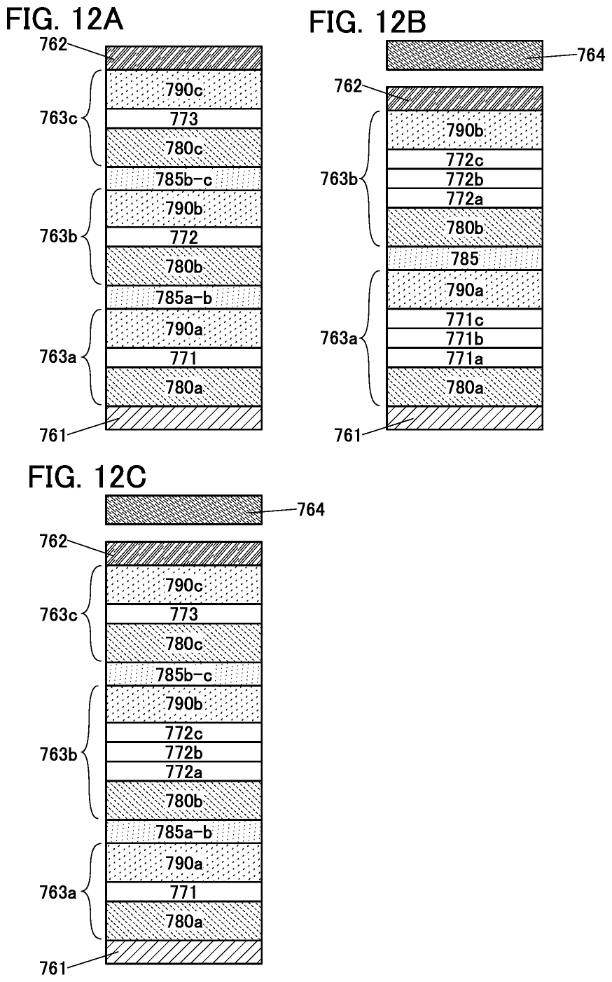

Specifically, the light-emitting device may have any of structures illustrated in FIG. 12A to FIG. 12C.

FIG. 12A illustrates a structure including three light-emitting units. Note that a structure including two light-emitting units and a structure including three light-emitting units may be referred to as a two-unit tandem structure and a three-unit tandem structure, respectively.

As illustrated in FIG. 12A, a plurality of light-emitting units (the light-emitting unit 763a, the light-emitting unit 763b, and the light-emitting unit 763c) are connected in series through the charge-generation layers (a charge-generation layer 785a-b and a charge-generation layer 785b-c). Specifically, in the light-emitting device illustrated in FIG. 12A, the light-emitting unit 763a, the charge-generation layer 785a-b, the light-emitting unit 763b, the charge-generation layer 785b-c, and the light-emitting unit 763c are stacked in this order. The light-emitting unit 763a includes a layer 780a, the light-emitting layer 771, and a layer 790a. The light-emitting unit 763b includes a layer 780b, the light-emitting layer 772, and a layer 790b. The light-emitting unit 763c includes a layer 780c, the light-emitting layer 773, and a layer 790c.

For the charge-generation layer 785a-b and the charge-generation layer 785b-c, the above description of the charge-generation layer 785 can be referred to.

In the structure illustrated in FIG. 12A, the light-emitting layer 771, the light-emitting layer 772, and the light-emitting layer 773 preferably contain light-emitting substances that emit light of the same color. Specifically, the light-emitting layer 771, the light-emitting layer 772, and the light-emitting layer 773 can each contain a light-emitting substance that emits red (R) light (a so-called R\R\R three-unit tandem structure); the light-emitting layer 771, the light-emitting layer 772, and the light-emitting layer 773 can each contain a light-emitting substance that emits green (G) light (a so-called a G\G\G three-unit tandem structure); or the light-emitting layer 771, the light-emitting layer 772, and the light-emitting layer 773 can each contain a light-emitting substance that emits blue (B) light (a so-called B\B\B three-unit tandem structure). Note that in the structure illustrated in FIG. 12A, the light-emitting layer 771, the light-emitting layer 772, and the light-emitting layer 773 may contain light-emitting substances which emit light of different colors. The structure illustrated in FIG. 12A may exhibit white (W) light by mixing light emitted from the light-emitting layer 771, the light-emitting layer 772, and the light-emitting layer 773. In the structure illustrated in FIG. 12A, the layer 764 may be provided as a color filter as in FIG. 12D or FIG. 12F.

Note that the structure containing the light-emitting substances that emit light of the same color is not limited to the above structure. For example, a light-emitting device with a tandem structure may be employed in which light-emitting units each including a plurality of light-emitting substances are stacked as illustrated in FIG. 12B. FIG. 12B illustrates a structure in which a plurality of light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In the structure illustrated in FIG. 12B, emission colors of the light-emitting layer 771a, the light-emitting layer 771b, and the light-emitting layer 771c are mixed so that white (W) light emission can be performed. In addition, emission colors of the light-emitting layer 772a, the light-emitting layer 772b, and the light-emitting layer 772c are mixed so that white (W) light emission can be performed. That is, the structure illustrated in FIG. 12C is a two-unit tandem structure of WWW. Note that there is no particular limitation on the stacking order of the light-emitting layer 771a, the light-emitting layer 771b, and the light-emitting layer 771c. Similarly, there is no particular limitation on the stacking order of the light-emitting layer 772a, the light-emitting layer 772b, and the light-emitting layer 772c. The practitioner can select the optimal stacking order as appropriate. Although not illustrated, a three-unit tandem structure of W\WWW or a tandem structure with four or more units may be employed.

The following structure can be given as the light-emitting device having a tandem structure: a B\Y two-unit tandem structure including a light-emitting unit that emits yellow (Y) light and a light-emitting unit that emits blue (B) light; an RG\B two-unit tandem structure including a light-emitting unit that emits red (R) light and green (G) light and a light-emitting unit that emits blue (B) light; a B\Y\B three-unit tandem structure including a light-emitting unit that emits blue (B) light, a light-emitting unit that emits yellow (Y) light, and a light-emitting unit that emits blue (B) light in this order; a B\YG\B three-unit tandem structure including a light-emitting unit that emits blue (B) light, a light-emitting unit that emits yellow green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order.

As illustrated in FIG. 12C, a light-emitting unit including one light-emitting substance and a light-emitting unit including a plurality of light-emitting substances may be used in combination.

Specifically, in the structure illustrated in FIG. 12C, a plurality of light-emitting units (the light-emitting unit 763a, the light-emitting unit 763b, and the light-emitting unit 763c) are connected in series through the charge-generation layers 785 (the charge-generation layer 785a-b and the charge-generation layer 785b-c). The light-emitting unit 763a includes the layer 780a, the light-emitting layer 771, and the layer 790a. The light-emitting unit 763b includes a layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 12C, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of stacked light-emitting units and the order of colors from an anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Also in FIG. 11C and FIG. 11D, the layer 780 and the layer 790 may each independently have a stacked-layer structure of two or more layers as illustrated in FIG. 11B.

In FIG. 11E and FIG. 11F, the light-emitting unit 763a includes the layer 780a, the light-emitting layer 771, and the layer 790a, and the light-emitting unit 763b includes the layer 780b, the light-emitting layer 772, and the layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are interchanged, and the structures of the layer 780b and the layer 790b are also interchanged.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of fabricating a light-emitting device having a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

Next, materials that can be used for the light-emitting device will be described.

A conductive film transmitting visible light is used for the electrode through which light is extracted, which is either the lower electrode 761 or the upper electrode 762. A conductive film that reflects visible light is preferably used as the electrode through which light is not extracted. In the case where a display apparatus includes a light-emitting device emitting infrared light, a conductive film transmitting visible light and infrared light is preferably used as the electrode through which light is extracted, and a conductive film reflecting visible light and infrared light is preferably used as the electrode through which light is not extracted.

A conductive film transmitting visible light may be used also for the electrode through which light is not extracted. In that case, the electrode is preferably provided between a reflective layer and the EL layer 763. In other words, light emitted from the EL layer 763 may be reflected by the reflective layer to be extracted from the display apparatus.

As a material that forms the pair of electrodes of the light-emitting device, a metal, an alloy, an electrically conductive compound, a mixture thereof, and the like can be used as appropriate. Specific examples of the material include metals such as aluminum, titanium, chromium, manganese, iron, cobalt, nickel, copper, gallium, zinc, indium, tin, molybdenum, tantalum, tungsten, palladium, gold, platinum, silver, yttrium, and neodymium. Other examples of the material include an alloy containing any of the above metals in appropriate combination. Other examples of the material include indium tin oxide (In—Sn oxide, also referred to as ITO), In—Si—Sn oxide (also referred to as ITSO), indium zinc oxide (In—Zn oxide), and In—W—Zn oxide. Other examples of the material include an alloy containing aluminum (aluminum alloy) such as an alloy of aluminum, nickel, and lanthanum (Al—Ni—La), and an alloy of silver, palladium, and copper (Ag—Pd—Cu, also referred to as APC). Other example of the material include elements belonging to Group 1 or Group 2 of the periodic table, which are not exemplified above (e.g., lithium, cesium, calcium, or strontium), rare earth metals such as europium and ytterbium, an alloy containing any of these metals in appropriate combination, and graphene.

The light-emitting device preferably employs a microcavity structure. Therefore, one of the pair of electrodes of the light-emitting devices preferably includes an electrode having a transmitting property and a reflecting property with respect to visible light (a transflective electrode), and the other preferably includes an electrode having a reflecting property with respect to visible light (a reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer that can be used as a reflective electrode and a conductive layer that can be used as an electrode having a visible-light-transmitting property (also referred to as a transparent electrode).

The light transmittance of the transparent electrode is higher than or equal to 40%. For example, an electrode having a visible light (light at wavelengths greater than or equal to 400 nm and less than 750 nm) transmittance higher than or equal to 40% is preferably used in the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least the light-emitting layer. In addition, the light-emitting device may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used for the light-emitting device, and an inorganic compound may also be contained. Each layer included in the light-emitting device can be formed by an evaporation method (including a vacuum evaporation method), a transfer method, a printing method, an inkjet method, a coating method, or the like.

The light-emitting layer contains one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance emitting near-infrared light can be used.

Examples of the light-emitting substance include a fluorescent material, a phosphorescent material, a TADF material, a quantum dot material, and the like.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (guest material). As one or more kinds of organic compounds, one or both of a substance having a high hole-transport property (a hole-transport material) and a substance having a high electron-transport property (an electron-transport material) can be used. As the hole-transport material, it is possible to use a material with a high hole-transport property which can be used for the hole-transport layer and will be described later. As the electron-transport material, it is possible to use a material having a high electron-transport property which can be used for the electron-transport layer and will be described later. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from an exciplex to a light-emitting substance (a phosphorescent material). When a combination of materials is selected so as to form an exciplex that exhibits light emission whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The hole-injection layer is a layer that injects holes from an anode to the hole-transport layer and contains a material with a high hole-injection property. Examples of a material with a high hole-injection property include an aromatic amine compound, and a composite material containing a hole-transport material and an acceptor material (an electron-accepting material).

As the hole-transport material, it is possible to use a material with a high hole-transport property which can be used for the hole-transport layer and will be described later.

As the acceptor material, an oxide of a metal belonging to any of Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is especially preferable because it is stable in the air, has a low hygroscopic property, and is easy to handle. Alternatively, an organic acceptor material containing fluorine can be used. Alternatively, organic acceptor materials such as a quinodimethane derivative, a chloranil derivative, and a hexaazatriphenylene derivative can be used.

For example, a material containing a hole-transport material and an oxide of a metal belonging to Group 4 to Group 8 of the periodic table (typically, molybdenum oxide) described above may be used as the material having a high hole-injection property.

The hole-transport layer is a layer transporting holes, which are injected from the anode by the hole-injection layer, to the light-emitting layer. The hole-transport layer is a layer that contains a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, materials with a high hole-transport property, such as a x-electron rich heteroaromatic compound (e.g., a carbazole derivative, a thiophene derivative, and a furan derivative) and an aromatic amine (a compound having an aromatic amine skeleton), are preferable.

The electron-blocking layer is provided in contact with the light-emitting layer. The electron-blocking layer has a hole-transport property and contains a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer transporting electrons, which are injected from the cathode by the electron-injection layer, to the light-emitting layer. The electron-transport layer is a layer that contains an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a x-electron deficient heteroaromatic compound such as a nitrogen-containing heteroaromatic compound.

The hole-blocking layer is provided in contact with the light-emitting layer. The hole-blocking layer is a layer having an electron-transport property and containing a material that can block holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer that injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The difference between the lowest unoccupied molecular orbital (LUMO) level of the material with a high electron-injection property and the work function value of the material used for the cathode is preferably small (specifically, smaller than or equal to 0.5 eV).

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato) lithium (abbreviation: Liq), 2-(2-pyridyl) phenolatolithium (abbreviation: LiPP), 2-(2-pyridyl)-3-pyridinolato lithium (abbreviation: LiPPy), 4-phenyl-2-(2-pyridyl) phenolatolithium (abbreviation: LiPPP), lithium oxide (LiOₓ), or cesium carbonate, for example. The electron-injection layer may have a stacked-layer structure of two or more layers. In the stacked-layer structure, for example, lithium fluoride can be used for the first layer and ytterbium can be used for the second layer.

The electron-injection layer may contain an electron-transport material. For example, a compound having an unshared electron pair and an electron deficient heteroaromatic ring can be used as the electron-transport material. Specifically, a compound having one or more of a pyridine ring, a diazine ring (e.g., a pyrimidine ring, a pyrazine ring, or a pyridazine ring), and a triazine ring can be used.

Note that the LUMO level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl) biphenyl-3-yl]-1,3,5-triazine (abbreviation: TmPPPyTz), or the like can be used for the organic compound having an unshared electron pair. Note that NBPhen has a higher glass transition temperature (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the above-described hole-injection layer.

The charge-generation layer preferably includes a layer containing a material having a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can be configured to contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the electron-injection layer can be suitably used for the electron-injection buffer layer.

The charge-generation layer preferably includes a layer containing a material having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from each other in some cases on the basis of the cross-sectional shapes, properties, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can suppress an increase in driving voltage.

### Structure Example of Pixel Circuit

Here, structure examples of a pixel circuit that can be included in the pixel layer PXAL will be described.

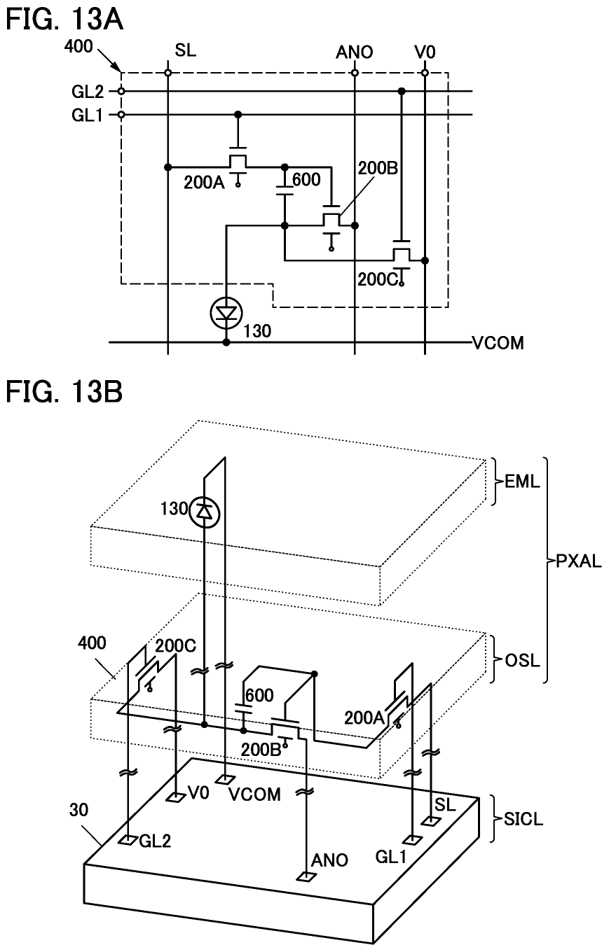

FIG. 13A and FIG. 13B illustrate a structure example of a pixel circuit that can be included in the pixel layer PXAL and the light-emitting device 130 connected to the pixel circuit. FIG. 13A is a diagram illustrating connection of circuit elements included in a pixel circuit 400 included in the pixel layer PXAL, and FIG. 13B is a diagram schematically illustrating the vertical positional relation of the circuit layer SICL including a driver circuit 30 and the like, a layer OSL including a plurality of transistors of the pixel circuit, and a layer EML including the light-emitting device 130. Note that the pixel layer PXAL of the display apparatus 1000 illustrated in FIG. 13B includes the layer OSL and the layer EML, for example. A transistor 200A, a transistor 200B, a transistor 200C, or the like included in the layer OSL illustrated in FIG. 13B corresponds to the transistor 200 in FIG. 6. The light-emitting device 130 included in the layer EML illustrated in FIG. 13B corresponds to the light-emitting device 130R, the light-emitting device 130G, or the light-emitting device 130B in FIG. 6.

The pixel circuit 400 illustrated as an example in FIG. 13A and FIG. 13B includes the transistor 200A, the transistor 200B, the transistor 200C, and a capacitor 600. The transistor 200A, the transistor 200B, and the transistor 200C can be transistors that can be used as the transistor 200 described above as an example. That is, the transistor 200A, the transistor 200B, and the transistor 200C can be LTPS transistors. The transistor 200A, the transistor 200B, and the transistor 200C can be transistors that can be used as the transistor 200 described above as an example. That is, the transistor 200A, the transistor 200B, and the transistor 200C can be OS transistors. In particular, in the case where the transistor 200A, the transistor 200B, and the transistor 200C are OS transistors, each of the transistor 200A, the transistor 200B, and the transistor 200C preferably includes a back gate electrode, in which case a structure in which the back gate electrode is supplied with the same signals as the gate electrode or a structure in which the back gate electrode is supplied with signals different from those supplied to the gate electrode can be employed. Although each of the transistor 200A, the transistor 200B, and the transistor 200C illustrated in FIG. 13A and FIG. 13B includes a back gate electrode, each of the transistor 200A, the transistor 200B, and the transistor 200C does not necessarily include a back gate electrode.

The transistor 200B includes a gate electrode electrically connected to the transistor 200A, a first electrode electrically connected to the light-emitting device 130, and a second electrode electrically connected to a wiring ANO. The wiring ANO is a wiring for supplying a potential for supplying current to the light-emitting device 130.

The transistor 200A includes a first terminal electrically connected to the gate electrode of the transistor 200B, a second terminal electrically connected to the wiring SL functioning as a source line, and the gate electrode having a function of controlling the conducting state or the non-conducting state on the basis of the potential of the wiring GL1 functioning as a gate line.

The transistor 200C includes a first terminal electrically connected to a wiring V0, a second terminal electrically connected to the light-emitting device 130, and the gate electrode having a function of controlling the conducting state or the non-conducting state on the basis of the potential of the wiring GL2 functioning as a gate line. The wiring V0 is a wiring for supplying a reference potential and a wiring for outputting current flowing through the pixel circuit 400 to the driver circuit 30.

The capacitor 600 includes a conductive film electrically connected to the gate electrode of the transistor 200B and a conductive film electrically connected to the second electrode of the transistor 200C.

The light-emitting device 130 includes a first electrode electrically connected to the first electrode of the transistor 200B and a second electrode electrically connected to a wiring VCOM. The wiring VCOM is a wiring for supplying a potential for supplying current to the light-emitting device 130.

Accordingly, the intensity of light emitted from the light-emitting device 130 can be controlled in accordance with an image signal supplied to the gate electrode of the transistor 200B. Furthermore, variations in the gate-source voltage of the transistor 200B can be reduced by the reference potential of the wiring V0 supplied through the transistor 200C.

A current value that can be used for setting pixel parameters can be output from the wiring V0. Specifically, the wiring V0 can function as a monitor line for outputting current flowing through the transistor 200B or current flowing through the light-emitting device 130 to the outside. Current output to the wiring V0 is converted into voltage by a source follower circuit or the like and output to the outside. Alternatively, for example, current output to the wiring V0 can be converted into a digital signal by an A-D converter or the like and output to the AI accelerator or the like included in the external control circuit PRPH described in the above embodiment.

Note that in the structure illustrated as an example in FIG. 13B, the wirings electrically connecting the pixel circuit 400 and the driver circuit 30 can be shortened, so that wiring resistance of the wirings can be reduced. Thus, data writing can be performed at high speed, leading to high-speed operation of the display apparatus 1000. Therefore, even when the number of pixel circuits 400 included in the display apparatus 1000 is increased, a sufficient frame period can be ensured and thus the pixel density of the display apparatus 1000 can be increased. In addition, the increased pixel density of the display apparatus 1000 enables a higher definition image to be displayed on the display apparatus 1000. For example, the pixel density of the display apparatus 1000 can be 500 ppi or higher, preferably 1000 ppi or higher. Thus, the display apparatus 1000 can be, for example, a display apparatus for AR or VR and can be suitably used in an electronic device with a short distance between a display portion and the user, such as an HMD.

Although FIG. 13A and FIG. 13B illustrate, as an example, the pixel circuit 400 including three transistors in total, the pixel circuit of the electronic device of one embodiment of the present invention is not limited thereto. Structure examples of a pixel circuit that can be used as the pixel circuit 400 will be described below.

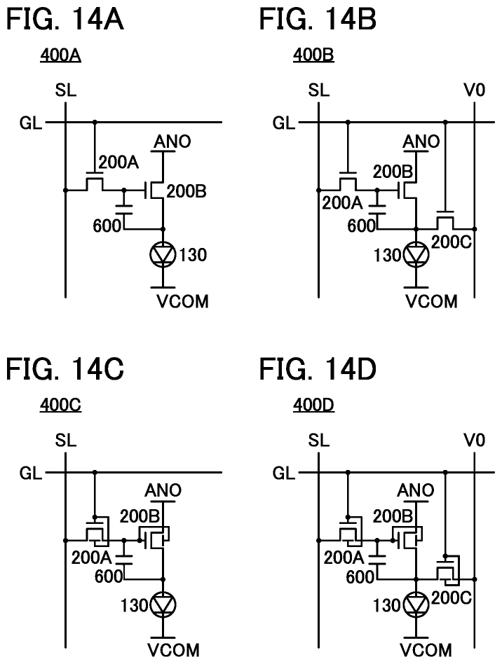

A pixel circuit 400A illustrated in FIG. 14A includes the transistor 200A, the transistor 200B, and the capacitor 600. FIG. 14A illustrates the light-emitting device 130 connected to the pixel circuit 400A. The wiring SL, the wiring GL, the wiring ANO, and the wiring VCOM are electrically connected to the pixel circuit 400A.

A gate of the transistor 200A is electrically connected to the wiring GL, one of a source and a drain of the transistor 200A is electrically connected to the wiring SL, and the other of the source and the drain of the transistor 200A is electrically connected to a gate of the transistor 200B and one electrode of the capacitor 600. One of a source and a drain of the transistor 200B is electrically connected to the wiring ANO and the other of the source and the drain of the transistor 200B is electrically connected to an anode of the light-emitting device 130. The other electrode of the capacitor 600 is electrically connected to the anode of the light-emitting device 130. A cathode of the light-emitting device 130 is electrically connected to the wiring VCOM.

A pixel circuit 400B illustrated in FIG. 14B has a structure in which the transistor 200C is added to the pixel circuit 400A. In addition, the wiring V0 is electrically connected to the pixel circuit 400B.

A pixel circuit 400C illustrated in FIG. 14C is an example of the case in which a transistor having a gate and a back gate electrically connected to each other is used as each of the transistor 200A and the transistor 200B of the pixel circuit 400A. A pixel circuit 400D illustrated in FIG. 14D is an example of the case where such transistors are used in the pixel circuit 400B. Thus, current that can flow through the transistors can be increased. Note that although transistors having a pair of gates electrically connected to each other are used as all the transistors here, one embodiment of the present invention is not limited thereto. A transistor having a pair of gates electrically connected to different wirings may be used. For example, when a transistor in which one of gates is electrically connected to a source is used, the reliability can be increased.

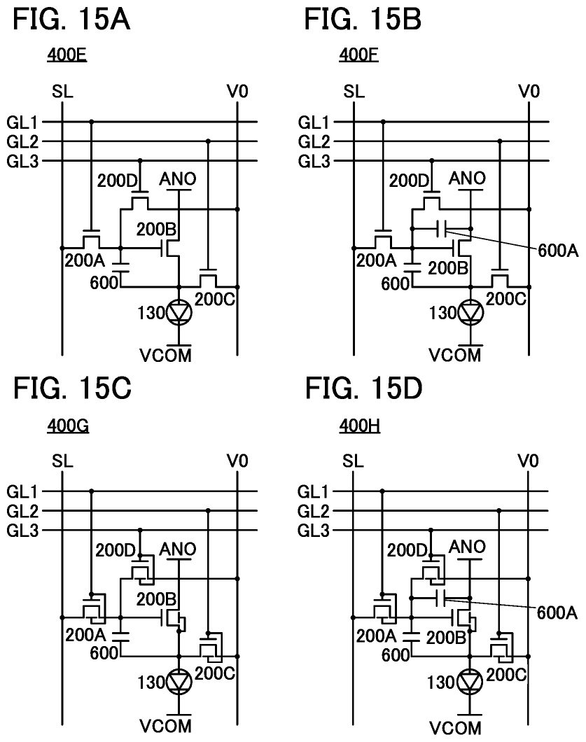

A pixel circuit 400E illustrated in FIG. 15A has a structure in which a transistor 200D is added to the pixel circuit 400B. Three wirings (the wiring GL1, the wiring GL2, and a wiring GL3) functioning as gate lines are electrically connected to the pixel circuit 400E.

A gate of the transistor 200D is electrically connected to the wiring GL3, one of a source and a drain of the transistor 200D is electrically connected to the gate of the transistor 200B, and the other of the source and the drain of the transistor 200D is electrically connected to the wiring V0. The gate of the transistor 200A is electrically connected to the wiring GL1, and the gate of the transistor 200C is electrically connected to the wiring GL2.

When the transistor 200C and the transistor 200D are brought into in conducting states at the same time, the source and the gate of the transistor 200B have the same potential, so that the transistor 200B can be brought into a non-conducting state. Thus, current flowing through the light-emitting device 130 can be blocked forcibly. Such a pixel circuit is suitable for the case of using a display method in which a display period and a non-lighting period are alternately provided.

A pixel circuit 400F illustrated in FIG. 15B is an example of the case where a capacitor 600A is added to the pixel circuit 400E. The capacitor 600A functions as a storage capacitor.

A pixel circuit 400G illustrated in FIG. 15C and a pixel circuit 400H illustrated in FIG. 15D are respectively examples of the cases where transistors each having a gate and a back gate that are electrically connected to each other are used in the pixel circuit 400E and the pixel circuit 400F. A transistor having a gate and a back gate electrically connected to each other is used as each of the transistor 200A, the transistor 200C, and the transistor 200D, and a transistor having a gate and a source electrically connected to each other is used as the transistor 200B.

### <Pixel Layout>

A pixel layout is described here. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

Examples of a top surface shape of the subpixel include polygons such as a triangle, a tetragon (e.g., a rectangle or a square), and a pentagon; polygons with rounded corners; an ellipse; or a circle. Here, the top surface shape of the subpixel corresponds to the top surface shape of a light-emitting region of the light-emitting device.

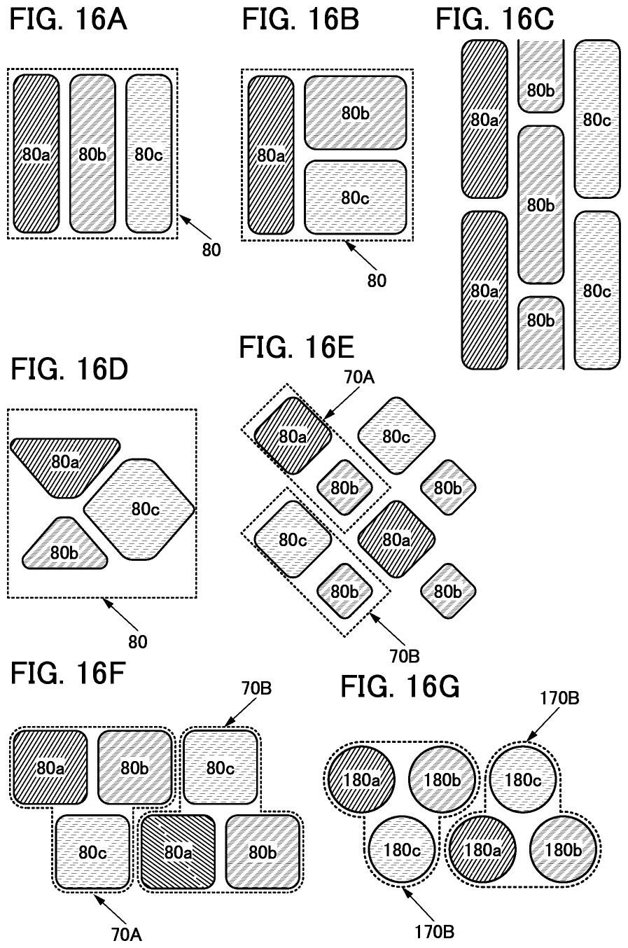

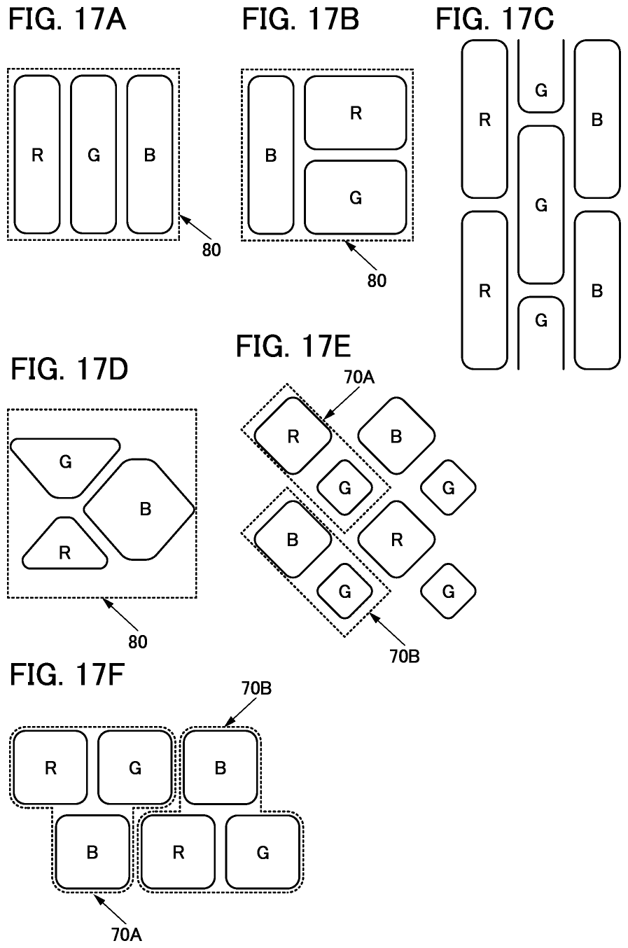

The pixel 80 illustrated in FIG. 16A employs stripe arrangement. The pixel 80 illustrated in FIG. 16A is composed of three subpixels: a subpixel 80a, a subpixel 80b, and a subpixel 80c. For example, as illustrated in FIG. 17A, the subpixel 80a may be a red subpixel R, the subpixel 80b may be a green subpixel G, and the subpixel 80c may be a blue subpixel B.

The pixel 80 illustrated in FIG. 16B employs S-stripe arrangement. The pixel 80 illustrated in FIG. 16B is composed of three subpixels: the subpixel 80a, the subpixel 80b, and the subpixel 80c. For example, as illustrated in FIG. 17B, the subpixel 80a may be the blue subpixel B, the subpixel 80b may be the red subpixel R, and the subpixel 80c may be the green subpixel G.

FIG. 16C illustrates an example in which subpixels of different colors are arranged in a zigzag manner. Specifically, the positions of the top sides of two subpixels arranged in the column direction (e.g., the subpixel 80a and the subpixel 80b or the subpixel 80b and the subpixel 80c) are not aligned in the plan view. For example, as illustrated in FIG. 17C, the subpixel 80a may be the red subpixel R, the subpixel 80b may be the green subpixel G, and the subpixel 80c may be the blue subpixel B.

The pixel 80 illustrated in FIG. 16D includes the subpixel 80a whose top surface has a rough trapezoidal shape with rounded corners, the subpixel 80b whose top surface has a rough triangle shape with rounded corners, and the subpixel 80c whose top surface has a rough quadrilateral or rough hexagonal shape with rounded corners. The subpixel 80a has a larger light-emitting area than the subpixel 80b. In this manner, the shapes and sizes of the subpixels can be determined independently. For example, the size of a subpixel including a light-emitting device with higher reliability can be smaller. For example, as illustrated in FIG. 17D, the subpixel 80a may be the green subpixel G, the subpixel 80b may be the red subpixel R, and the subpixel 80c may be the blue subpixel B.

A pixel 70A and a pixel 70B illustrated in FIG. 16E employ pentile arrangement. FIG. 16E illustrates an example in which the pixels 70A including the subpixel 80a and the subpixel 80b and the pixels 70B including the subpixel 80b and the subpixel 80c are alternately arranged. For example, as illustrated in FIG. 17E, the subpixel 80a may be the red subpixel R, the subpixel 80b may be the green subpixel G, and the subpixel 80c may be the blue subpixel B.

The pixel 70A and the pixel 70B illustrated in FIG. 16F and FIG. 16G employ delta arrangement. The pixel 70A includes two subpixels (the subpixel 80a and the subpixel 80b) in the upper row (first row) and one subpixel (the subpixel 80c) in the lower row (second row). The pixel 70B includes one subpixel (the subpixel 80c) in the upper row (first row) and two subpixels (the subpixel 80a and the subpixel 80b) in the lower row (second row). For example, as illustrated in FIG. 17F, the subpixel 80a may be the red subpixel R, the subpixel 80b may be the green subpixel G, and the subpixel 80c may be the blue subpixel B.

FIG. 16F illustrates an example in which the top surface of each subpixel has a rough quadrilateral shape with rounded corners, and FIG. 16G illustrates an example in which the top surface of each subpixel has a circular shape.

In a photolithography method, as a pattern to be processed becomes finer, the influence of light diffraction becomes more difficult to ignore; accordingly, fidelity in transferring a photomask pattern by light exposure is degraded, and it becomes difficult to process a resist mask into a desired shape. Thus, a pattern with rounded corners is likely to be formed even with a rectangular photomask pattern. Consequently, a top surface shape of a subpixel becomes a polygon with rounded corners, an ellipse, or a circle in some cases.

Furthermore, in the method for manufacturing the display apparatus of one embodiment of the present invention, the EL layer is processed into an island shape with the use of a resist mask. A resist film formed over the EL layer needs to be cured at a temperature lower than the upper temperature limit of the EL layer. Thus, the resist film is insufficiently cured in some cases depending on the upper temperature limit of the material of the EL layer and the curing temperature of a resist material. An insufficiently cured resist film might have a shape different from a desired shape at the time of processing. As a result, a top surface of the EL layer has a polygonal shape with rounded corners, an elliptical shape, a circular shape, or the like in some cases. For example, when a resist mask with a square top surface is intended to be formed, a resist mask with a circular top surface might be formed, and the top surface of the EL layer might be circular.

Note that to obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

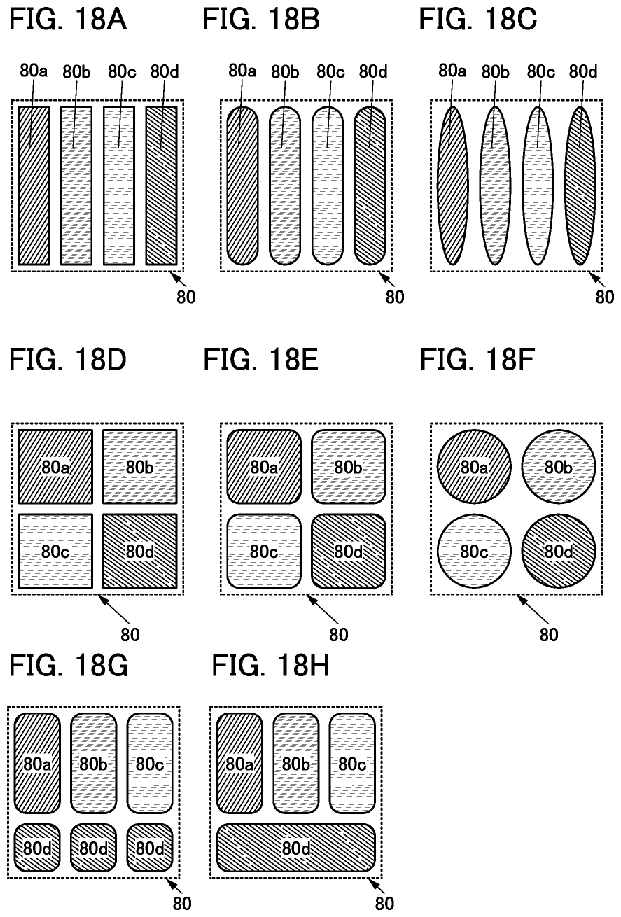

The pixels 80 illustrated in FIG. 18A to FIG. 18C employ stripe arrangement.

FIG. 18A illustrates an example where each subpixel has a rectangular top surface shape, FIG. 18B illustrates an example where each subpixel has a top surface shape formed by combining two half circles and a rectangle, and FIG. 18C illustrates an example where each subpixel has an elliptical top surface shape.

The pixels 80 illustrated in FIG. 18D to FIG. 18F employ matrix arrangement.

FIG. 18D illustrates an example where each subpixel has a square top surface shape, FIG. 18E illustrates an example where each subpixel has a rough square top surface shape with rounded corners, and FIG. 18F illustrates an example where each subpixel has a circular top surface shape.

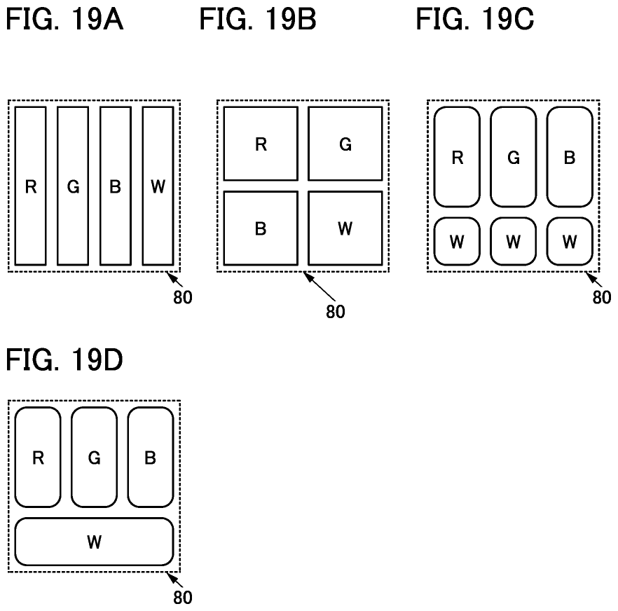

The pixels 80 illustrated in FIG. 18A to FIG. 18F are each configured with four subpixels: the subpixel 80a, the subpixel 80b, the subpixel 80c, and a subpixel 80d. The subpixel 80a, the subpixel 80b, the subpixel 80c, and the subpixel 80d emit light of different colors. For example, the subpixel 80a, the subpixel 80b, the subpixel 80c, and the subpixel 80d can be red, green, blue, and white subpixels, respectively. For example, the subpixel 80a, the subpixel 80b, the subpixel 80c, and the subpixel 80d can be red, green, blue, and white subpixels, respectively, as illustrated in FIG. 19A and FIG. 19B. Alternatively, the subpixel 80a, the subpixel 80b, the subpixel 80c, and the subpixel 80d can be red, green, blue, and infrared-light subpixels, respectively.

The subpixel 80d includes a light-emitting device. The light-emitting device includes, for example, a pixel electrode, an EL layer, and a common electrode. The pixel electrode can be formed using a material similar to that for the conductor 112a to the conductor 112c or the conductor 126a to the conductor 126c. The EL layer is formed using a material similar to that for the first layer 113a, the second layer 113b, or the third layer 113c, for example.

FIG. 18G illustrates an example in which one pixel 80 is configured with two rows and three columns. The pixel 80 includes three subpixels (the subpixel 80a, the subpixel 80b, and the subpixel 80c) in the upper row (first row) and three subpixels 80d in the lower row (second row). In other words, the pixel 80 includes the subpixel 80a and the subpixel 80d in the left column (first column), the subpixel 80b and another subpixel 80d in the center column (second column), and the subpixel 80c and another subpixel 80d in the right column (third column). Matching the positions of the subpixels in the upper row and the lower row as illustrated in FIG. 18G enables dust and the like that would be produced in the manufacturing process to be removed efficiently. Thus, a display apparatus with high display quality can be provided.

FIG. 18H illustrates an example in which one pixel 80 is configured with two rows and three columns. The pixel 80 includes three subpixels (the subpixel 80a, the subpixel 80b, and the subpixel 80c) in the upper row (first row) and one subpixel (the subpixel 80d) in the lower row (second row). In other words, the pixel 80 includes the subpixel 80a in the left column (first column), the subpixel 80b in the center column (second column), the subpixel 80c in the right column (third column), and the subpixel 80d across these three columns.

In the pixel 80 illustrated in each of FIG. 18G and FIG. 18H, for example, the subpixel 80a can be the red subpixel R, the subpixel 80b can be the green subpixel G, the subpixel 80c can be the blue subpixel B, and the subpixel 80d can be a white subpixel W, as illustrated in FIG. 19C and FIG. 19D.

Note that the insulators, the conductors, the semiconductors, and the like disclosed in this specification and the like can be formed by a PVD (Physical Vapor Deposition) method or a CVD method. Examples of a PVD method include a sputtering method, a resistance heating evaporation method, an electron beam evaporation method, and a PLD (Pulsed Laser Deposition) method. Examples of the CVD method include a plasma CVD method and a thermal CVD method. In particular, examples of a thermal CVD method include a MOCVD (Metal Organic Chemical Vapor Deposition) method and an ALD (Atomic Layer Deposition) method.

A thermal CVD method, which is a deposition method not using plasma, has an advantage that a defect due to plasma damage is not generated.

Deposition by a thermal CVD method may be performed in the following manner: a source gas and an oxidizer are supplied into a chamber at a time, the pressure in the chamber is set to an atmospheric pressure or a reduced pressure, and they are made to react with each other in the vicinity of the substrate or over the substrate to be deposited over the substrate.

Deposition by an ALD method may be performed in the following manner: pressure in a chamber is set to an atmospheric pressure or a reduced pressure, source gases for reaction are sequentially introduced into the chamber, and then the sequence of the gas introduction is repeated. For example, two or more kinds of source gases are sequentially supplied to the chamber by switching respective switching valves (also referred to as high-speed valves); in order to avoid mixing of the plurality of kinds of source gases, an inert gas (e.g., argon or nitrogen) or the like is introduced at the same time as or after introduction of a first source gas and then a second source gas is introduced. Note that in the case where the inert gas are introduced at the same time, the inert gas serves as a carrier gas, and the inert gas may also be introduced at the same time as the introduction of the second source gas. Alternatively, the second source gas may be introduced after the first source gas is exhausted by vacuum evacuation instead of the introduction of the inert gas. The first source gas is adsorbed on the surface of the substrate to form a first thin layer, and then the second source gas is introduced to react with the first thin layer; as a result, a second thin layer is stacked over the first thin layer, so that a thin film is formed. The sequence of the gas introduction is controlled and repeated a plurality of times until a desired thickness is obtained, so that a thin film with excellent step coverage can be formed. The thickness of the thin film can be adjusted by the number of repetition times of the sequence of the gas introduction; therefore, an ALD method makes it possible to accurately adjust the thickness and is thus suitable for fabricating a minute FET.

A variety of films such as the metal film, the semiconductor film, and the inorganic insulating film disclosed in the above-described embodiments can be formed by a thermal CVD method such as an MOCVD method or an ALD method; for example, in the case of depositing an In—Ga—Zn—O film, trimethylindium (In(CH₃)₃), trimethylgallium (Ga(CH₃)₃), and dimethylzinc (Zn(CH₃)₂) are used. Without limitation to the above combination, triethylgallium (Ga(C₂H₅)₃) can also be used instead of trimethylgallium, and diethylzinc (Zn(C₂H₅)₂) can also be used instead of dimethylzinc.

For example, in the case where a hafnium oxide film is formed with a deposition apparatus utilizing an ALD method, two kinds of gases, ozone (O₃) as an oxidizer and a source gas which is obtained by vaporizing liquid containing a solvent and a hafnium precursor compound (e.g., hafnium alkoxide or hafnium amide such as tetrakis (dimethylamide) hafnium (TDMAH, Hf[N(CH₃)₂]₄)), are used. Examples of another material include tetrakis (ethylmethylamide) hafnium.

For example, in the case where an aluminum oxide film is formed with a deposition apparatus utilizing an ALD method, two kinds of gases, H₂O as an oxidizer and a source gas which is obtained by vaporizing liquid containing a solvent and an aluminum precursor compound (e.g., trimethylaluminum (TMA, Al(CH₃)₃)), are used. Examples of another material include tris (dimethylamide)aluminum, triisobutylaluminum, and aluminum tris (2,2,6,6-tetramethyl-3,5-heptanedionate).

For example, in the case where a silicon oxide film is formed with a deposition apparatus utilizing an ALD method, hexachlorodisilane is adsorbed on a surface on which a film is to be formed, and radicals of an oxidizing gas (e.g., O₂ or dinitrogen monoxide) are supplied to react with the adsorbate.

For example, in the case where a tungsten film is formed with a deposition apparatus utilizing an ALD method, a WF₆ gas and a B₂H₆ gas are sequentially and repeatedly introduced to form an initial tungsten film, and then a WF₆ gas and an H₂ gas are sequentially and repeatedly introduced to form a tungsten film. Note that a SiH₄ gas may be used instead of a B₂H₆ gas.

In the case where an In—Ga—Zn—O film is formed as an oxide semiconductor film with a deposition apparatus using an ALD method, a precursor (generally referred to as a precursor or a metal precursor or the like in some cases) and an oxidizer (generally referred to as a reagent, a reactant, a non-metal precursor, or the like in some cases) are sequentially and repetitively introduced. Specifically, for example, an In(CH₃)₃ gas as a precursor and an O₃ gas as an oxidizer are introduced to form an In—O layer; a Ga(CH₃)₃ gas as a precursor and an O₃ gas as an oxidizer are introduced to form a GaO layer; and then, a Zn(CH₃)₂ gas as a precursor and an O₃ gas as an oxidizer are introduced to form a ZnO layer. Note that the order of these layers is not limited to this example. A mixed oxide layer such as an In—Ga—O layer, an In—Zn—O layer, or a Ga—Zn—O layer may be formed with the use of these gases. Note that although an H₂O gas which is obtained by bubbling water with an inert gas such as Ar may be used instead of an O₃ gas, it is preferable to use an O₃ gas which does not contain H. Furthermore, instead of an In(CH₃)₃ gas, an In(C₂H₅)₃ gas may be used. Furthermore, instead of a Ga(CH₃)₃ gas, a Ga(C₂H₅)₃ gas may be used. Furthermore, a Zn(CH₃)₂ gas may be used.

There is no particular limitation on the screen ratio (aspect ratio) of the display portion of the electronic device of one embodiment of the present invention. For example, the display portion is compatible with a variety of screen ratios such as 1:1 (a square), 4:3, 16:9, and 16:10.

There is no particular limitation on the shape of the display portion of the electronic device of one embodiment of the present invention. The display portion can have any of various shapes such as a rectangular shape, a polygonal shape (e.g., octagon), a circular shape, and an elliptical shape.

Note that this embodiment can be combined with any of the other embodiments in this specification as appropriate.

### Embodiment 3

Described in this embodiment is a metal oxide (hereinafter, also referred to as an oxide semiconductor) that can be used in the OS transistor described in the above embodiment.

The metal oxide used in the OS transistor preferably contains at least indium or zinc, and further preferably contains indium and zinc. The metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin, and M is further preferably gallium.

The metal oxide can be formed by a sputtering method, a chemical vapor deposition (CVD) method such as a metal organic chemical vapor deposition (MOCVD) method, or an atomic layer deposition (ALD) method.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### <Classification of Crystal Structure>

Amorphous (including completely amorphous), CAAC (c-axis-aligned crystalline), nc (nanocrystalline), CAC (cloud-aligned composite), single crystal, and polycrystalline (poly crystal) can be given as examples of a crystal structure of an oxide semiconductor.

Note that a crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method. Hereinafter, an XRD spectrum obtained from GIXD measurement is simply referred to as an XRD spectrum in some cases.

For example, the XRD spectrum of a quartz glass substrate shows a peak with a substantially bilaterally symmetrical shape. On the other hand, the peak of the XRD spectrum of the In—Ga—Zn oxide film having a crystal structure has a bilaterally asymmetrical shape. The asymmetrical peak of the XRD spectrum clearly shows the existence of a crystal in the film or the substrate. In other words, the film or the substrate cannot be regarded as being in an amorphous state unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of a quartz glass substrate, which indicates that the quartz glass substrate is in an amorphous state. Furthermore, not a halo pattern but a spot-like pattern is observed in the diffraction pattern of an In—Ga—Zn oxide film formed at room temperature. This suggests that the In—Ga—Zn oxide film formed at room temperature is in an intermediate state, which is neither a single crystal nor polycrystal nor an amorphous state, and it cannot be concluded that the In—Ga—Zn oxide film is in an amorphous state.

### <<Structure of Oxide Semiconductor>>

Note that oxide semiconductors may be classified in a manner different from the above when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the CAAC-OS, the nc-OS, and the a-like OS will be described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one minute crystal, the maximum diameter of the crystal region is less than 10 nm. In the case where the crystal region is formed of a large number of fine crystals, the maximum diameter of the crystal region may be approximately several tens of nanometers.

In the case of an In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga,Zn) layer) are stacked. Indium and gallium can be replaced with each other. Therefore, indium may be contained in the (Ga,Zn) layer. In addition, gallium may be contained in the In layer. Note that zinc may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at or around 2θ of 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (also referred to as grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure where a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor is sometimes decreased by one or both of entry of impurities and formation of defects, the CAAC-OS can be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter greater than the diameter of a nanocrystal (e.g., greater than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm).

[a-like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

### <<Structure of Oxide Semiconductor>>

Next, the above-described CAC-OS will be described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state where one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic proportions of In, Ga, and Zn in the metal elements contained in the CAC-OS in an In—Ga—Zn oxide are denoted by [In], [Ga], and [Zn], respectively. For example, the first region in the CAC-OS in the In—Ga—Zn oxide is a region having [In] higher than [In] in the composition of the CAC-OS film. Moreover, the second region is a region having [Ga] higher than [Ga] in the composition of the CAC-OS film. For example, the first region is a region having [In] higher than [In] in the second region and [Ga] lower than [Ga] in the second region. Moreover, the second region is a region having [Ga] higher than [Ga] in the first region and [In] lower than [In] in the first region.

Specifically, the first region is a region containing indium oxide, indium zinc oxide, or the like as its main component. The second region is a region containing gallium oxide, gallium zinc oxide, or the like as its main component. That is, the first region can be rephrased as a region containing In as its main component. The second region can be rephrased as a region containing Ga as its main component.

Note that a clear boundary between the first region and the second region cannot be observed in some cases.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions each form a mosaic pattern and are randomly present. Thus, it is suggested that the CAC-OS has a structure where metal elements are unevenly distributed.

The CAC-OS can be formed by a sputtering method under a condition where a substrate is not heated, for example. Moreover, in the case of forming the CAC-OS by a sputtering method, any one or more selected from an inert gas (typically, argon), an oxygen gas, and a nitrogen gas are used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas is preferably higher than or equal to 0% and lower than 30%, further preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure where the region containing In as its main component (the first region) and the region containing Ga as its main component (the second region) are unevenly distributed and mixed.

Here, the first region is a region having higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

The second region is a region having a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Ion), high field-effect mobility (u), and excellent switching operation can be achieved.

A transistor using the CAC-OS has high reliability. Thus, the CAC-OS is most suitable for a variety of semiconductor devices such as a display apparatus.

An oxide semiconductor has various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Transistor Including Oxide Semiconductor>

Next, the case where the above oxide semiconductor is used for a transistor will be described.

When the above oxide semiconductor is used for a transistor, a transistor with high field-effect mobility can be achieved. In addition, a transistor with high reliability can be achieved.

It is particularly preferable to use an oxide containing indium (In), gallium (Ga), and zinc (Zn) (also referred to as “IGZO”) for a semiconductor layer where a channel is formed. Alternatively, an oxide containing indium (In), aluminum (Al), and zinc (Zn) (also referred to as “IAZO”) may be used for the semiconductor layer. Alternatively, an oxide containing indium (In), aluminum (Al), gallium (Ga), and zinc (Zn) (also referred to as “IAGZO”) may be used for the semiconductor layer.

An oxide semiconductor having a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Charges trapped by the trap states in an oxide semiconductor take a long time to be released and may behave like fixed charges. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon. Note that an impurity in an oxide semiconductor refers to, for example, elements other than the main components of the oxide semiconductor. For example, an element with a concentration lower than 0.1 atomic % can be regarded as an impurity.

### <Impurity>

Here, the influence of each impurity in the oxide semiconductor will be described.

When silicon or carbon, which is one of Group 14 elements, is contained in the oxide semiconductor, defect states are formed in the oxide semiconductor. Thus, the concentration of silicon or carbon (the concentration obtained by secondary ion mass spectrometry (SIMS)) in the semiconductor layer is set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

An oxide semiconductor containing nitrogen easily becomes n-type by generation of electrons serving as carriers and an increase in carrier concentration. As a result, a transistor using an oxide semiconductor that contains nitrogen as a semiconductor is likely to have normally-on characteristics. When nitrogen is contained in the oxide semiconductor, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in an oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the oxide semiconductor is preferably reduced as much as possible. Specifically, the concentration of hydrogen in the oxide semiconductor, which is measured by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

The structures described in this embodiment can be used in an appropriate combination with the structures described in the other embodiments.

### Embodiment 4

In this embodiment, a display module that can be used for the electronic device of one embodiment of the present invention will be described.

### Structure Example of Display Module

First, a display module including the display apparatus that can be used for the electronic device of one embodiment of the present invention will be described.

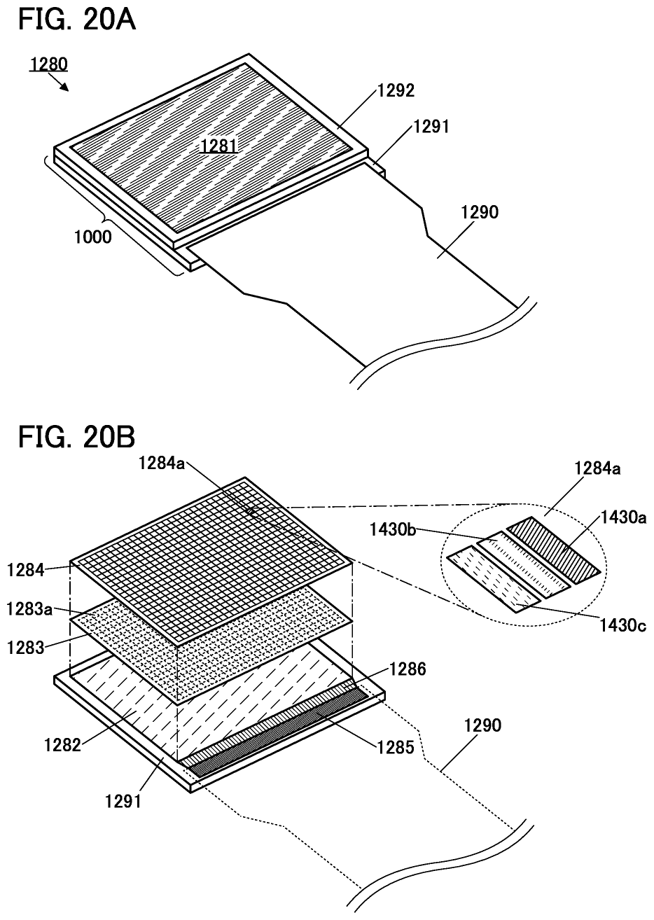

FIG. 20A is a perspective view of a display module 1280. The display module 1280 includes the display apparatus 1000 and an FPC 1290.

The display module 1280 includes a substrate 1291 and a substrate 1292. The display module 1280 includes a display portion 1281. The display portion 1281 is a region of the display module 1280 where an image is displayed, and is a region where light emitted from pixels provided in a pixel portion 1284 described later can be seen.

FIG. 20B is a perspective view schematically illustrating a structure on the substrate 1291 side. A circuit portion 1282, a pixel circuit portion 1283 over the circuit portion 1282, and the pixel portion 1284 over the pixel circuit portion 1283 are stacked over the substrate 1291. In addition, a terminal portion 1285 for connection to the FPC 1290 is provided in a portion not overlapping with the pixel portion 1284 over the substrate 1291. The terminal portion 1285 and the circuit portion 1282 are electrically connected to each other through a wiring portion 1286 formed of a plurality of wirings.

Note that the pixel portion 1284 and the pixel circuit portion 1283 correspond to the pixel layer PXAL described above, for example. The circuit portion 1282 corresponds to the circuit layer SICL described above, for example.

The pixel portion 1284 includes a plurality of pixels 1284a arranged periodically. An enlarged view of one pixel 1284a is illustrated on the right side in FIG. 20B. The pixel 1284a includes a light-emitting device 1430a, a light-emitting device 1430b, and a light-emitting device 1430c that emit light of different colors. Note that the light-emitting device 1430a, the light-emitting device 1430b, and the light-emitting device 1430c correspond to the light-emitting device 130R, the light-emitting device 130G, and the light-emitting device 130B described above, for example. The above-described light-emitting devices may be arranged in a stripe pattern as illustrated in FIG. 20B. Alternatively, a variety of arrangement methods, such as delta arrangement and pentile arrangement, can be employed.

The pixel circuit portion 1283 includes a plurality of pixel circuits 1283a arranged periodically.

One pixel circuit 1283a is a circuit that controls light emission from three light-emitting devices included in one pixel 1284a. One pixel circuit 1283a may be provided with three circuits each of which controls light emission from one light-emitting device. For example, the pixel circuit 1283a can include at least one selection transistor, one current control transistor (driving transistor), and a capacitor for one light-emitting device. In that case, a gate signal is input to a gate of the selection transistor, and a source signal is input to one of a source and a drain of the selection transistor. Thus, an active-matrix display apparatus is achieved.

The circuit portion 1282 includes a circuit for driving the pixel circuits 1283a in the pixel circuit portion 1283. For example, one or both of a gate line driver circuit and a source line driver circuit are preferably included. In addition, one or more selected from an arithmetic circuit, a memory circuit, and a power supply circuit may be included.

The FPC 1290 functions as a wiring for supplying a video signal or a power supply potential to the circuit portion 1282 from the outside. In addition, an IC may be mounted on the FPC 1290.

The display module 1280 can have a structure in which one or both of the pixel circuit portion 1283 and the circuit portion 1282 are stacked below the pixel portion 1284; thus, the aperture ratio (the effective display area ratio) of the display portion 1281 can be significantly high.

Note that this embodiment can be combined with any of the other embodiments described in this specification as appropriate.

### Embodiment 5

In this embodiment, electronic devices each including a display apparatus will be described as examples of an electronic device of one embodiment of the present invention.

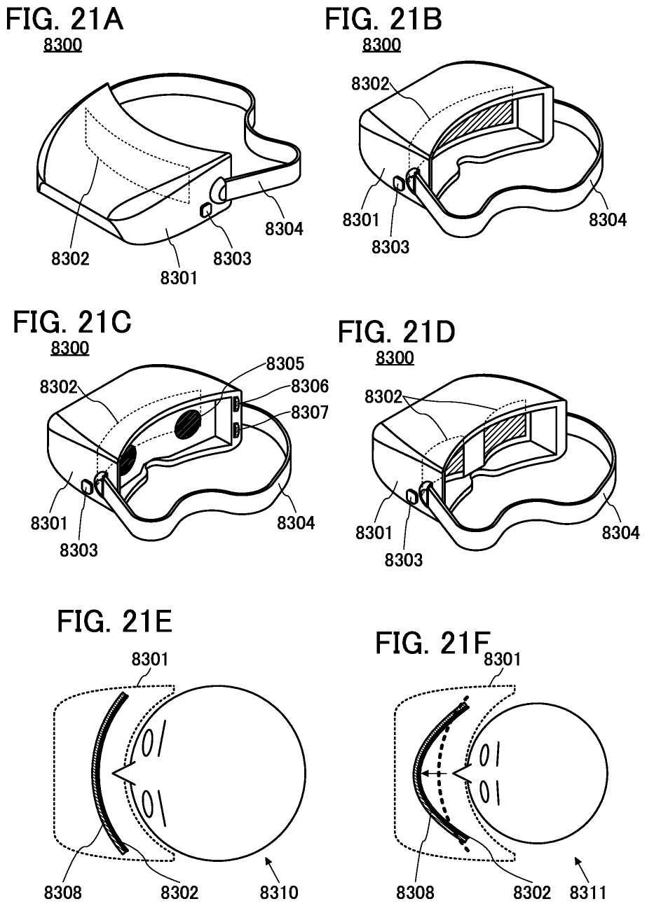

FIG. 21A and FIG. 21B each illustrate an appearance of an electronic device 8300 that is a head-mounted display.

The electronic device 8300 includes a housing 8301, a display portion 8302, an operation button 8303, and a band-shaped fixing unit 8304.

The operation button 8303 has a function of a power button or the like. The electronic device 8300 may include a button other than the operation button 8303.

As illustrated in FIG. 21C, lenses 8305 may be included between the display portion 8302 and the positions of the user's eyes. The user can see magnified images on the display portion 8302 through the lenses 8305, leading to a higher realistic sensation. In that case, as illustrated in FIG. 21C, a dial 8306 for changing the positions of the lenses to adjust visibility may be included.

For the display portion 8302, an extremely high-definition display apparatus is preferably used, for example. When a high-definition display apparatus is used for the display portion 8302, it is possible to display a more realistic image that does not allow the user to perceive pixels even when the image is magnified using the lenses 8305 as illustrated in FIG. 21C.

FIG. 21A to FIG. 21C illustrate an example in which one display portion 8302 is provided. Such a structure can reduce the number of components.

The display portion 8302 can display an image for the right eye and an image for the left eye side by side on a right region and a left region, respectively. Thus, a three-dimensional image using binocular disparity can be displayed.

One image that can be seen by both eyes may be displayed on the entire display portion 8302. A panorama image can thus be displayed from end to end of the field of view, which can provide a stronger sense of reality.

Here, the display portion 8302 of the electronic device 8300 preferably has a mechanism for changing the curvature of the display portion 8302 to an optimal value in accordance with the size of the user's head, the positions of the user's eyes, or the like. For example, the user himself or herself may adjust the curvature of the display portion 8302 by operating a dial 8307 for adjusting the curvature of the display portion 8302. Alternatively, a sensor for detecting the size of the user's head, the positions of the user's eyes, or the like (e.g., a camera, a contact sensor, or a noncontact sensor) may be provided on the housing 8301, and a mechanism for adjusting the curvature of the display portion 8302 on the basis of detection data obtained by the sensor may be provided.

In the case where the lenses 8305 are used, a mechanism for adjusting the positions and angle of the lenses 8305 in synchronization with the curvature of the display portion 8302 is preferably provided. Alternatively, the dial 8306 may have a function of adjusting the angle of the lenses.

FIG. 21E and FIG. 21F illustrate an example in which a driver portion 8308 controlling the curvature of the display portion 8302 is provided. The driver portion 8308 is fixed to at least part of the display portion 8302. The driver portion 8308 has a function of changing the shape of the display portion 8302 when the part that is fixed to the display portion 8302 changes in shape or moves.

FIG. 21E is a schematic view illustrating the case where a user 8310 having a relatively large head wears the housing 8301. In that case, the driver portion 8308 adjusts the shape of the display portion 8302 such that the curvature is relatively small (the radius of curvature is large).

By contrast, FIG. 21F illustrates the case where a user 8311 having a smaller head than the user 8310 wears the housing 8301. The user 8311 has a shorter distance between the eyes than the user 8310. In that case, the driver portion 8308 adjusts the shape of the display portion 8302 such that the curvature of the display portion 8302 is large (the radius of curvature is small). In FIG. 21F, the position and shape of the display portion 8302 in FIG. 21E are denoted by a dashed line.

When the electronic device 8300 has such a mechanism for adjusting the curvature of the display portion 8302, an optimal display can be offered to a variety of users of all ages and genders.

When the curvature of the display portion 8302 is changed in accordance with contents displayed on the display portion 8302, the user can have a more realistic sensation. For example, shaking can be expressed by fluctuating the curvature of the display portion 8302. In this way, it is possible to produce various effects depending on the scene in contents, and provide the user with new experiences. A further realistic display can be provided when the display portion 8302 operates in conjunction with a vibration module provided in the housing 8301.

Note that the electronic device 8300 may include two display portions 8302 as illustrated in FIG. 21D.

Since the two display portions 8302 are included, the user's eyes can see their respective display portions. This allows a high screen resolution image to be displayed even when three-dimensional display using parallax or the like is performed. In addition, the display portion 8302 is curved around an arc with the user's eye as an approximate center. This allows a uniform distance between the user's eye and the display surface of the display portion; thus, the user can see a more natural image. Even when the luminance or chromaticity of light from the display portion is changed depending on the angle at which the user sees it, since the user's eye is positioned in a normal direction of the display surface of the display portion, the influence of the change can be substantially ignorable and thus a more realistic image can be displayed.

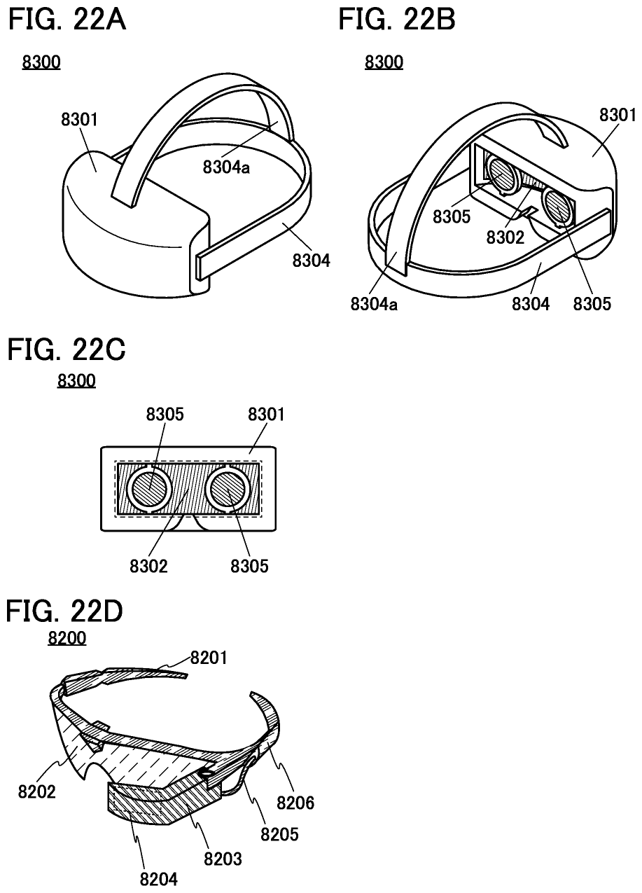

FIG. 22A to FIG. 22C are diagrams illustrating an appearance of another electronic device 8300, which is different from the electronic devices 8300 illustrated in FIG. 21A to FIG. 21D. Specifically, FIG. 22A to FIG. 22C are different from FIG. 21A to FIG. 21D in including a fixing unit 8304a worn on a head and a pair of lenses 8305, for example.

A user can see display on the display portion 8302 through the lenses 8305. The display portion 8302 is preferably curved so that the user can feel high realistic sensation. Another image displayed on another region of the display portion 8302 is seen through the lenses 8305, so that three-dimensional display using parallax or the like can be performed. Note that the structure is not limited to the structure in which one display portion 8302 is provided; two display portions 8302 may be provided and one display portion may be provided per eye of the user.

For the display portion 8302, an extremely high-definition display apparatus is preferably used, for example. When a high-definition display apparatus is used for the display portion 8302, it is possible to display a more realistic image that does not allow the user to perceive pixels even when the image is magnified using the lenses 8305 as illustrated in FIG. 22C.

The head-mounted display, which is an electronic device of one embodiment of the present invention, may be an electronic device 8200 illustrated in FIG. 22D, which is a glasses-type head-mounted display.

The electronic device 8200 includes a mounting portion 8201, a lens 8202, a main body 8203, a display portion 8204, and a cable 8205. A battery 8206 is incorporated in the mounting portion 8201.

The cable 8205 supplies power from the battery 8206 to the main body 8203. The main body 8203 includes a wireless receiver or the like and can display received image information on the display portion 8204. The main body 8203 includes a camera, and information on the movement of the eyeballs or the eyelids of the user can be used as an input means.

The mounting portion 8201 may include a plurality of electrodes capable of sensing current flowing accompanying with the movement of the user's eyeballs at a position in contact with the user to have a function of recognizing the user's sight line. The mounting portion 8201 may also have a function of monitoring the user's pulse with use of current flowing through the electrodes. The mounting portion 8201 may include a variety of sensors such as a temperature sensor, a pressure sensor, or an acceleration sensor to have a function of displaying the user's biological information on the display portion 8204, a function of changing an image displayed on the display portion 8204 in accordance with the movement of the user's head, and the like.

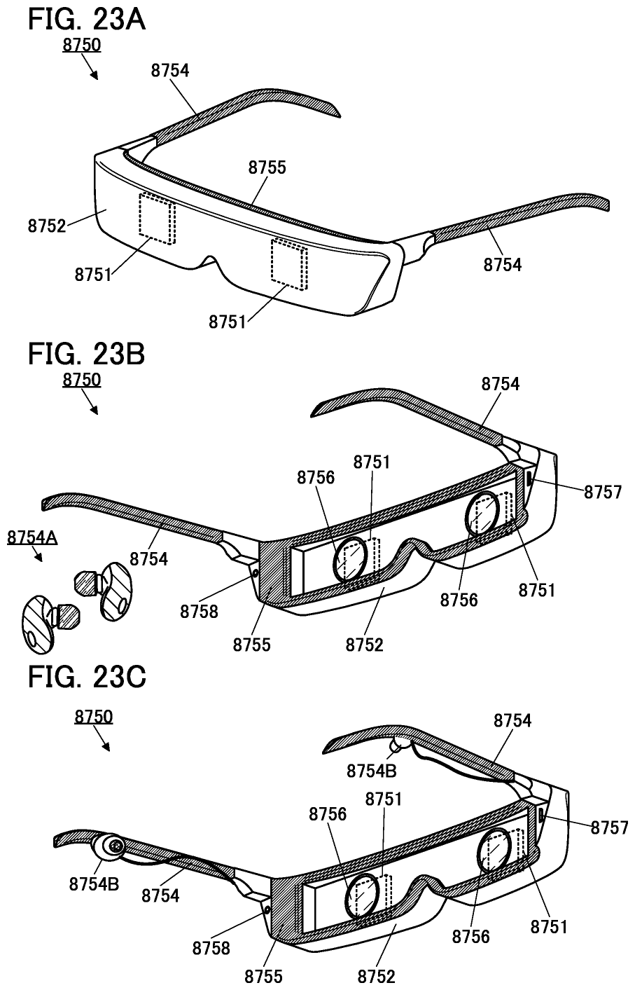

FIG. 23A to FIG. 23C are diagrams illustrating an appearance of an electronic device 8750, which is different from the electronic devices 8300 illustrated in FIG. 21A to FIG. 21D and FIG. 22A to FIG. 22C and the electronic device 8200 illustrated in FIG. 22D.

FIG. 23A is a perspective view illustrating the front surface, the top surface, and the left side surface of the electronic device 8750, and FIG. 23B and FIG. 23C are each a perspective view illustrating the back surface, the bottom surface, and the right side surface of the electronic device 8750.

The electronic device 8750 includes a pair of display apparatuses 8751, a housing 8752, a pair of mounting portions 8754, a cushion 8755, a pair of lenses 8756, and the like. The pair of display apparatuses 8751 is positioned to be seen through the lenses 8756 inside the housing 8752.

Here, one of the pair of display apparatuses 8751 corresponds to the display apparatus DSP described in Embodiment 1, for example. Although not illustrated, the electronic device 8750 illustrated in FIG. 23A to FIG. 23C includes an electronic component including the processing unit described in the above embodiment (e.g., the circuits included in the control circuit PRPH illustrated in FIG. 5). Although not illustrated, the electronic device 8750 illustrated in FIG. 23A to FIG. 23C includes a camera. The camera can take an image of the user's eye and its periphery. Although not illustrated, in the housing 8752 of the electronic device 8750 illustrated in FIG. 23A to FIG. 23C, a motion detection portion, an audio, a control portion, a communication portion, and a battery are provided.

The electronic device 8750 is an electronic device for VR. A user wearing the electronic device 8750 can see an image displayed on the display apparatus 8751 through the lens 8756. Furthermore, the pair of display apparatuses 8751 may display different images, whereby three-dimensional display using parallax can be performed.

An input terminal 8757 and an output terminal 8758 are provided on the back side of the housing 8752. To the input terminal 8757, a cable for supplying an image signal or the like from an image output device or power or the like for charging a battery provided in the housing 8752 can be connected. The output terminal 8758 can function as, for example, an audio output terminal to which earphones or headphones can be connected.

The housing 8752 preferably includes a mechanism for enabling adjustment of the left and right positions of the lens 8756 and the display apparatus 8751 to the optimal positions in accordance with the position of the user's eye. In addition, the housing 8752 preferably includes a mechanism for adjusting focus by changing the distance between the lens 8756 and the display apparatus 8751.

With use of the camera, the display apparatus 8751, and the electronic component, the electronic device 8750 can estimate the state of a user of the electronic device 8750 and can display information on the estimated user's state on the display apparatus 8751. Alternatively, information on a state of a user of an electronic device connected to the electronic device 8750 through a network can be displayed on the display apparatus 8751.

The cushion 8755 is a portion in contact with the user's face (e.g., forehead or cheek). The cushion 8755 is in close contact with the user's face, so that light leakage can be prevented, which increases the sense of immersion. A soft material is preferably used for the cushion 8755 so that the cushion 8755 is in close contact with the face of the user wearing the electronic device 8750. For example, any of materials such as rubber, silicone rubber, urethane, and sponge can be used. Furthermore, when a sponge or the like whose surface is covered with cloth or leather (for example, natural leather or synthetic leather) is used, a gap is unlikely to be generated between the user's face and the cushion 8755, whereby light leakage can be suitably prevented.

Furthermore, using such a material is preferable because it has a soft texture and the user does not feel cold when wearing the device in a cold season, for example. The member in contact with user's skin, such as the cushion 8755 or the mounting portion 8754, is preferably detachable because cleaning or replacement can be easily performed.

The electronic device in this embodiment may further include earphones 8754A. The earphones 8754A include a communication portion (not illustrated) and have a wireless communication function. The earphones 8754A can output audio data with the wireless communication function. Note that the earphones 8754A may include a vibration mechanism to function as bone-conduction earphones.

Like earphones 8754B illustrated in FIG. 23C, the earphones 8754A can be connected to the mounting portion 8754 directly or by wiring. The earphones 8754B and the mounting portion 8754 may each have a magnet. This is preferable because the earphones 8754B can be fixed to the mounting portion 8754 with magnetic force and thus can be easily housed.

The earphones 8754A may include a sensor portion. With use of the sensor portion, the state of the user of the electronic device can be estimated.

The electronic device of one embodiment of the present invention may include one or more selected from an antenna, a battery, a camera, a speaker, a microphone, a touch sensor, and an operation button, in addition to any one of the above components.

The electronic device of one embodiment of the present invention may include a secondary battery, and it is preferable that the secondary battery be capable of being charged by contactless power transmission.

Examples of the secondary battery include a lithium ion secondary battery (e.g., a lithium polymer battery using a gel electrolyte (lithium ion polymer battery)), a nickel-hydride battery, a nickel-cadmium battery, an organic radical battery, a lead-acid battery, an air secondary battery, a nickel-zinc battery, or a silver-zinc battery.

The electronic device of one embodiment of the present invention may include an antenna. When a signal is received by the antenna, the electronic device can display an image, information, or the like on a display portion. When the electronic device includes an antenna and a secondary battery, the antenna may be used for contactless power transmission.

A display portion in an electronic device of one embodiment of the present invention can display an image with a screen resolution of, for example, full high definition, 4K2K, 8K4K, 16K8K, or higher.

Note that this embodiment can be combined with any of the other embodiments described in this specification as appropriate.

### Embodiment 6

In this embodiment, electronic devices each including a display apparatus fabricated in accordance with one embodiment of the present invention will be described.

Electronic devices described below as examples each include the display apparatus of one embodiment of the present invention in a display portion. Thus, the electronic devices achieve high screen resolution.

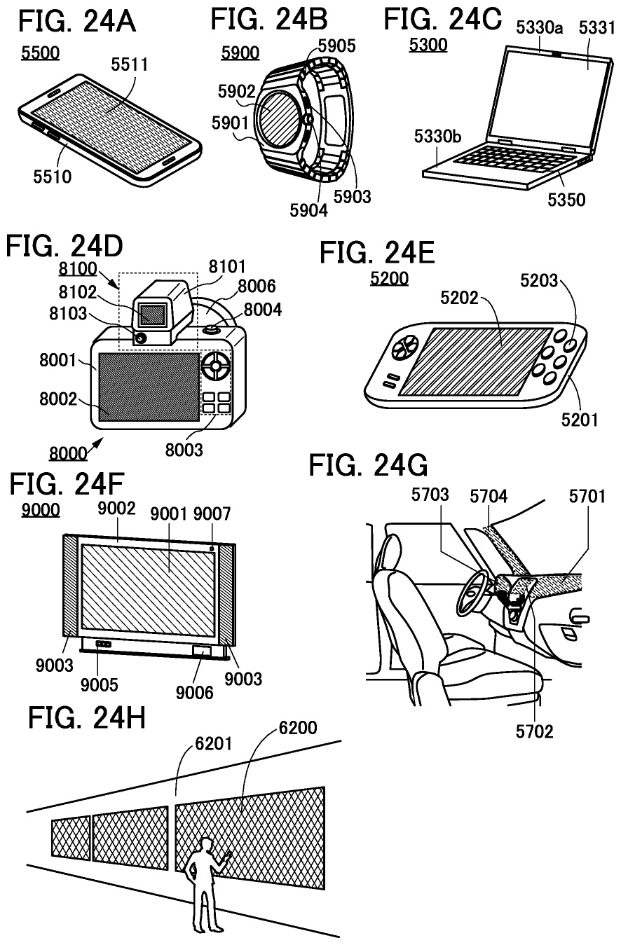

For example, a 12-inch or larger display apparatus may be used in a display portion of each of a notebook information terminal 5300 in FIG. 24C, a television device 9000 in FIG. 24F, a display panel 5701 to a display panel 5704 in an automobile in FIG. 24G, and a display portion of an electronic signage 6200 in FIG. 24H, which are described later. Therefore, the display apparatus described in Embodiment 1 is preferably used in the above electronic device. In addition, the electronic devices described above can each achieve both high screen resolution and a large screen.

Alternatively, a display apparatus taken from one substrate where a plurality of display apparatuses are fabricated can be used in a display portion of each of an information terminal 5500 in FIG. 24A, an information terminal 5900 in FIG. 24B, a camera 8000 in FIG. 24D, and a portable game machine 5200 in FIG. 24E, which are described later. Thus, the electronic devices described above can be electronic devices with a high screen resolution.

One embodiment of the present invention includes the display apparatus and one or more selected from an antenna, a battery, a housing, a camera, a speaker, a microphone, a touch sensor, and an operation button.

The electronic device of one embodiment of the present invention may include the secondary battery described in Embodiment 5, and it is preferable that the secondary battery be capable of being charged by contactless power transmission.

As the secondary battery, the secondary battery described in Embodiment 5 can be used, for example.

The electronic device of one embodiment of the present invention may include the antenna described in Embodiment 5.

A display portion in an electronic device of one embodiment of the present invention can display an image with a screen resolution of, for example, full high vision, 4K2K, 8K4K, 16K8K, or higher.

Examples of the electronic devices include electronic devices with relatively large screens, such as a television device, a laptop personal computer, a monitor device, digital signage, a pachinko machine, and a game machine. Moreover, examples of electronic devices with relatively small screens include a digital camera, a digital video camera, a digital photo frame, a mobile phone, a portable game machine, a portable information terminal, and an audio reproducing device.

The electronic device using one embodiment of the present invention can be incorporated along a surface (e.g., a flat surface or a curved surface) of an inner wall or an outer wall of a building (e.g., a house, a commercial facility and an industrial facility) or an interior or exterior surface (e.g., a flat surface or a curved surface) of a moving object (e.g., a car, a train, a ship, and a flying object).

### [Mobile Phone]

An information terminal 5500 illustrated in FIG. 24A is a mobile phone (smartphone), which is a type of information terminal. The information terminal 5500 includes a housing 5510 and a display portion 5511, and as input interfaces, a touch panel is provided in the display portion 5511 and a button is provided in the housing 5510.

### [Wearable Terminal]

FIG. 24B is an external view of an information terminal 5900 that is an example of a wearable terminal. The information terminal 5900 includes a housing 5901, a display portion 5902, an operation button 5903, a crown 5904, and a band 5905.

### [Information Terminal]

FIG. 24C illustrates a laptop information terminal 5300. The laptop information terminal 5300 illustrated in FIG. 24C includes, for example, a display portion 5331 in a housing 5330a and a keyboard portion 5350 in a housing 5330b.

Although the smartphone, the wearable terminal, and the laptop information terminal are respectively illustrated in FIG. 24A to FIG. 24C as examples of the electronic devices, one embodiment of the present invention can be used for information terminals other than a smartphone, a wearable terminal, and a laptop information terminal. Examples of information terminals other than a smartphone, a wearable terminal, and a laptop information terminal include a PDA (Personal Digital Assistant), a desktop information terminal, and a workstation.

### [Camera]

FIG. 24D is an external view of a camera 8000 to which a finder 8100 is attached.

The camera 8000 includes a housing 8001, a display portion 8002, operation buttons 8003, a shutter button 8004, and the like. In addition, a detachable lens 8006 is attached to the camera 8000.

Note that the lens 8006 and the housing may be integrated with each other in the camera 8000.

The camera 8000 can take images by the press of the shutter button 8004 or touch on the display portion 8002 functioning as a touch panel.

The housing 8001 includes a mount including an electrode, so that, in addition to the finder 8100, a stroboscope or the like can be connected to the housing.

The finder 8100 includes a housing 8101, a display portion 8102, and a button 8103.

The housing 8101 is attached to the camera 8000 in engagement with a mount of the camera 8000. In the finder 8100, an image or the like received from the camera 8000 can be displayed on the display portion 8102.

The button 8103 has a function of a power button.

The display apparatus of one embodiment of the present invention can be used for the display portion 8002 of the camera 8000 and the display portion 8102 of the finder 8100. Note that a finder may be incorporated in the camera 8000.

### [Game Machine]

FIG. 24E is an external view of a portable game machine 5200 which is an example of a game machine. The portable game machine 5200 includes a housing 5201, a display portion 5202, and a button 5203.

Images displayed on the portable game machine 5200 can be output with a display apparatus such as a television device, a personal computer display, a game display, or a head-mounted display, for example.

The portable game machine 5200 with low power consumption can be provided by including the display apparatus described in the above embodiment. Moreover, heat generation from a circuit can be reduced owing to low power consumption; thus, the influence of heat generation on the circuit itself, a peripheral circuit, and a module can be reduced.

Although FIG. 24E illustrates the portable game machine as an example of a game machine, the electronic device of one embodiment of the present invention is not limited thereto. Examples of the electronic device of one embodiment of the present invention include a stationary game machine, an arcade game machine installed in entertainment facilities (e.g., a game center or an amusement park), and a throwing machine for batting practice installed in sports facilities.

### <Television Device>

FIG. 24F is a perspective view illustrating a television device. A television device 9000 includes a housing 9002, a display portion 9001, speakers 9003, an operation key 9005 (including a power switch or an operation switch), a connection terminal 9006, and a sensor 9007 (a sensor having a function of measuring force, displacement, a position, speed, acceleration, angular velocity, rotational frequency, distance, light, liquid, magnetism, temperature, a chemical substance, sound, time, hardness, an electric field, current, voltage, power, radiation, a flow rate, humidity, gradient, oscillation, an odor, or infrared rays). The memory device of one embodiment of the present invention can be provided in the television device. The television device can include the display portion 9001 of, for example, 50 inches or more or 100 inches or more.

The television device 9000 with low power consumption can be provided by including the display apparatus described in the above embodiment. Moreover, heat generation from a circuit can be reduced owing to low power consumption; thus, the influence of heat generation on the circuit itself, a peripheral circuit, and a module can be reduced.

### <Moving Vehicle>

The display apparatus of one embodiment of the present invention can be used around a driver's seat in a car, which is a moving vehicle.

FIG. 24G is a diagram illustrating an area around a windshield inside a car. FIG. 24G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying navigation information, a speedometer, a tachometer, a mileage, a fuel meter, a gearshift indicator, and air-condition settings, for example. The content and layout of the display on the display panels can be changed appropriately to suit the user's preferences, so that the design can be improved. The display panel 5701 to the display panel 5703 can also be used as lighting devices.

The display panel 5704 can compensate for the view obstructed by the pillar (blind areas) by showing an image taken by an imaging unit provided for the car body. That is, showing an image taken by an imaging unit provided on the outside of the car body leads to elimination of blind areas and enhancement of safety. Display of an image that complements for a portion that cannot be seen makes it possible to confirm safety more naturally and comfortably. The display panel 5704 can also be used as a lighting device.

The display apparatus of one embodiment of the present invention can be used for the display panel 5701 to the display panel 5704, for example.

Although a car is described above as an example of a moving vehicle, the moving vehicle is not limited to a car. Examples of moving vehicles include a train, a monorail train, a ship, and a flying object (e.g., a helicopter, an unmanned aircraft (a drone), an airplane, or a rocket), and these moving vehicles can include the display apparatus of one embodiment of the present invention.

### [Digital Signage]

FIG. 24H illustrates an example of digital signage that can be attached to a wall. FIG. 24H illustrates a state where digital signage 6200 is attached to a wall 6201. The display apparatus of one embodiment of the present invention can be used in a display portion of the digital signage 6200, for example. An interface such as a touch panel may be provided in the digital signage 6200, for example.

Although the electronic device attachable to a wall is described above as an example of digital signage, the kind of digital signage is not limited thereto. Examples of the digital signage include digital signage attached to a pillar, freestanding digital signage placed on the ground, and digital signage mounted on a rooftop or a side wall of an architecture such as a building.

Note that this embodiment can be combined with any of the other embodiments described in this specification as appropriate.

### REFERENCE NUMERALS

DSP: display apparatus, PXAL: pixel layer, EML: layer, OSL: layer, SICL: circuit layer, BS: substrate, DRV: driver circuit region, LIA: region, DIS: display portion, ARA[1,1]: display region, ARA[2,1]: display region, ARA[m-1,1]: display region, ARA[m,1]: display region, ARA[1,2]: display region, ARA[2,2]: display region, ARA[m-1,2]: display region, ARA[m,2]: display region, ARA[1,n-1]: display region, ARA[2,n-1]: display region, ARA[m-1,n-1]: display region, ARA[m,n-1]: display region, ARA[1,n]: display region, ARA[2,n]: display region, ARA[m-1,n]: display region, ARA[m,n]: display region, ARD[1,1]: circuit region, ARD[2,1]: circuit region, ARD[m-1,1]: circuit region, ARD[m, 1]: circuit region, ARD[1,2]: circuit region, ARD[2,2]: circuit region, ARD[m-1,2]: circuit region, ARD[m,2]: circuit region, ARD[1, n-1]: circuit region, ARD[2,n-1]: circuit region, ARD[m-1,n-1]: circuit region, ARD[m,n-1]: circuit region, ARD[1,n]: circuit region, ARD[2,n]: circuit region, ARD[m-1,n]: circuit region, ARD[m,n]: circuit region, PRPH: control circuit, SD: driver circuit, SDS: circuit, GD: driver circuit, GDS: circuit, DMG: distribution circuit, DMS: distribution circuit, CTR: control portion, MD: memory device, PG: voltage generation circuit, TMC: timing controller, CKS: clock signal generation circuit, GPS: image processing portion, INT: interface, BW: bus wiring, PX: pixel, GL: wiring, GL1: wiring, GL2: wiring, GL3: wiring, SL: wiring, ANO: wiring, VCOM: wiring, V0: wiring, 30: driver circuit, 70A: pixel, 70B: pixel, 80: pixel, 80a: subpixel, 80b: subpixel, 80c: subpixel, 80d: subpixel, 103: insulator, 104: conductor, 105: insulator, 106: conductor, 107: adhesive layer, 110: substrate, 112a: conductor, 112b: conductor, 112c: conductor, 113a: first layer, 113b: second layer, 113c: third layer, 114: common layer, 115: common electrode, 118a: mask layer, 125: insulator, 127: insulator, 126a: conductor, 126b: conductor, 126c: conductor, 128: layer, 129a: conductor, 129b: conductor, 129c: conductor, 130R: light-emitting device, 130G: light-emitting device, 130B: light-emitting device, 131: protective layer, 131a: protective layer, 131b: protective layer, 131c: protective layer, 147: resin layer, 166a: coloring layer, 166b: coloring layer, 166c: coloring layer, 200: transistor, 200A: transistor, 200B: transistor, 200C: transistor, 200D: transistor, 211: insulator, 213: insulator, 214: insulator, 215: insulator, 218: insulator, 221: conductor, 222a: conductor, 222b: conductor, 223: conductor, 225: insulator, 231: semiconductor layer, 231n: low-resistance region, 231i: channel-formation region, 300: transistor, 310: substrate, 311: insulator, 312: insulator, 313: insulator, 314: insulator, 316: conductor, 317: conductor, 318: semiconductor layer, 318i: semiconductor region, 318p: low-resistance region, 319: conductor, 320: insulator, 322: insulator, 324: insulator, 400: pixel circuit, 400A: pixel circuit, 400B: pixel circuit, 400C: pixel circuit, 400D: pixel circuit, 400E: pixel circuit, 400F: pixel circuit, 400G: pixel circuit, 400H: pixel circuit, 600: capacitor, 600A: capacitor, 761: lower electrode, 762: upper electrode, 763: EL layer, 764: layer, 771: light-emitting layer, 771a: light-emitting layer, 771b: light-emitting layer, 771c: light-emitting layer, 772: light-emitting layer, 772a: light-emitting layer, 772b: light-emitting layer, 772c: light-emitting layer, 773: light-emitting layer, 780: layer, 780a: layer, 780b: layer, 780c: layer, 781: layer, 782: layer, 785: charge-generation layer, 790: layer, 790a: layer, 790b: layer, 790c: layer, 791: layer, 792: layer, 1000: display apparatus, 1000A: display apparatus, 1000B: display apparatus, 1000C: display apparatus, 1280: display module, 1281: display portion, 1290: FPC, 1282: circuit portion, 1283: pixel circuit portion, 1283a: pixel circuit, 1284: pixel portion, 1284a: pixel, 1285: terminal portion, 1286: wiring portion, 1291: substrate, 1292: substrate, 1430a: light-emitting device, 1430b: light-emitting device, 1430c: light-emitting device, 5200: portable game machine, 5201: housing, 5202: display portion, 5203: button, 5300: laptop information terminal, 5330a: housing, 5330b: housing, 5331: display portion, 5350: keyboard portion, 5500: information terminal, 5510: housing, 5511: display portion, 5701: display panel, 5702: display panel, 5703: display panel, 5704: display panel, 5900: information terminal, 5901: housing, 5902: display portion, 5903: operation button, 5904: crown, 5905: band, 6200: digital signage, 6201: wall, 8000: camera, 8001: housing, 8002: display portion, 8003: operation button, 8004: shutter button, 8006: lens, 8100: finder, 8101: housing, 8102: display portion, 8103: button, 8200: electronic device, 8201: mounting portion, 8202: lens, 8203: main body, 8204: display portion, 8205: cable, 8206: battery, 8300: electronic device, 8301: housing, 8302: display portion, 8303: operation button, 8304: fixing unit, 8304a: fixing unit, 8305: lens, 8310: user, 8311: user, 8750: electronic device, 8751: display apparatus, 8752: housing, 8754: mounting portion, 8754A: earphones, 8754B: earphones, 8755: cushion, 8756: lens, 8757: input terminal, 8758: output terminal, 9000: television device, 9001: display portion, 9002: housing, 9003: speaker, 9005: operation key, 9006: connection terminal, 9007: sensor

1. A display apparatus comprising a first layer and a second layer positioned above the first layer,
wherein the first layer comprises a substrate and a plurality of circuit regions,
wherein the second layer comprises a plurality of display regions,
wherein each of the plurality of circuit regions comprises a driver circuit,
wherein the driver circuit comprises a transistor including low-temperature polysilicon in a channel formation region,
wherein each of the plurality of display regions comprises a display pixel,
wherein the display pixel comprises a transistor including a metal oxide in a channel formation region and a light-emitting device,
wherein the driver circuit included in one of the plurality of circuit regions is configured to drive the display pixel included in one of the plurality of display regions, and
wherein the display apparatus is configured to display images on at least two of the plurality of display regions at different frame frequencies.

2. The display apparatus according to claim 1,
wherein the one of the plurality of circuit regions and the one of the plurality of display regions are positioned in a region where the ones overlap with each other in a plan view.

3. The display apparatus according to claim 1,
wherein a wiring is extended between the first layer and the second layer in a direction perpendicular to the substrate, and
wherein the wiring is electrically connected to the display pixel and the driver circuit.

4. The display apparatus according to claim 1,
wherein the substrate is a glass substrate.

5. An electronic device comprising the display apparatus according to claim 1 and a housing.
